(19) United States
(12) Patent Application Publication
(10) Pub. No.: US 2012/0217609 A1
(43) Pub. Date: Aug. 30, 2012

(54) SEMICONDUCTOR DEVICE AND ITS MANUFACTURING METHOD

(75) Inventor: Akira TANABE, Kanagawa (JP)

(73) Assignee: Renesas Electronics Corporation

(21) Appl. No.: 13/396,273

(22) Filed: Feb. 14, 2012

(30) Foreign Application Priority Data
Feb. 24, 2011 (JP) 2011-038677
Sep. 1, 2011 (JP) 2011-190906

(51) Int. Cl. H01L 29/66; H01L 21/02

(52) U.S. Cl. 257/470; 438/54; 257/E29.347; 257/E21.002

(57) ABSTRACT

A semiconductor device includes a stacked body with a recessed gas passage formed therein, a heater disposed in the stacked body, the heater being exposed on a bottom surface of the gas passage, and a plurality of thermal sensors disposed in the stacked body in such a manner that the plurality of thermal sensors sandwich the heater therebetween in an extending direction of the gas passage, the plurality of thermal sensors being exposed on the bottom surface of the gas passage. An acceleration sensor having a high affinity to the ordinary semiconductor manufacturing process can be provided.

### CROSS-REFERENCE TO RELATED APPLICATIONS

This application is based upon and claims the benefit of priority from Japanese patent application No. 2011-38677, filed on Feb. 24, 2011 and Japanese patent application No. 2011-190906, filed on Sep. 1, 2011, the disclosures of which are incorporated herein in its entirety by reference.

### BACKGROUND

1. Field of the Invention

The present invention relates to a semiconductor device and its manufacturing method, and is applied, for example, to a gas-type acceleration sensor.

2. Description of Related Art

In recent years, as mobile information apparatuses have become more sophisticated, these apparatus have been equipped with various sensors. An acceleration sensor has become an indispensable device for controllers of game machines, mobile communication terminals such as mobile phones, and so on.

Various types of the acceleration sensor have been known, including an optical type, a capacitive type, a piezoresistance type, and a gas temperature distribution type. The optical type acceleration sensor uses an optical fiber as its component, and therefore there are certain limits for its miniaturization/integration. The other three types are manufactured based on the MEMS technology. Note that when an acceleration sensor is incorporated into a compact electronic apparatus, it is common to use an acceleration sensor that is manufactured based on the MEMS (Micro Electro Mechanical Systems) technology.

Japanese Unexamined Patent Application Publication No. 2000-65850 (Patent literature 1) discloses a thermal-type acceleration sensor explained below. Thermally-isolated three beams are provided on a semiconductor substrate and a heater is provided on the middle beam. A thermocouple is provided across the left and middle beams. Similarly, another thermocouple is provided across the right and middle beams. An electromotive force of each thermocouple is amplified by an amplifier and arithmetic processing is performed on the amplified electromotive force. An acceleration output signal is generated by calculating the difference between the outputs of these thermocouples.

Further, Japanese Unexamined Patent Application Publication No. 6-27124 (Patent literature 2) discloses a gas type acceleration detector. In particular, Patent literature 2 discloses such a configuration that: a hole is formed through an insulating plate; a heating wire is disposed on one side of the insulating plate in such a manner that the heating wire straddles the hole of the insulating plate; and a heat sensor is disposed on the other side of the insulating plate in such a manner that the heat sensor straddles the hole of the insulating plate. Japanese Unexamined Patent Application Publication No. 6-174738 (Patent literature 3) discloses that a phase difference between outputs waveforms of a pair of heaters is detected by heating a heating element with an AC drive, and an angular velocity is calculated based on the detected phase difference.

### SUMMARY

The present inventors have found the following problem. When an acceleration sensor is manufactured based on the MEMS technology, it is possible to manufacture an acceleration sensor having a complex configuration. However, there is a problem that it is necessary to use a manufacturing process specific to the MEMS technology and therefore this manufacturing process has a poor affinity to the ordinary semiconductor manufacturing process.

A first aspect of the present invention is a semiconductor device including: a stacked body with a recessed gas passage formed therein; a heat-generating section disposed in the stacked body, the heat-generating section being exposed on a bottom surface of the gas passage; and a plurality of heat-sensing sections disposed in the stacked body in such a manner that the plurality of heat-sensing sections are exposed on the bottom surface of the gas passage and sandwich the heat-generating section therebetween in an extending direction of the gas passage.

The gas passage, the heat-generating section, and the plurality of heat-sensing sections are provided in the stacked body, and the heat-generating section and the plurality of heat-sensing sections are exposed on the bottom surface of the gas passage. This configuration makes it possible to provide an acceleration sensor having a high affinity to the ordinary semiconductor manufacturing process.

Another aspect of the present invention is a method of manufacturing a semiconductor device, including: forming a heat-generating section in a stacked body; forming a plurality of heat-sensing sections in the stacked body in such a manner that the plurality of heat-sensing sections sandwich the heat-generating section therebetween; and providing a recessed gas passage that extends along a direction in which the heat-generating section and the plurality of heat-sensing sections are disposed, the heat-generating section and the plurality of heat-sensing sections being exposed on a bottom surface of the gas passage.

According to an aspect of the present invention, it is possible to provide an acceleration sensor having a high affinity to the ordinary semiconductor manufacturing process.

### BRIEF DESCRIPTION OF THE DRAWINGS

The above and other aspects, advantages and features will be more apparent from the following description of certain embodiments taken in conjunction with the accompanying drawings, in which:

FIG. 1 is a schematic top view of a semiconductor device according to a first embodiment of the present invention;

FIG. 2 is a schematic cross section of a semiconductor device according to a first embodiment of the present invention;

FIG. 3 is a schematic cross section of a semiconductor device according to a first embodiment of the present invention;

FIG. 4 is a schematic top view of a heater according to a first embodiment of the present invention;

FIG. 5 is a circuit diagram showing a heater drive circuit according to a first embodiment of the present invention;

FIG. 6 is a circuit diagram showing a heat detection circuit according to a first embodiment of the present invention;

FIG. 7 is a diagram for explaining a principle for detecting an acceleration according to a first embodiment of the present invention;

FIG. 8 is a diagram for explaining a principle for detecting an acceleration according to a first embodiment of the present invention;

FIG. 9 is a block diagram showing a configuration for detecting an acceleration according to a first embodiment of the present invention;

FIG. 10 is a schematic cross section of a semiconductor device according to a second embodiment of the present invention;

FIG. 11 is a schematic top view of a semiconductor device according to a second embodiment of the present invention;

FIG. 12 is a circuit diagram showing a heat detection circuit according to a second embodiment of the present invention;

FIG. 13 is a circuit diagram showing a heat detection circuit according to a third embodiment of the present invention;

FIG. 14 is a diagram showing an operation principle of a heat detection circuit according to a third embodiment of the present invention;

FIG. 15 is a circuit diagram showing a heater drive circuit according to a fourth embodiment of the present invention;

FIG. 16 is a timing chart showing an operation of a heater drive circuit according to a fourth embodiment of the present invention;

FIG. 17 is a schematic cross section of a semiconductor device according to a fifth embodiment of the present invention;

FIG. 18 is a schematic cross section of a semiconductor device according to a sixth embodiment of the present invention;

FIG. 19 is a schematic cross section of a semiconductor device according to a seventh embodiment of the present invention;

FIG. 20 is a schematic cross section of a semiconductor device according to an eighth embodiment of the present invention;

FIG. 21 is a schematic diagram showing a heater according to a ninth embodiment of the present invention;

FIG. 22 is a schematic diagram of a semiconductor device according to a tenth embodiment of the present invention;

FIG. 23 is a block diagram showing a configuration for detecting an acceleration according to an eleventh embodiment of the present invention;

FIG. 24 is a schematic cross section of a semiconductor device according to a twelfth embodiment of the present invention;

FIG. 25 is a schematic cross section of a semiconductor device according to a twelfth embodiment of the present invention;

FIG. 26 is a schematic top view of a semiconductor device according to a thirteenth embodiment of the present invention;

FIG. 27A is a schematic horizontal cross section of an acceleration sensor according to a reference example;

FIG. 27B is a schematic vertical cross section of an acceleration sensor according to a reference example;

FIG. 28A is a schematic horizontal cross section of a semiconductor device according to a fourteenth embodiment of the present invention;

FIG. 28B is a schematic vertical cross section of a semiconductor device according to a fourteenth embodiment of the present invention;

FIG. 29 is a schematic cross section showing a method of manufacturing a semiconductor device according to a fourteenth embodiment of the present invention;

FIG. 30A is a schematic horizontal cross section of a semiconductor device according to a fifteenth embodiment of the present invention;

FIG. 30B is a schematic vertical cross section of a semiconductor device according to a fifteenth embodiment of the present invention;

FIG. 31A is a schematic horizontal cross section of a semiconductor device according to a sixteenth embodiment of the present invention;

FIG. 31B is a schematic vertical cross section of a semiconductor device according to a sixteenth embodiment of the present invention;

FIG. 32 is a schematic cross section showing a method of manufacturing a semiconductor device according to a sixteenth embodiment of the present invention;

FIG. 33A is a schematic horizontal cross section of a semiconductor device according to a seventeenth embodiment of the present invention;

FIG. 33B is a schematic vertical cross section of a semiconductor device according to a seventeenth embodiment of the present invention;

FIG. 34A is a schematic horizontal cross section of a semiconductor device according to an eighteenth embodiment of the present invention;

FIG. 34B is a schematic vertical cross section of a semiconductor device according to an eighteenth embodiment of the present invention;

FIG. 35A is a schematic horizontal cross section of a semiconductor device according to a nineteenth embodiment of the present invention;

FIG. 35B is a schematic vertical cross section of a semiconductor device according to a nineteenth embodiment of the present invention;

FIG. 36A is a schematic horizontal cross section of a semiconductor device according to a twentieth embodiment of the present invention;

FIG. 36B is a schematic vertical cross section of a semiconductor device according to a twentieth embodiment of the present invention;

FIG. 37 is a schematic top view of a semiconductor device according to a twenty-first embodiment of the present invention;

FIG. 38A is a schematic top view of a heater or a thermal sensor according to a twenty-second embodiment of the present invention;

FIG. 38B is a schematic top view of a heater or a thermal sensor according to a twenty-second embodiment of the present invention;

FIG. 38C is a schematic top view of a heater or a thermal sensor according to a twenty-second embodiment of the present invention;

FIG. 39A is a schematic top view of a heater or a thermal sensor according to a twenty-third embodiment of the present invention;

FIG. 39B is a schematic top view of a heater or a thermal sensor according to a twenty-third embodiment of the present invention;

FIG. 40A is a schematic perspective view of a heater or a thermal sensor according to a twenty-fourth embodiment of the present invention;

FIG. 40B is a schematic perspective view of a heater or a thermal sensor according to a twenty-fourth embodiment of the present invention;

FIG. 41 is a schematic top view of a semiconductor device according to a reference example;

FIG. 42 is a schematic top view of a semiconductor device according to a twenty-fifth embodiment of the present invention;

FIG. 43A is a schematic cross section of a semiconductor device according to a twenty-fifth embodiment of the present invention;

FIG. 43B is a schematic cross section of a semiconductor device according to a twenty-fifth embodiment of the present invention;

FIG. 43C is a schematic cross section of a semiconductor device according to a twenty-fifth embodiment of the present invention;

FIG. 43D is a schematic cross section of a semiconductor device according to a twenty-fifth embodiment of the present invention;

FIG. 44 is a schematic top view of a semiconductor device according to a twenty-sixth embodiment of the present invention;

FIG. 45 is a schematic top view of a semiconductor device according to a twenty-seventh embodiment of the present invention;

FIG. 46 is a circuit diagram showing a resistance read circuit according to a twenty-eighth embodiment of the present invention;

FIG. 47 is a circuit diagram showing a resistance read circuit according to a twenty-ninth embodiment of the present invention;

FIG. 48 is a schematic cross section of a resistance read circuit according to a twenty-ninth embodiment of the present invention;

FIG. 49 is a circuit diagram showing a resistance read circuit according to a thirtieth embodiment of the present invention;

FIG. 50A is a schematic horizontal cross section of a semiconductor device according to a thirty-first embodiment of the present invention;

FIG. 50B is a schematic vertical cross section of a semiconductor device according to a thirty-first embodiment of the present invention;

FIG. 51A is a schematic horizontal cross section of a semiconductor device according to a thirty-second embodiment of the present invention;

FIG. 51B is a schematic vertical cross section of a semiconductor device according to a thirty-second embodiment of the present invention;

FIG. 52 is a circuit diagram showing a heat detection circuit according to a thirty-third embodiment of the present invention;

FIG. 53A is a diagram for explaining a detection principle of a thermal detection circuit according to a thirty-third embodiment of the present invention;

FIG. 53B is a diagram for explaining a detection principle of a thermal detection circuit according to a thirty-third embodiment of the present invention;

FIG. 54 is a block diagram showing a measurement configuration of a semiconductor device according to a thirty-fourth embodiment of the present invention;

FIG. 55 is a circuit diagram showing a read circuit according to a thirty-fourth embodiment of the present invention;

FIG. 56 is a graph showing a measurement result of a semiconductor device according to a thirty-fourth embodiment of the present invention;

FIG. 57 is a circuit diagram showing a heat detection circuit according to a thirty-fifth embodiment of the present invention;

FIG. 58 is a circuit diagram showing a heat detection circuit according to a thirty-sixth embodiment of the present invention;

FIG. 59 is a circuit diagram showing a comparator according to a thirty-seventh embodiment of the present invention;

FIG. 60A is a circuit diagram showing a comparator according to a thirty-seventh embodiment of the present invention;

FIG. 60B is a circuit diagram showing a comparator according to a thirty-seventh embodiment of the present invention; and

FIG. 61 is a circuit diagram showing a comparator according to a thirty-seventh embodiment of the present invention.

### DETAILED DESCRIPTION

Embodiments according to the present invention are explained hereinafter with reference to the drawings. Embodiments explained below are not independent of each other, and can be combined with one another as desired. Further, advantageous effects obtained by such combinations are also included in the advantageous effects of the present invention. The same components are assigned with the same symbols, and duplicated explanation thereof is omitted. The drawings are created for the purpose of explaining the present invention, and the scope of the present invention should not be restricted based on the drawings.

### First Embodiment

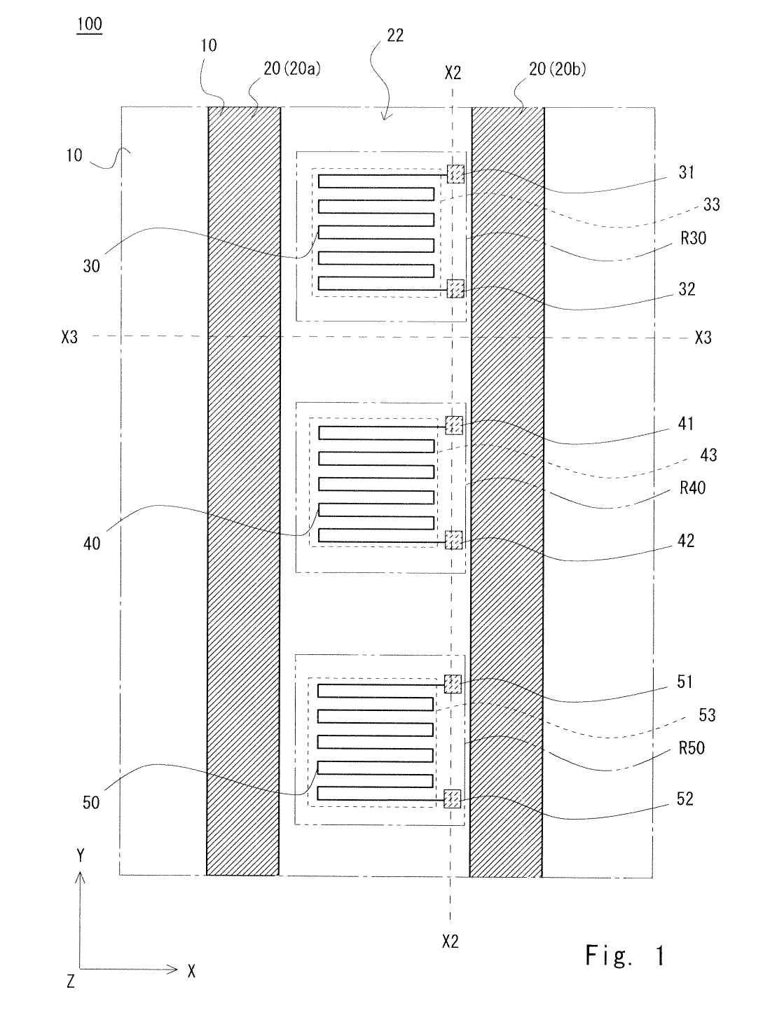

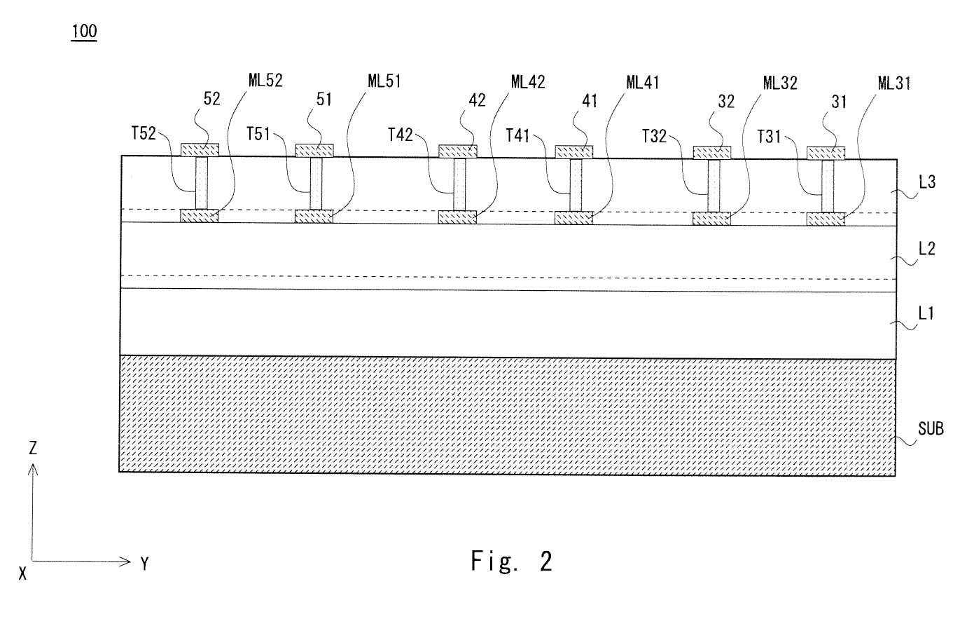

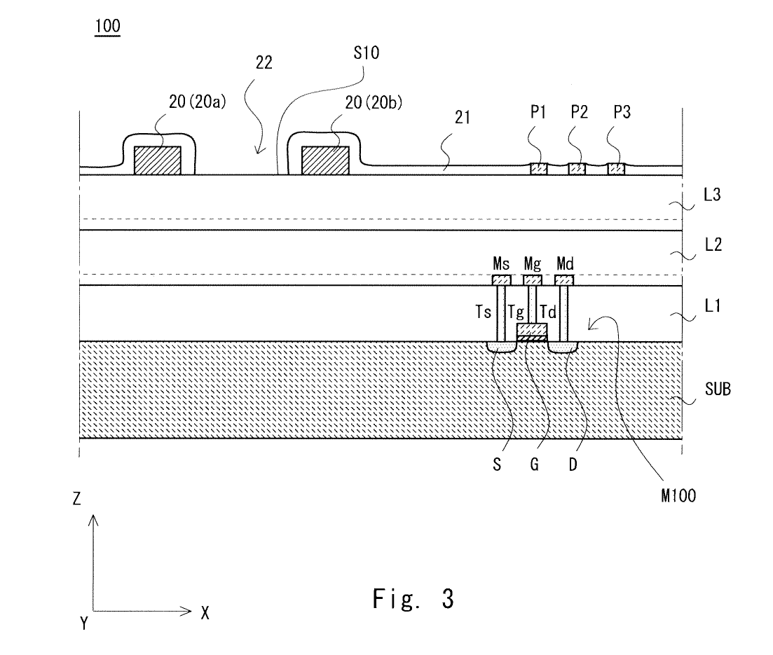

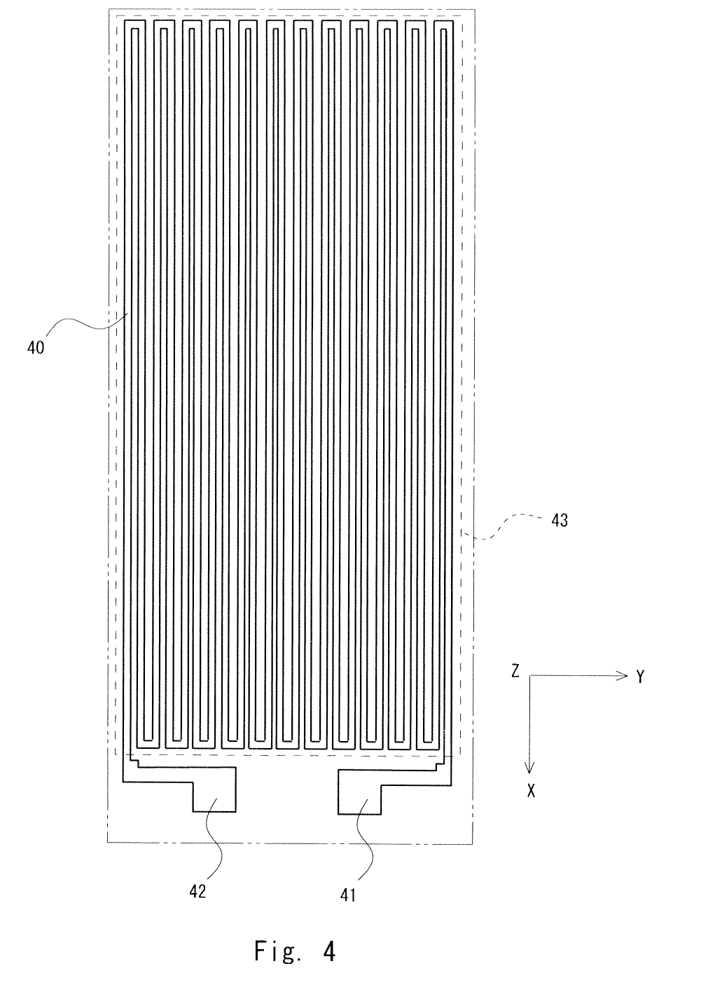

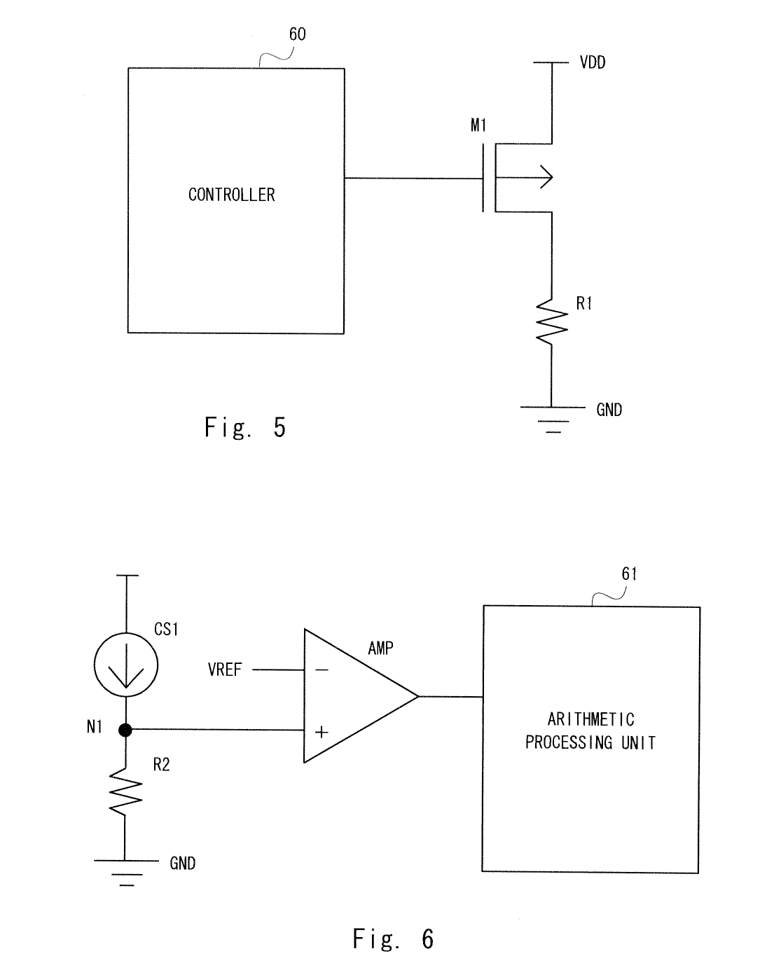

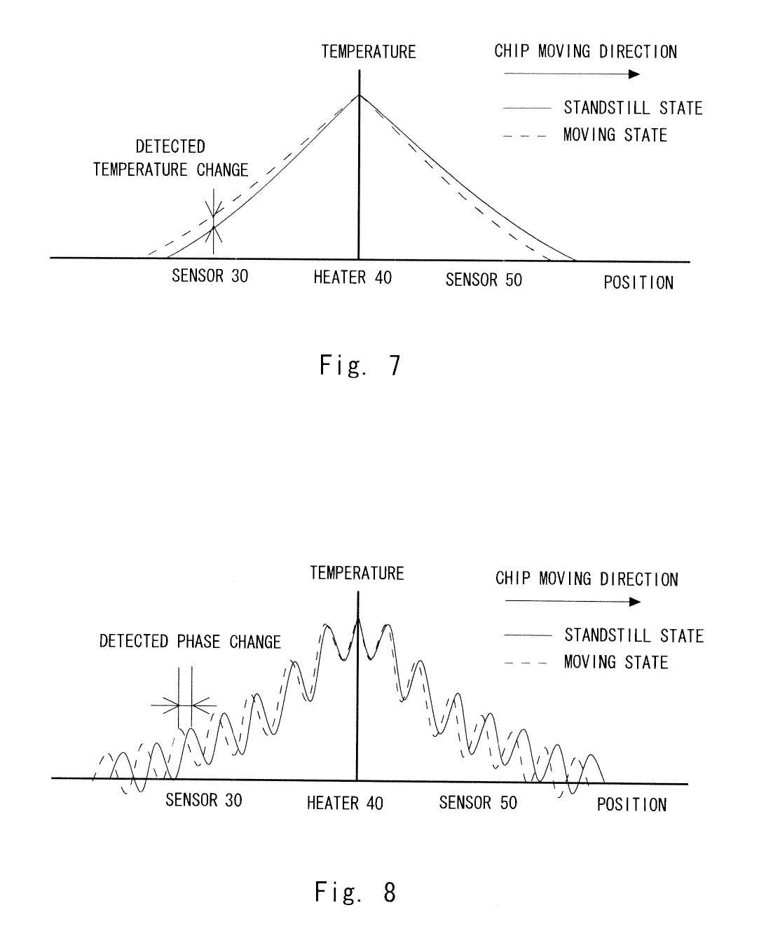

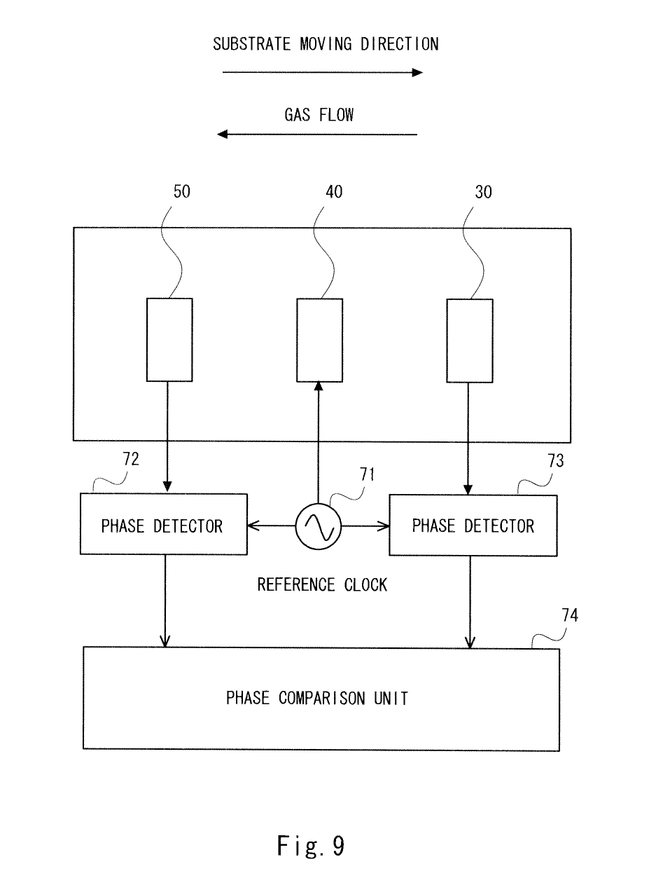

Embodiments according to the present invention are explained hereinafter with reference to the drawings. FIG. 1 is a schematic top view of a semiconductor device. FIGS. 2 and 3 are schematic cross sections of the semiconductor device. FIG. 4 is a schematic top view of a heater. FIG. 5 is a circuit diagram showing a heater drive circuit. FIG. 6 is a circuit diagram showing a heat detection circuit. FIGS. 7 and 8 are diagrams for explaining a principle for detecting an acceleration. FIG. 9 is a block diagram showing a configuration for detecting an acceleration.

As it becomes more obvious from the explanation below, in this embodiment according to the present invention, a gas passage, a heat-generating section, and a plurality of heat-sensing sections are provided in a stacked body, and the heat-generating section and the plurality of heat-sensing sections are exposed on the bottom surface of the gas passage. The gas passage can be provided in the stacked body by using an ordinary semiconductor process technology (layer deposition, photo lithography, etching, lift-off, substrate bonding, spin-coating, plating, and so on). Similarly, the heat-generating section and the heat-sensing sections can be also provided in the stacked body by using an ordinary semiconductor process. As a result, it is possible to manufacture an acceleration sensor by using an ordinary semiconductor process without using any process specific to the MEMS technology. Further, it is also possible to integrate an acceleration sensor into a semiconductor circuit chip.

There are various possible merits that are obtained by integrating an acceleration sensor into a semiconductor circuit chip. For example, it is possible to reduce the overall cost by integrating an acceleration sensor into a semiconductor circuit chip. In addition, the assembling process, which is indispensable in the conventional manufacturing method, can be eliminated. Note that the specific configuration and specific number of the gas passage, the heat-generating section, and the heat-sensing sections can be arbitrarily determined and should not be limited to those mentioned in the explanation below. The same is true for the specific configuration of the stacked body. Further, the interval of the heat-sensing sections with respect to the heat-generating section can be also arbitrarily determined.

Specific explanation is given hereinafter. As shown in FIG. 1, a semiconductor device 100 includes a stacked body 10, a wiring layer (uppermost layer wiring structure) 20, at least two thermal sensors (heat-sensing sections) 30 and 50, and a heater (heat-generating section) 40. As shown in FIG. 2, the stacked body 10 includes a semiconductor substrate SUB and wiring structure layers L1 to L3. Note that the wiring layer 20 is a constituent layer of the stacked body 10 and thus included in the stacked body 10. As shown in FIG. 3, the upper surface S10 of the wiring structure layer L3 is covered by a protection layer 21. The protection layer 21 is not formed in part of the upper surface S10 that is located between wall line 20a and 20b. It is also possible to consider that the protection layer 21 is also included in the stacked body 10. As shown in FIG. 3, a MOS transistor M100 is formed in the semiconductor substrate SUB. Note that FIG. 2 is a schematic cross section taken along the line X2-X2 in FIG. 1, and FIG. 3 is a schematic cross section taken along the line X3-X3 in FIG. 1.

The semiconductor device 100 shown in FIGS. 1 to 3 is disposed in a semiconductor IC (Integrated Circuit) chip having an arbitrary size and housed within a package filled with an inert gas (such as nitrogen gas) in an airtight-sealed state. The actual packaging structure and the airtight sealing method may be implemented by using various known techniques.

The stacked body 10 is formed by staking a plurality of layers on a semiconductor substrate by using an ordinary semiconductor process. The stacked body 10 is formed by successively forming the wiring structure layers L1 to L3, the wiring layer 20, and the protection layer 21 on the semiconductor substrate SUB. The wiring structure layer L1 is formed by providing a wiring layer on an insulating layer. Further, the other wiring structure layers L2 and L3 are also formed in a similar manner. Note that the structure shown in FIGS. 1 to 3 is manufactured by using an ordinary semiconductor process (layer deposition, photo lithography, etching, lift-off, annealing, spin-coating, and so on). Since these processes are well-known for those skilled in the art, their detailed explanation is omitted.

The wiring layer 20 is a conductive layer that is shaped into a desired pattern by photolithography or the like. The wiring layer 20 includes projecting (convex) wall lines 20a and 20b. A gas passage 22 is formed between the wall lines 20a and 20b. The wall line 20a is a long linear line extending along the y-axis. The wall line 20b has a similar configuration. The gas passage 22 also extends along the y-axis. The wall lines and the gas passage extend along the axis line perpendicular to the stacking direction (z-axis direction) of the stacked body 10. The wall lines are in the same wiring layer as the heater and the sensor, or in a wiring layer located above the heater and the sensor. Further, the wall lines are disposed so as to surround the heater and the sensor. In this manner, the projecting bumps that are created by the wall lines formed above the wiring layer structure serve as walls, and the gas passage is formed inside the walls. The surface of these wall lines may be or may not be coated with an insulating film such as an oxide film/polyimide film. In this example, in comparison to Patent literature 1, the gas passage can be formed without forming a through-hole in the stacked body 10 and without requiring any additional process. Further, by forming the wall lines in a long shape, it is possible to secure a sufficient wring space for other components disposed in the same semiconductor substrate SUB. In other words, since a pair of wall lines can be formed by using an empty space in the wiring space of other components disposed in the same substrate, the increase in the chip size can be minimized.

The thermal sensor 30, the heater 40, and the thermal sensor 50 are disposed on the bottom surface of the gas passage 22 in an exposed state. The thermal sensor 30, the heater 40, and the thermal sensor 50 are formed by a conductive layer (preferably, copper (Cu), aluminum (Al), tungsten (W), nickel (Ni), titanium (Ti), chromium (Cr), iron (Fe), gold (Au), platinum (Pt), vanadium (V), an alloy thereof, an oxide thereof, or a nitride thereof) that is formed and patterned on the wiring structure layer L3. The heater 40 is sandwiched between the thermal sensors 30 and 50. When viewed from the heater 40, the thermal sensors 30 and 50 are disposed in roughly equivalent places. The thermal sensors 30 and 50 are thermally connected to the heater 40 through a gas present in the gas passage 22. It is unnecessary to make the distances from the heater 40 to the thermal sensors 30 and 50 completely equal to each other, because an offset adjustment can be made as necessary by processing performed on the controller side of the acceleration sensor.

Note that it is preferable that the surfaces of the thermal sensor 30, the heater 40, and the thermal sensor 50 are exposed to the gas as much as possible. Referring to FIG. 2, only the bottom surfaces of the thermal sensor 30, the heater 40, and the thermal sensor 50 are in contact with the wiring layer structure and their side surfaces and upper surfaces are exposed to the gas. To increase these surface areas even further, it is preferable to perform etching, CVD, or plating on the surfaces of the thermal sensor 30, the heater 40, and the thermal sensor 50 so that they have uneven (concave-convex) surfaces.

The thermal sensor 30 includes a line portion 31 having a rectangular shape as viewed from the top (hereinafter, also simply called “land”), a land 32 having a rectangular shape as viewed from the top, and a pattern line portion 33. Further, the thermal sensor 30 is disposed in a patterning area R30. The pattern line portion 33 is a part in which a projecting line is laid out in a wavelike pattern along the y-axis. The pattern line portion does not necessarily have to be laid out in a wavelike pattern. One end of the wiring constituting the pattern line portion 33 is connected to the island-like land 31 and the other end is connected to the island-like land 32. The patterning area R30 is disposed between a pair of wall lines.

Similarly to the thermal sensor 30, the heater 40 includes a land 41, a land 42, and a pattern line portion 43, and is disposed in a patterning area R40. Similarly to the thermal sensor 30, the thermal sensor 50 includes a land 51, a land 52, and a pattern line portion 53, and is disposed in a patterning area R50. The configuration of each of the pattern line portion 43 and 53 is similar to that of the pattern line portion 33. The patterning areas R30 to R50 has roughly the equal size to each other, but the present invention is not limited to this configuration. Although the lands 31, 32, 41, 42, 51 and 52 are arranged in a row, the layout pattern of the lands can be arbitrarily determined. That is, it is not limited to this particular disclosure. Each of the patterning areas R30, R40 and R50 is a rectangular area having a length of about 10 μM to 30 μM and a width of about 10 μM to 30 μM. In order to achieve acceleration detection with higher accuracy, each patterning area is formed in a minuscule area as described above.

As schematically shown in FIG. 2, each land disposed on the wiring structure layer L3 is connected to the wiring layer disposed on the wiring structure layer L2 through a trench line disposed in the wiring structure layer L3. For example, the land 31 is connected to a wiring layer ML31 through a trench line T31. Note that the trench line is formed by forming a through-hole in the insulating layer and filing this through-hole with conductive material.

As schematically shown in FIG. 3, the transistor M100 formed on the semiconductor substrate SUB includes a source region (S), a gate structure (G), and a drain region (D). The source region is connected to a source wiring layer Ms through a trench line Ts. The gate electrode is connected to a gate wiring layer Mg through a trench line Tg. The drain region is connected to a drain wiring layer Md through a trench line Td. The source wiring Ms is connected to other circuit components through a wiring connection (not shown). Similarly, the gate wiring Mg and the drain wiring Md are also connected to other circuit components. A control signal input pad P1, a reference potential supply pad P2, and a signal output pad P3 are provided on the wiring structure layer L3. For example, a functional circuit that is included in the transistor M100 as a circuit component operates according to a control signal input through the control signal input pad P1. Note that the pads P1 to P3 are usually disposed on the peripheral area of the chip. However, they are illustrated in a simpler fashion in this example for the sake of explanation.

As obvious from FIGS. 1 to 3, the wiring pattern constituting the thermal sensor 30, the heater 40, and the thermal sensor 50 is formed in the same layer as that of other wiring structures (for example, pads P1 to P3 shown in FIG. 3) or in a layer below the wall line. In this manner, it is possible to incorporate the thermal sensor 30, the heater 40, and the thermal sensor 50 into the stacked body 10 without drastically changing the existing manufacturing process. By forming the above-described wiring pattern by using an empty space in the wiring space, it is possible to incorporate an acceleration sensor into an existing IC chip without increasing the current chip size.

FIG. 4 shows a configuration of the heater 40 as viewed from the top. As shown in FIG. 4, the width of the line in the pattern line portion 43 is narrower than the width of the line portion that connects a heater with heater drive circuit. This narrow line is laid out upward and downward along the x-axis and thereby extends in a wavelike pattern along the y-axis. The narrow line is a heat-generating member that generates heat according to the current flowing therethrough. By laying out the narrow line at a high density as described above, a minuscule heat source is provided on the bottom of the gas passage 22. Letting V and R stand for the power supply voltage and the resistance value of the heater respectively, the power consumption P of the heater is expressed as “P=V2/R”. Therefore, by securing the resistance value of the heater to a certain level, the power consumption of the heater can be reduced. Therefore, by increasing the resistance value of the heater by using the narrow line, the power consumption of the heater can be reduced. Note that the patterning configuration of the heater does not necessarily have to be a single layer configuration. That is, the heater may be constructed by using multi-layer wiring layers (for example, four layers). In this way, it is possible to provide a heater in a smaller area and thereby possibly improve the accuracy of the acceleration sensor even further.

In this embodiment, the pattern line portion 43 itself is thermally isolated from the semiconductor substrate SUB by insulating layers present in the wiring structure layers L1 to L3. If the heat generated by the pattern line portion 43 of the heater 40 is transferred to the semiconductor substrate SUB, it could have an adverse effect on the operation of components provided in the semiconductor substrate SUB. In this embodiment, since the pattern line portion 43 is formed above the semiconductor substrate SUB with the insulating layers present in the wiring structure layers L1 to L3 interposed therebetween as described above, the pattern line portion 43 is thermally isolated as viewed from the semiconductor substrate SUB. By suppressing the heat transfer from the pattern line portion 43 to the semiconductor substrate SUB, it is possible to effectively increase the reliability of the operation of the semiconductor device 100. By using a ground wiring layer, the heat transfer through the connection line from the pattern line portion 43 to the semiconductor substrate SUB may be also prevented.

Each of the thermal sensors 30 and 50 has a roughly similar configuration to that of the heater 40 shown in FIG. 4. It should be noted that although the thermal sensors 30 and 50 do not need to generate heat, they also have a similar configuration to that of the heater 40, in which a narrow line is laid out, so that they can detect a change in the resistance value caused by a temperature change in the vicinity thereof.

A configuration example of a heater drive circuit is explained with reference to FIG. 5. Note that the following explanation is made on the assumption that this drive circuit is provided above the semiconductor substrate SUB shown in FIG. 2. As shown in FIG. 5, the heater drive circuit includes a MOS transistor M1 and a resistor R1 that are connected in series between a power-supply potential VDD and a ground potential GND. The On/Off of the MOS transistor is controlled by a controller 60. The heater 40 shown in FIGS. 1 to 3 corresponds to the resistor R1 in FIG. 5. For example, the controller 60 supplies a drive pulse to the gate terminal of the MOS transistor M1. The MOS transistor M1 is turned on in response to the drive pulse. During the period in which the MOS transistor M1 is in an On-state, a current flows through the resistor R1 and the heater 40 thereby generates heat.

A configuration example of a heat detection circuit is explained with reference to FIG. 6. Note that the following explanation is made on the assumption that the heat detection circuit is provided above the semiconductor substrate SUB shown in FIG. 2. The heat detection circuit detects a change in resistance according to the temperature change, of the line constituting the thermal sensor. The sheet resistance of a metal line (copper, aluminum, or the like) formed on a silicon substrate increases by 1 to 2% per degree of temperature. The heat detection circuit senses this resistance change and thereby detects the temperature. Further, it is also possible to use vanadium oxide, which exhibits a larger temperature change to the heat.

As shown in FIG. 6, the heat detection circuit includes a current source CS1, a resistor R2, an amplifier AMP, and an arithmetic processing unit 61. The current source CS1 and the resistor R2 are connected in series between a power-supply potential VDD and a ground potential GND. The node between the current source CS1 and the resistor R2 is connected to the positive input terminal of the amplifier AMP. A reference voltage VREF is connected to the negative input terminal of the amplifier AMP. The output of the amplifier AMP is supplied to the arithmetic processing unit 61. The thermal sensor 30 shown in FIGS. 1 to 3 corresponds to the resistor R2 in FIG. 6. The temperature of the resistor R2 changes according to the temperature of the heater 40 that is transferred through the gas. The voltage input to the positive input terminal of the amplifier AMP changes according to the change in resistance value of the resistor R2. The amplifier AMP amplifies a difference value between the reference voltage VREF and the input voltage and outputs the amplified difference value. Note that the same heat detection circuit shown in FIG. 6 is also used for the thermal sensor 50. The arithmetic processing unit 61 performs arithmetic processing of the values output from the circuits connected to the respective thermal sensors 30 and 50, and thereby calculates an acceleration.

A acceleration calculation principle/method is explained with reference to FIGS. 7 and 8. Note that the thermal sensors 30 and 50 are arranged with roughly equal distances as viewed from the heater 40 as described above. Therefore, when the semiconductor device 100 is not moving, the thermal sensors 30 and 50 sense roughly the same quantity of heat as each other. Note that in order to reduce the effect caused by variations of the arrangement distances of the thermal sensors with respect to the heater, it is preferable to adjust the offset caused between the thermal sensors 30 and 50. In this way, it is possible to detect an acceleration with higher accuracy.

As shown in FIG. 7, an acceleration may be calculated based on the temperature difference between the thermal sensors 30 and 50. As schematically shown in FIG. 7, when the semiconductor device 100 moves, the thermal distribution indicated by the solid line shifts to that indicated by the dotted line as viewed from the semiconductor device 100. The temperature in the thermal sensor 30 increases while the temperature in the thermal sensor 50 decreases. There is a temperature difference in the thermal sensor 30 between a time t1 in a standstill state and a time t2 in a moving state. There is also a temperature difference in the thermal sensor 50 between the time t1 in the standstill state and the time t2 in the moving state. An acceleration is calculated based on the difference between the temperatures sensed by the thermal sensor 30 and 50. Note that the actual formula for calculating an acceleration is obtained based on experiments, and its detailed explanation is omitted.

Note that the output voltages from the respective thermal sensors 30 and 50 at a standstill state are not necessarily equal to each other due to variations of the sensor positions, variations of the components, and so on. In such cases, an output from each thermal sensor in a non-accelerated state is stored in advance, and an acceleration in an accelerated state is detected based on the difference from the stored value.

The heat transfer path form the heater from the thermal sensors includes, in addition to the path through the gas, paths through the interlayer insulating film and through the silicon substrate. However, the heat transfer caused by the paths other than the path through the gas does not change regardless of whether the chip is accelerated or not. Therefore, it is possible to eliminate the effect caused by these paths by detecting an acceleration by using the output from each thermal sensor obtained in the non-accelerated state as a reference output.

As shown in FIG. 8, the heater 40 may be driven by pulses and an acceleration may be thereby calculated based on the phase difference between the temperature change waveforms of the thermal sensor 30 and 50. As schematically shown in FIG. 8, when the heater 40 is driven by pulses, a wavelike thermal distribution is formed around the heater 40. The apexes of the thermal waveform correspond to the heater 40 in On-states, and bottoms of the thermal waveform correspond to the heater 40 in Off-states. The temperature in the thermal sensor 30 changes according to the waveform, which changes with time. The temperature in the thermal sensor 50 changes in a similar fashion.

As schematically shown in FIG. 8, when the semiconductor device 100 moves, the thermal distribution indicated by the solid line shifts to that indicated by the dotted line as viewed from the semiconductor device 100. In response to this, the temperature change in the thermal sensor 30 changes from a phase corresponding to the thermal distribution indicated by the solid line to a phase corresponding to the thermal distribution indicated by the dotted line. The phase difference of the thermal distribution schematically shown in FIG. 8 is detected as a phase change of the temperature change in the thermal sensor 30. An acceleration is calculated based on the phase difference of the temperature changes in the thermal sensors 30 and 50. Note that the actual formula for calculating an acceleration is obtained based on experiments, and its detailed explanation is omitted.

An example of a circuit configuration for calculating an acceleration according to the method shown in FIG. 8 is explained with reference to FIG. 9. As shown in FIG. 9, a reference clock 71 is supplied to the heater 40 and also individually supplied to phase detectors 72 and 73. The heater 40 is driven by pulses according to the supplied reference clock 71. The phase of the temperature change in the thermal sensor 30 is detected by the phase detector 73 based on the comparison with the reference clock. The phase of the temperature change in the thermal sensor 50 is detected by the phase detector 72 based on the comparison with the reference clock. Note that it is assumed that the output of the amplifier AMP shown in FIG. 6 is supplied to the phase detectors 72 and 73. A phase comparison unit 74 detects a phase difference between the waveform supplied from the phase detector 72 and that supplied from the phase detector 73.

As shown in FIG. 9, when the semiconductor device 100 moves, the gas flows in the opposite direction as viewed from the semiconductor device 100. As a result, the heat transfer time from the heater 40 to the thermal sensor 30, which is located on the forward side as viewed from the heater 40, becomes longer than the heat transfer time from the heater 40 to the thermal sensor 50, which is located on the opposite side. In the example shown in FIG. 9, this time difference is detected as a phase difference of the temperature change in the thermal sensors and an acceleration is calculated based on this phase difference. By calculating an acceleration based on a difference between the transfer time for the thermal sensor 30 (which is detected based on the rising edge timing of pulses output from the phase detector 73) and the transfer time for the thermal sensor 50 (which is detected based on the rising edge timing of pulses output from the phase detector 72), it is possible to calculate the acceleration in such a state that the adverse effect caused by accuracy variations due to the absolute temperature detection and the like is reduced. In the method shown in FIGS. 8 and 9, since alternating-fashion temporal temperature changes are detected, the absolute values of temperatures do not have any direct influence on the calculation accuracy. Therefore, it is possible to calculate an acceleration with higher accuracy in comparison to the methods in which the absolute values of temperatures are detected.

Note that specific manufacturing procedure of the semiconductor device 100 can be arbitrarily determined, and various modifications can be made as necessary by those skilled in the art. The configuration shown in FIGS. 1 to 3 is merely an example. FIGS. 1 to 3 show a part of an IC chip configuration in a simplified manner, and do not show the entire IC chip in which various circuits/components are integrated.

As explained at the beginning, in this embodiment according to the present invention, the gas passage 22, the heater 40, and the thermal sensors 30 and 50 are provided in the stacked body 10, and the heater 40 and the thermal sensors 30 and 50 are exposed on the bottom surface of the gas passage 22. The gas passage 22 can be provided in the stacked body 10 by using an ordinary semiconductor process technology (layer deposition, photo lithography, etching, lift-off, substrate bonding, spin-coating, plating, and so on). Similarly, the heater 40 and the thermal sensors 30 and 50 can be also provided in the stacked body 10 by using an ordinary semiconductor process technology. As a result, it is possible to manufacture an acceleration sensor by using an ordinary semiconductor process without using any process specific to the MEMS technology. Further, it is also possible to integrate an acceleration sensor into a semiconductor circuit chip.

There are various possible merits that are obtained by integrating an acceleration sensor into a semiconductor circuit chip. For example, it is possible to reduce the overall cost by integrating an acceleration sensor into a semiconductor circuit chip. In addition, the assembling process, which is indispensable in the conventional manufacturing method, can be eliminated. Note that the specific configuration and specific number of the gas passage, the heater, and the thermal sensors can be arbitrarily determined. Similarly, the specific configuration of the stacked body can be also arbitrarily determined.

### Second Embodiment

A second embodiment according to the present invention is explained with reference to FIGS. 10 to 12. In this embodiment, in contrast to the first embodiment, temperature changes in a thermal sensor, i.e., temperature changes of a gas present above the thermal sensor is detected by detecting changes in the forward voltage of a PN junction connected to the thermal sensor. By using the PN junction in place of the resistor, temperature changes can be detected with higher accuracy. Note that the forward voltage of a diode composed of a PN junction changes about 2 mV per degree of temperature. Therefore, when the temperature changes by 10° C., a signal of about 20 mV can be obtained.

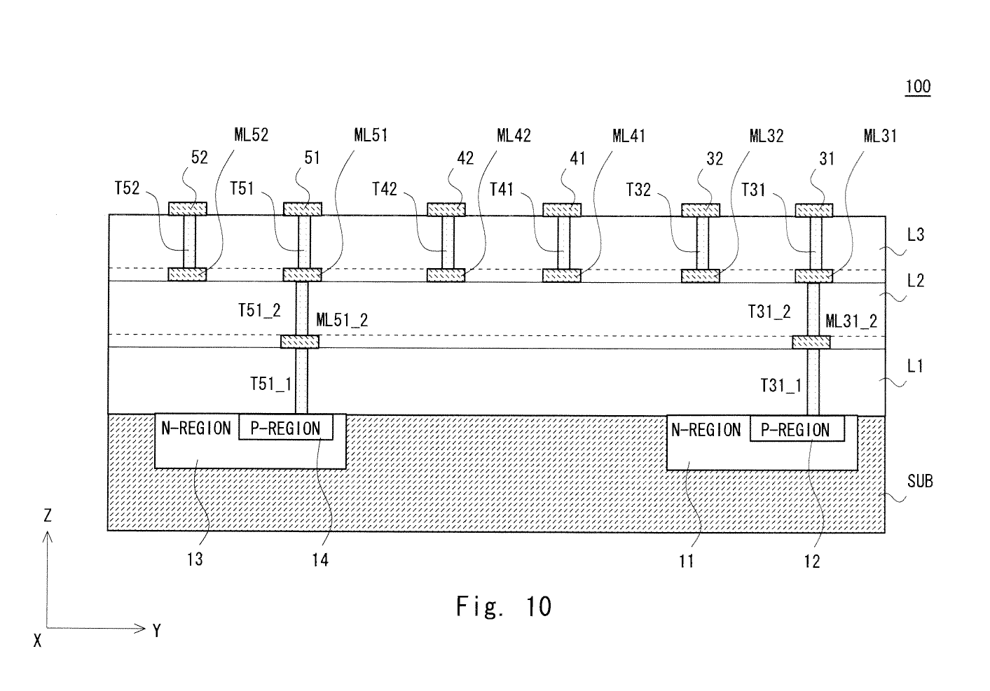

FIG. 10 is a schematic cross section of a semiconductor device. FIG. 11 is a schematic top view of the semiconductor device. FIG. 12 is a circuit diagram showing a heat detection circuit.

As shown in FIG. 10, N-well regions 11 and 13 are formed in a semiconductor substrate SUB (p-type substrate) by thermal diffusion of impurities. A P-well region 12 is formed within the N-well region 11 by thermal diffusion of impurities. A P-well region 14 is formed within the N-well region 13. The land 31 of the thermal sensor 30 is connected to the P-well region 12 through trench lines T31, T31_2 and T31_1, and lines ML31 and ML31_2 formed in the wiring structure layers. The land 51 of the thermal sensor 50 is connected to the P-well region 14 through trench lines T51, T51_2 and T51_1, and lines ML51 and ML51_2 formed in the wiring structure layers.

As shown in FIG. 11, the P-well region 12 is formed directly below the land 31. The formation range of the P-well region 12 is larger than the formation range of the land 31. The P-well region 14 is formed directly below the land 51. The formation range of the P-well region 14 is larger than the formation range of the land 51. Note that the relative positional relation between the P-well region and the land can be arbitrarily determined, and it is not limited to this example.

In comparison to the heat detection circuit shown FIG. 6, the resistor R2 is replaced by a diode D1 in the heat detection circuit shown in FIG. 12. By detecting temperature changes based on the changes in the cathode voltage of the diode D1 in this manner, it is possible to detect the temperature of the thermal sensor with higher accuracy. Note that in FIG. 12, it is assumed that the line portion of each of the thermal sensors 30 and 50 shown in FIG. 11 is disposed between the node N1 between the cathode terminal of the diode D1 and the current source CS1 and the current source CS1.

Similarly to the first embodiment, in this embodiment, the pattern line portion 43 is thermally isolated from the semiconductor substrate SUB by the insulating layers present in the wiring structure layers L1 to L3. If the heat generated by the pattern line portion 43 of the heater 40 is transferred to the semiconductor substrate SUB, it could have an adverse effect on the operation of the diode provided in the semiconductor substrate SUB. In this embodiment, since the pattern line portion 43 is formed above the semiconductor substrate SUB with the insulating layers present in the wiring structure layers L1 to L3 interposed therebetween as described above, the pattern line portion 43 is thermally isolated as viewed from the semiconductor substrate SUB. By suppressing the heat transfer from the pattern line portion 43 to the semiconductor substrate SUB, it is possible to effectively increase the reliability of the operation of the semiconductor device 100.

### Third Embodiment

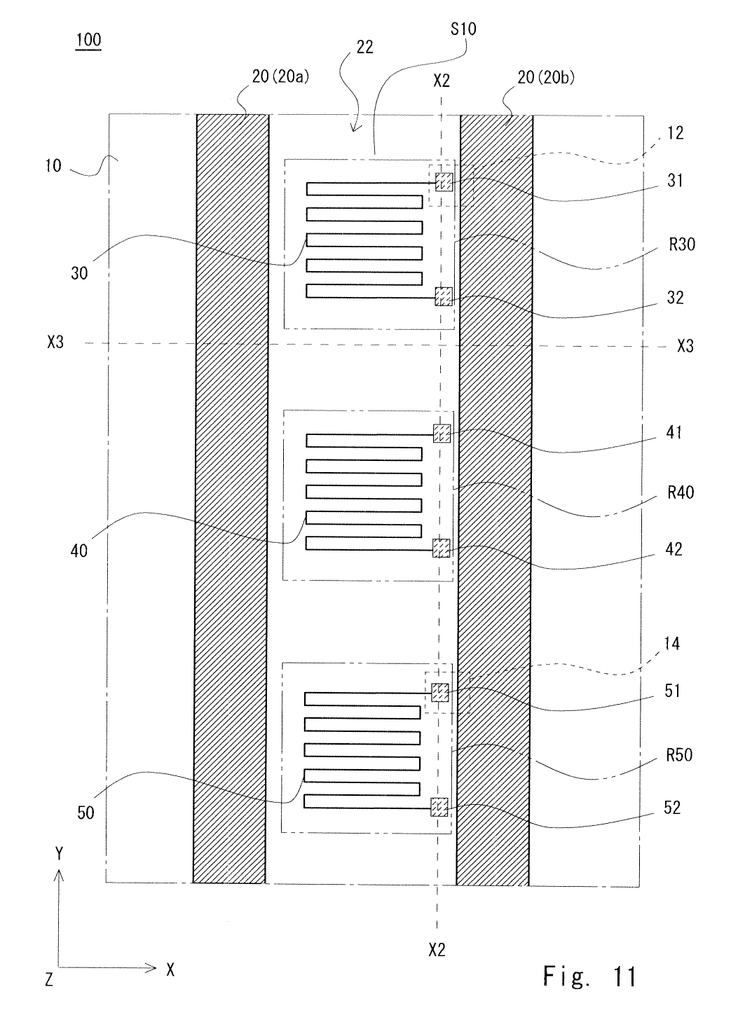

A third embodiment according to the present invention is explained with reference to FIGS. 13 and 14. In this embodiment, the heat detection circuit includes a reference voltage generation circuit. Even in the case like this, similar advantageous effects to those of the above-described embodiments can be obtained.

FIG. 13 is a circuit diagram showing a heat detection circuit. FIG. 14 shows an operation principle of the heat detection circuit.

As shown in FIG. 13, the node between a current source CS3 and a resistor R3 is connected to the negative input terminal of an amplifier (comparator) AMP. The heat capacity of the resistor R3 is significantly larger than that of the resistor R2. The resistor R3 is disposed adjacent to the resistor R2 and thereby has roughly the same temperature at the same timing as the resistor R2. The solid line in FIG. 14 indicates the temperature change of the resistor R2 in response to intermittent driving of the heater 40. The dotted line in FIG. 14 indicates the temperature change of the resistor R3 in response to intermittent driving of the heater 40. As obvious from FIG. 14, the resistor R3 having a large heat capacity is hardly affected by the heat transferred through the gas. Therefore, the voltage input to the negative input terminal of the amplifier AMP is roughly constant. Since the magnitude relation between the resistance values of the resistors R2 and R3 is reversed as the resistance values follow the temperature change, the amplifier AMP can detect the phase of the temperature change. In this manner, it is possible to form a heat detection circuit with a relatively simple configuration. The main difference between the resistors R2 and R3 is the exposed area within the gas passage 22. Therefore, it does not impose any large burden in terms of the manufacturing process.

### Fourth Embodiment

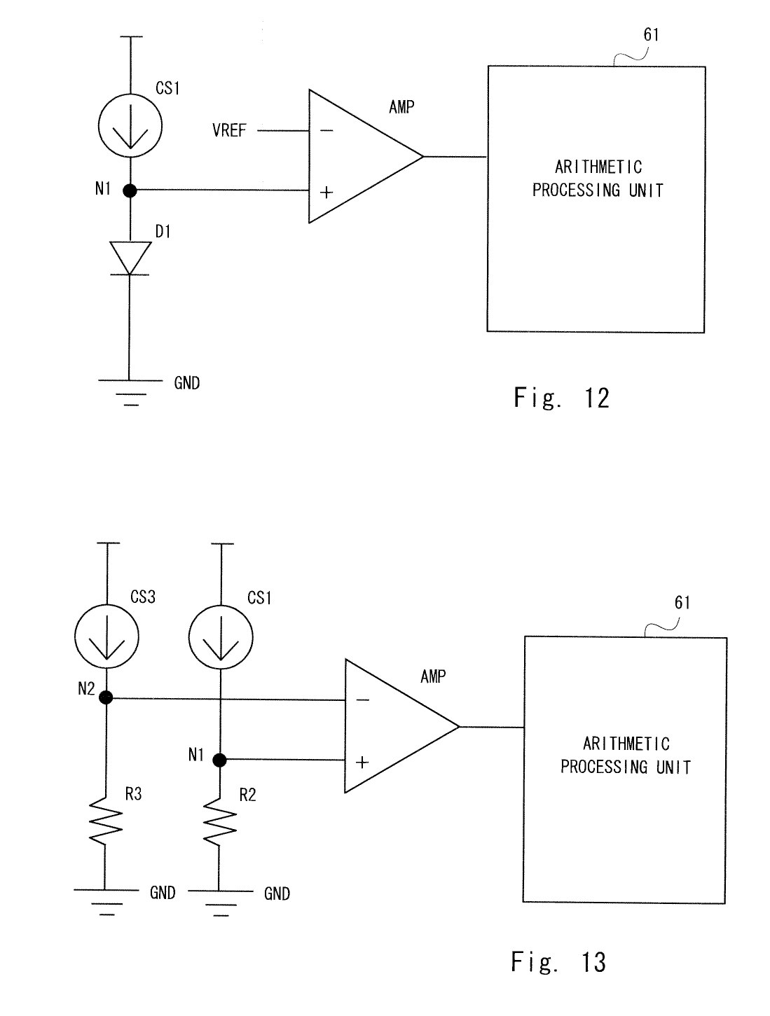

A fourth embodiment according to the present invention is explained with reference to FIGS. 15 and 16. In this embodiment, a current flows through the resistor R1, i.e., the heater 40 in a forward direction and a reverse direction in a time-division manner. As explained in the above-described embodiments, the heater 40 includes a narrow line that generates heat as a current flows therethrough. Therefore, if the current flowing direction is fixed, there is a possibility that the narrow line could deteriorate due to the electro-migration. This embodiment takes this matter into consideration, and the current flowing direction through the heater 40 is reversed at proper intervals so that the deterioration of the line constituting the heater 40 is minimized. In this way, it is possible to extend the life span of the heater 40 and thereby provide an acceleration sensor having higher reliability.

FIG. 15 is a circuit diagram showing a heater drive circuit. FIG. 16 is a timing chart showing an operation of the heater drive circuit.

As shown in FIG. 15, the drive circuit of the heater 40 includes MOS transistors M2 to M5, a resistor R1, and a controller 65. The MOS transistors M2 and M4 are connected in series between a power-supply potential VDD and a ground potential GND. The MOS transistors M3 and M5 are connected in series between the power-supply potential VDD and the ground potential GND. The resistor R1 is disposed between the node between the MOS transistors M2 and M4 and the node between the MOS transistors M3 and M5. The On/Off of each MOS transistor is controlled by the controller 65 as shown in FIG. 16.

As shown in FIG. 16, during a period from a time t1 to a time t2, the transistors M3 and M4 are turned on and the transistors M2 and M5 are turned off. When FIG. 15 is viewed from the front, a current flows through the resistor R1 from the left to the right (in forward direction). During a period from the time t2 to a time t3, the transistors M2 to M5 are turned on. Therefore, no current flows through the resistor R1. During a period from the time t3 to a time t4, the transistors M3 and M4 are turned off and the transistors M2 and M5 are turned on. When FIG. 15 is viewed from the front, a current flows through the resistor R1 from the right to the left (in reverse direction). During a period from the time t4 to a time t5, the transistors M2 to M5 are turned on. Therefore, no current flows through the resistor R1. By repeating this cycle, a current flows through the resistor R1, i.e., the heater 40 in forward/reverse directions in a time-division manner, thus making it possible to minimize the aged deterioration of the heater 40.

### Fifth Embodiment

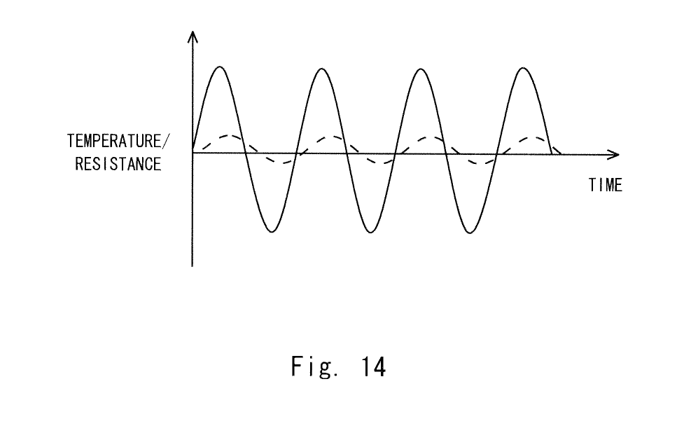

A fifth embodiment according to the present invention is explained with reference to FIG. 17. In this embodiment, in addition to the configuration of the above-described embodiment, a cover plate (cover member) 80 is disposed over the protection layer 21 and the gas passage 22 is thereby covered from above as shown in FIG. 17. In this way, the top of the gas passage 22 is closed. Therefore, it is possible to effectively prevent the heat transferred from the heater 40 to the gas contained in the gas passage 22 from diffusing upward. Preferably, a glass plate or a ceramic plate, which has a lower heat conductivity than that of the semiconductor, may be used as the cover plate 80. The cover member covering the gas passage 22 is not limited to plate-like members like the cover plate 80.

### Sixth Embodiment

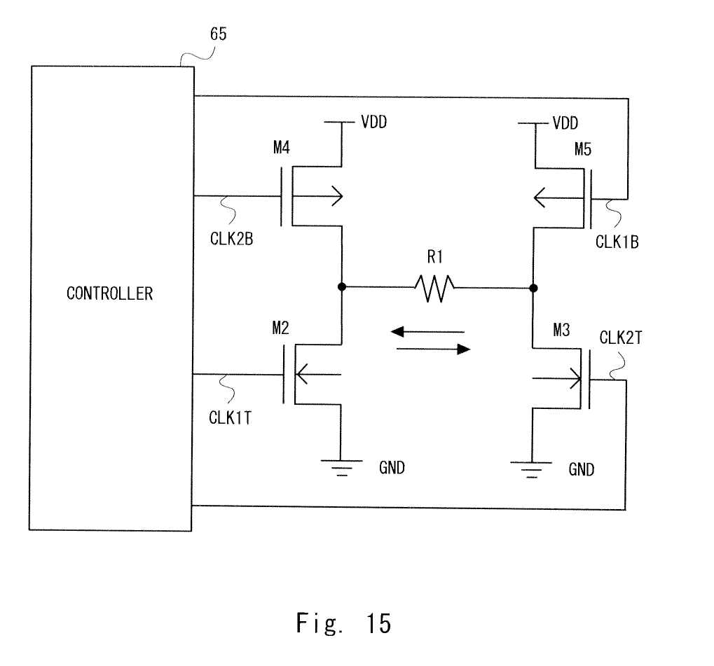

A sixth embodiment according to the present invention is explained with reference to FIG. 18. In this embodiment, in addition to the configuration of the above-described embodiment, the gas passage 22 is formed by a protection layer 21 located between the wall lines 20a and 20b as shown in FIG. 18. When the protection layer make inroads between the wall lines, a cave that can serves as a gas passage is formed between the wall lines as shown in FIG. 18. As shown in FIG. 18, the width of the gas passage 22 becomes narrower as the distance from the semiconductor substrate SUB increases (W1>W2). In this way, it is possible to create a state where the top of the gas passage 22 becomes narrower, thus making it possible to prevent the gas heated by the heater 40 from escaping upward. By confining the gas heated by the heater 40 inside the gas passage 22, it is possible to improve the accuracy of the gas temperature detection by the thermal sensors 30 and 50.

### Seventh Embodiment

A seventh embodiment according to the present invention is explained with reference to FIG. 19. In this embodiment, in contrast to the above-described embodiment, the gas passage 22 is formed by disposing a plate member having a long opening formed therein over the substrate (over the wiring structure layers), instead of forming the gas passage 22 by shaping the wiring layer 20 into a desired pattern. Even in the case like this, similar advantageous effects to those of the above-described embodiments can be obtained.

As shown in FIG. 19, a plate member (uppermost layer wiring structure) 25 is disposed above the substrate (semiconductor substrate SUB and wiring structure layers L1 to L3). The plate member 25 is, for example, a glass plate, a ceramic plate, or the like. An opening is formed in the plate member 25, and this opening serves as the gas passage 22. Note that in FIG. 19, the illustration of the heater, the thermal sensors, and the like is omitted for the sake of explanation. The specific method for stacking the plate member above the substrate can be arbitrarily determined. For example, the plate member is preferably stacked above the substrate by bonding the plate member to the substrate. The method for fixing the plate member to the substrate can be also arbitrarily determined. For example, the plate member is fixed on the substrate with an adhesive interposed therebetween. In this case, the adhesive is applied to such an extent that no adhesive infiltrates into the gas passage 22.

### Eighth Embodiment

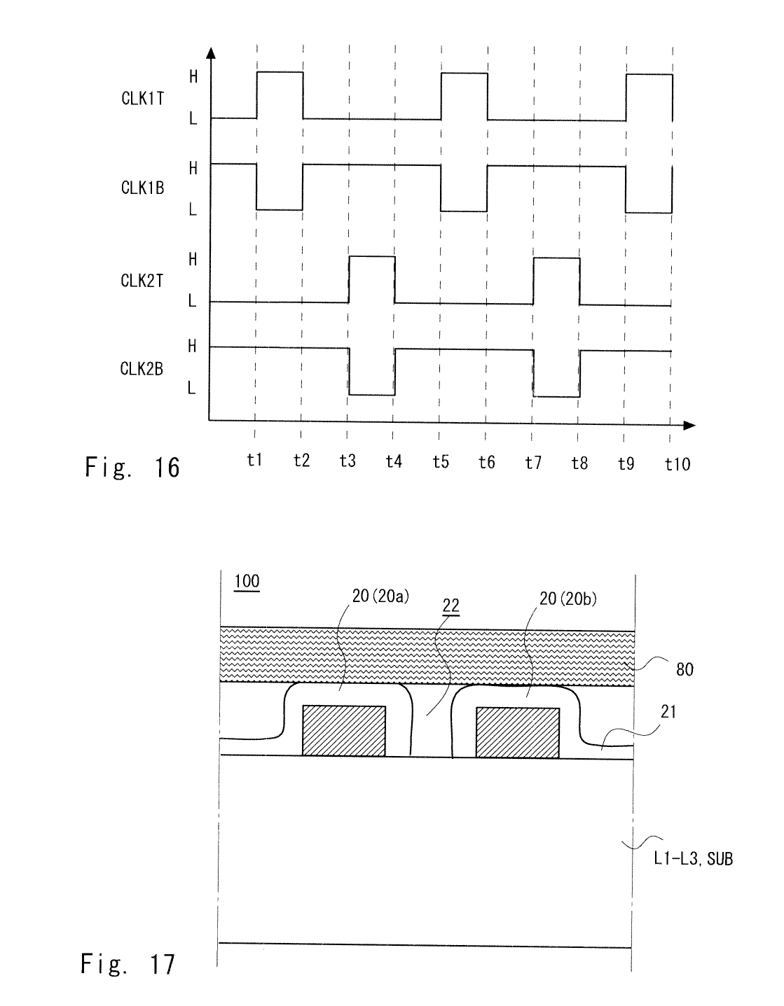

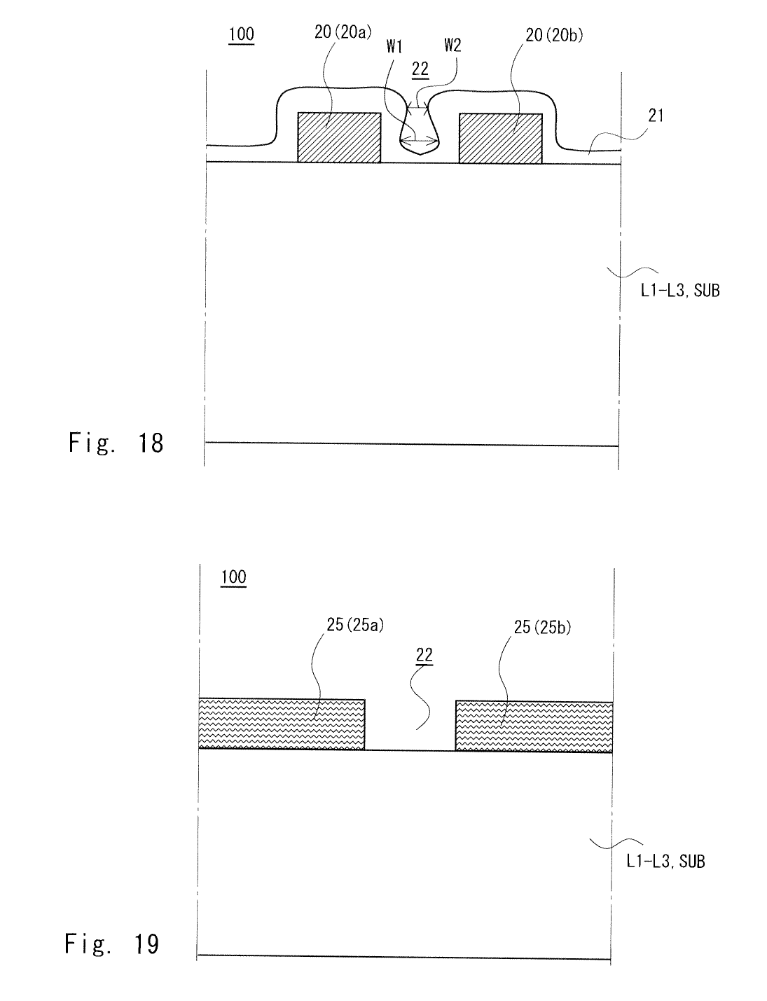

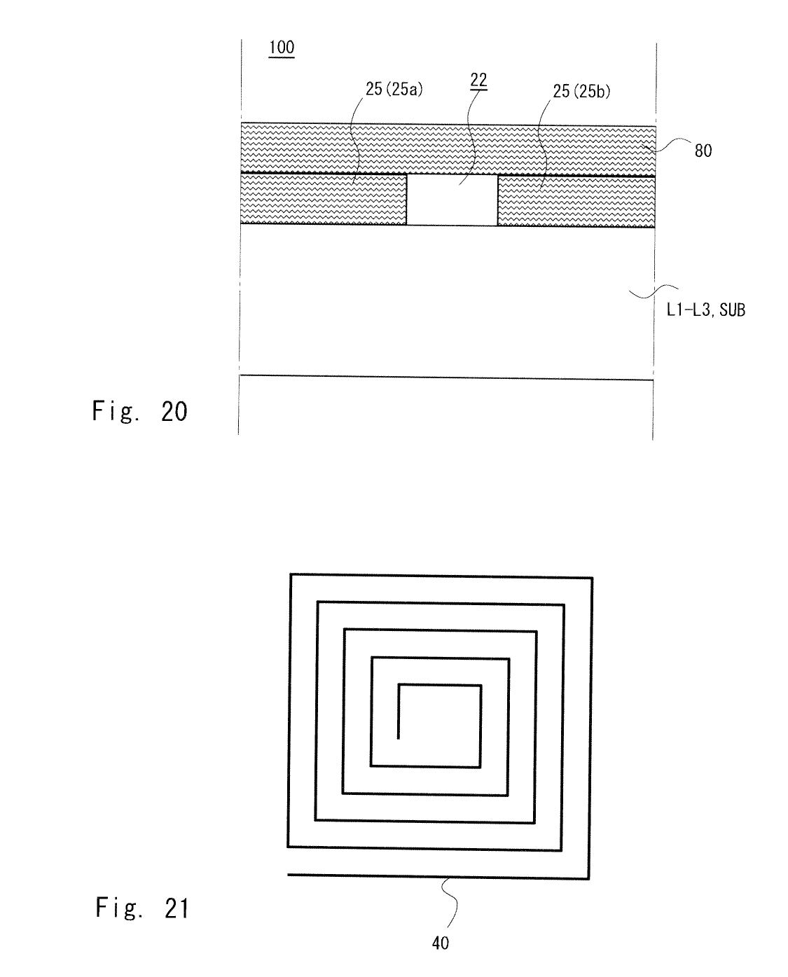

An eighth embodiment according to the present invention is explained with reference to FIG. 20. In this embodiment, a cover plate 80 shown in FIG. 17 is applied to the embodiment shown in FIG. 19. Even in the case like this, similar advantageous effects to those of the above-described embodiments can be obtained.

### Ninth Embodiment

A ninth embodiment according to the present invention is explained with reference to FIG. 21. In this embodiment, the heater is formed by laying out a different wiring pattern from that shown in FIG. 4. Even in the case like this, similar advantageous effects to those of the above-described embodiments can be obtained. As shown in FIG. 21, the heater is formed by a line laid out in a spiral pattern. One end of the line is connected to a line located in the wiring structure layers through a trench. The other end of the line is also connected in a similar manner. The heater shown in FIG. 21 is disposed in a rectangular area with each side about 9.6 μM long. The thermal sensor may be also configured in a similar wiring pattern to that shown in FIG. 21.

### Tenth Embodiment

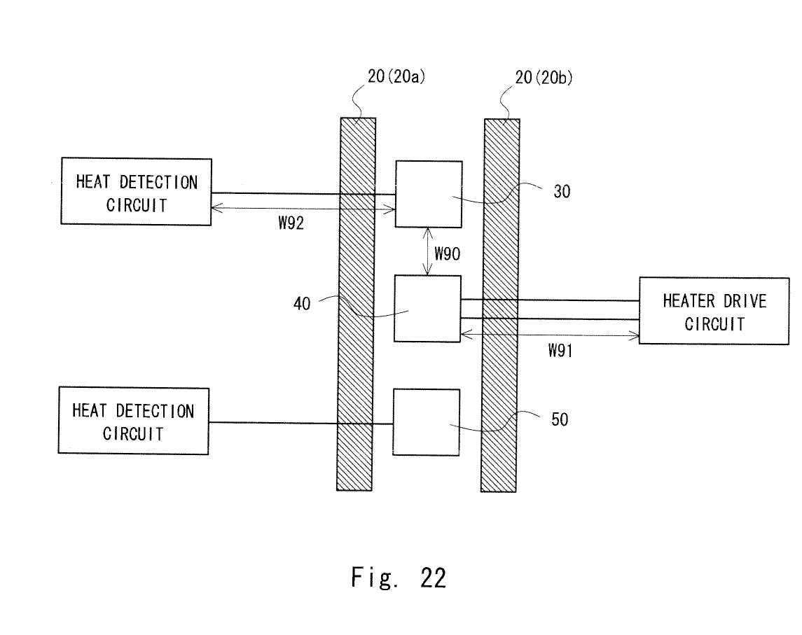

A tenth embodiment according to the present invention is explained with reference to FIG. 22. In this embodiment, the heat detection circuit and the heater drive circuit are disposed in places distant from the thermal sensor 30, the heater 40, and the thermal sensor 50 in order to avoid the characteristic fluctuations caused by the heat generated by the heater 40. More preferably, as can be seen from the positional intervals schematically shown in FIG. 22, the distance between the heater 40 and the heater drive circuit (e.g., distance W91) is longer than the distance between the heater 40 and the thermal sensor 30 (e.g., distance W90). Similarly, the distance between the thermal sensor 30 and the heat detection circuit (e.g., distance W92) is longer than the distance between the heater 40 and the thermal sensor 30. In this way, it is possible to advantageously prevent the characteristic of each circuit from fluctuating due to the thermal effect caused by the heater 40. Note that other features are similar to the above-described embodiment, and therefore duplicated explanation is omitted. Even in this embodiment, similar advantageous effects to those explained with the above-described embodiments can be obtained.

### Eleventh Embodiment

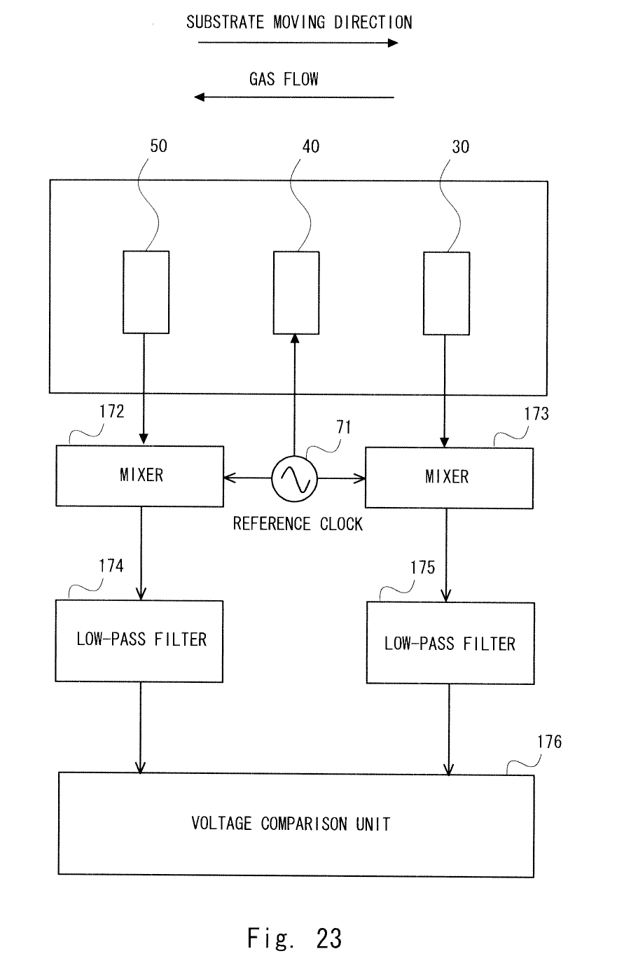

An eleventh embodiment according to the present invention is explained with reference to FIG. 23. In this embodiment, a detection configuration shown in FIG. 23 is adopted. As shown in FIG. 23, the output of the thermal sensor 50 is mixed with the clock signal of the heater 40, and the low frequency component of the output signal from the mixer 172 is selectively passed through a low-pass filter 174. Further, the output of the thermal sensor 30 is mixed with the clock signal of the heater 40, and the low frequency component of the output signal from the mixer 173 is selectively passed through a low-pass filter 175. A voltage comparison unit 176 compares input voltage values from the low-pass filters 174 and 175 with each other.

When the semiconductor device 100 is not being accelerated, the output signals from the thermal sensors 30 and 50 substantially coincide with the clock signal of the heater 40. However, when the semiconductor device 100 is being accelerated, the clock signal is modulated by an amount corresponding to the heat conduction through the gas. By mixing the modulated signal output from the thermal sensor 30 or 50 with the clock signal, a signal in which a signal having a frequency component twice as high as the clock signal and a low frequency signal near DC are combined is obtained. By passing only the low frequencies through the low-pass filter, the signal near DC can be extracted. The output voltage value of the low-pass filter changes by an amount corresponding to the modulation caused by the heat conduction through the gas. Based on this principle, the voltage comparison unit 176 compares the output voltages from the low-pass filters 174 and 175 with each other. It becomes possible to detect an acceleration based on the comparison result of the voltage comparison unit 176. Note that other features are similar to the above-described embodiment, and therefore duplicated explanation is omitted. Even in this embodiment, similar advantageous effects to those explained with the above-described embodiments can be obtained.

### Twelfth Embodiment

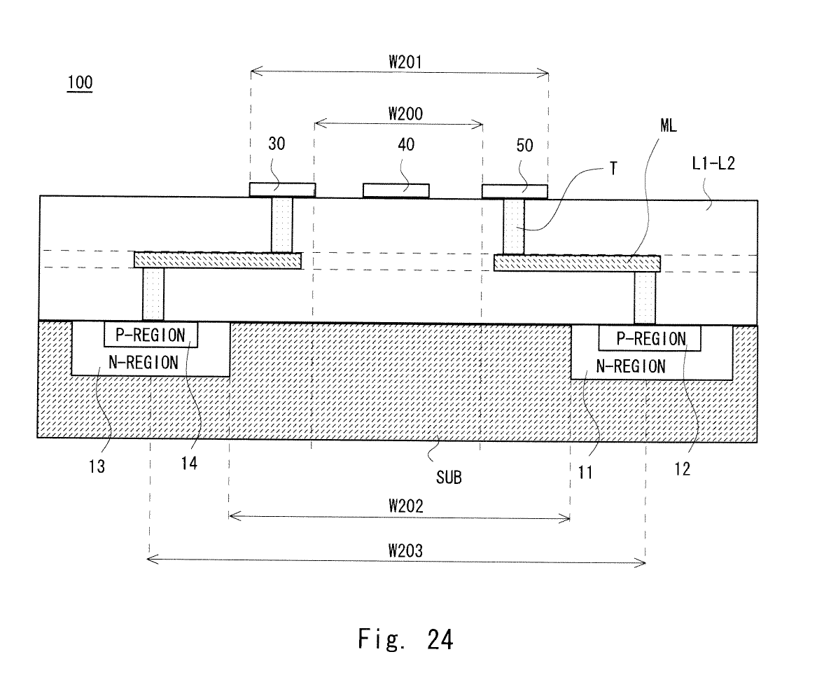

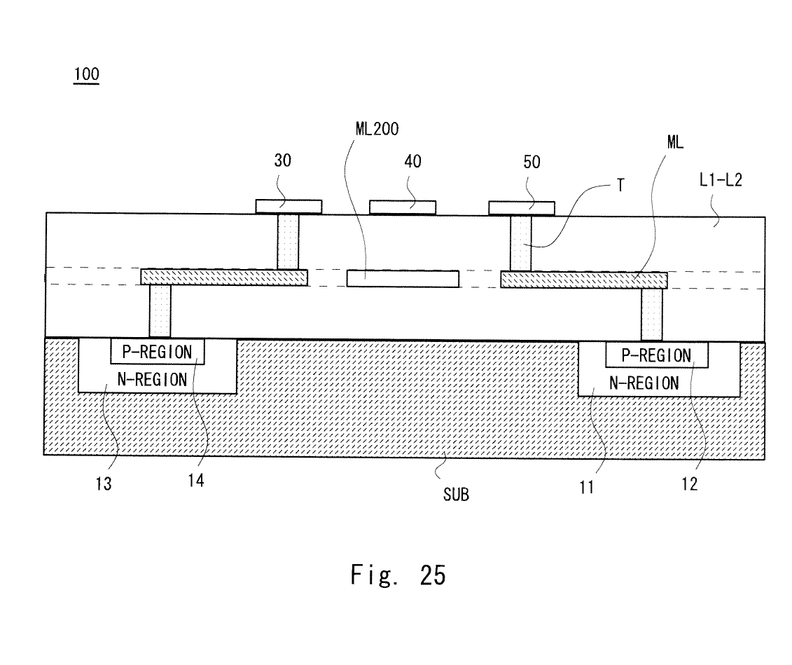

A twelfth embodiment according to the present invention is explained with reference to FIGS. 24 and 25. In this embodiment, as shown in FIG. 24, the junction between the N-region 13 and the P-region 14 is located in a place distant from the thermal sensor 30. Similarly, the junction between the N-region 11 and the P-region 12 is located in a place distant from the thermal sensor 50. By securing the distance between the diodes in this manner, it is possible to reduce the effect of the heat conduction between the diodes through the semiconductor substrate SUB. Note that a relation “W200<W201<W202<W204” is satisfied.

As shown in FIG. 25, a line ML200 for dissipating the heat is preferably disposed between the heater 40 and the semiconductor substrate SUB, more specifically, directly below the heater 40. In this way, the heat conduction path from the heater 40 to the diodes through the semiconductor substrate SUB can be cut off, thus making it possible to improve the sensitivity of the thermal sensor to the heat transferred through the gas. Preferably, the line ML200 is desirably fixed to the ground or a fixed potential. Since the wiring line for fixing the potential of the line ML200 becomes a heat conduction path, the wiring line is preferably disposed near the line for driving the heater. Further, the node that connects this wiring line to the ground or the fixed potential is preferably disposed near the heater drive circuit. Other features are similar to the above-described embodiment, and therefore duplicated explanation is omitted. Even in this embodiment, similar advantageous effects to those explained with the above-described embodiments can be obtained.

### Thirteenth Embodiment

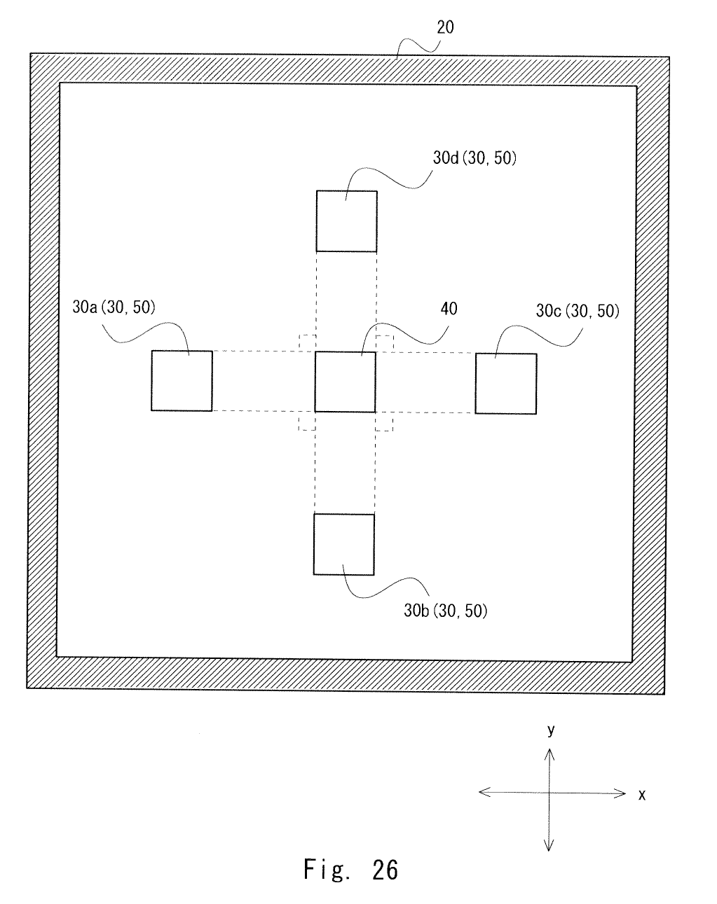

A thirteenth embodiment according to the present invention is explained with reference to FIG. 26. In this embodiment, as shown in FIG. 26, four thermal sensors 30 (50) are disposed around the heater 40. The four thermal sensors 30 are arranged at 90-degree intervals around the heater 40.

In other words, this embodiment can be described as follows. Thermal sensors 30a and 30c are arranged symmetrically with respect to the heater 40. Thermal sensors 30b and 30d are arranged symmetrically with respect to the heater 40. The arrangement direction of the pair of the thermal sensors 30a and 30c is roughly perpendicular to the arrangement direction of the thermal sensors 30b and 30d.

By using this configuration, it is possible to detect an acceleration in the x-axis direction by the comparison between the outputs of the thermal sensors 30a and 30c, and detect an acceleration in the y-axis direction by the comparison between the outputs of the thermal sensors 30b and 30d. In this way, it is possible to detect displacements in multiple directions with a smaller configuration. Note that other features are similar to the above-described embodiment, and therefore duplicated explanation is omitted. Even in this embodiment, similar advantageous effects to those explained with the above-described embodiments can be obtained.

Note that the present invention is not limited to the above-described embodiments, and various modifications can be made without departing from the spirit and scope of the present invention. The specific material of the uppermost layer wiring structure can be arbitrarily determined, and it may be formed by an insulating layer. The lines constituting the heater, the thermal sensor, and so on may be made of polysilicon or the like. The extension form of the gas passage can be also arbitrarily determined, and it is not limited to straight-line shapes.

### Fourteenth Embodiment

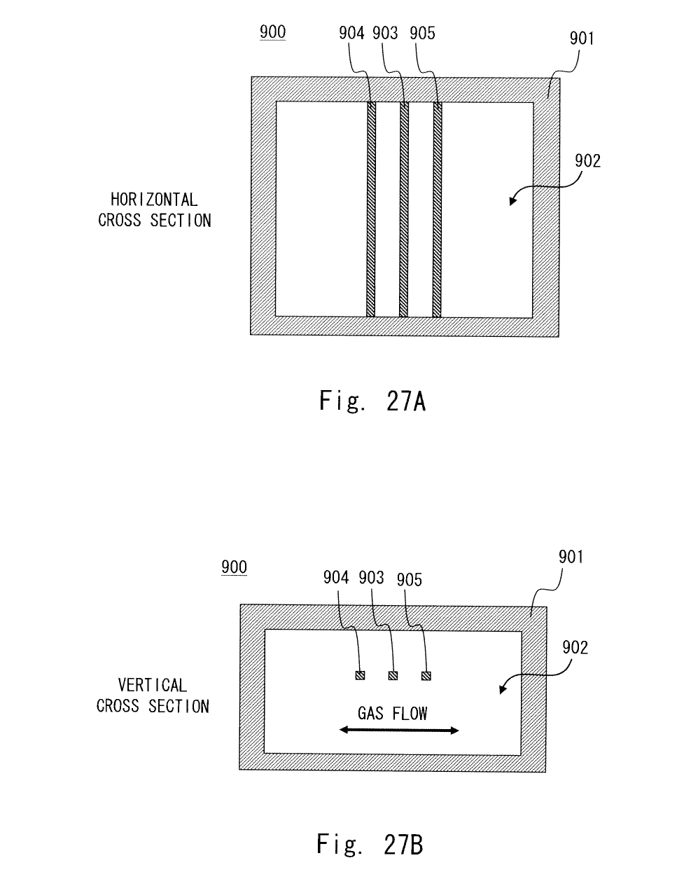

To make the difference between the present invention and related art clear, a reference example to which the present invention is not applied is explained hereinafter. FIGS. 27A and 27B are a horizontal cross section and a vertical cross section of a reference example obtained by sealing and forming a thermal type acceleration sensor disclosed in Patent literature 1.

In the acceleration sensor 900 of the reference example, a chamber (hollow portion) 902 filled with a gas is dug-in and formed inside a silicon substrate 901. A heater 903 is disposed at the center of the chamber 902 as viewed from the top and as viewed from the side. The heater 903 extends from one side of the acceleration sensor 900 to the opposed side. Thermal sensors 904 and 905 are disposed on both sides of the heater 903. The thermal sensors 904 and 905 extend from one side of the acceleration sensor 900 to the opposed side. That is, in the acceleration sensor 900 of the reference example, since the internal chamber 902 is formed by cutting away the inside of the silicon substrate 901, the chamber 902 has a similar outside shape to that of the silicon substrate 901, i.e., has a rectangular horizontal cross section and a rectangular vertical cross section. Further, the heater 903 and the thermal sensors 904 and 905 are formed in such a state that they are suspended inside the chamber 902.

In the acceleration sensor 900 of the reference example, the gas contained in the chamber 902 is heated by the heater 903 and the temperature of the gas is detected by the thermal sensors 904 and 905. When the acceleration sensor 900 of the reference example moves, the gas contained in the chamber 902 cannot follow the movement of the acceleration sensor 900 and thereby flows in the opposite direction to the moving direction of the acceleration sensor 900. As a result, the temperature distribution of the gas becomes asymmetrical between the positions of the thermal sensors 904 and 905 located on both sided of the heater 903. Therefore, in the acceleration sensor 900 of the reference example, an acceleration exerted on the acceleration sensor 900 is detected by comparing the outputs of the thermal sensors 904 and 905.

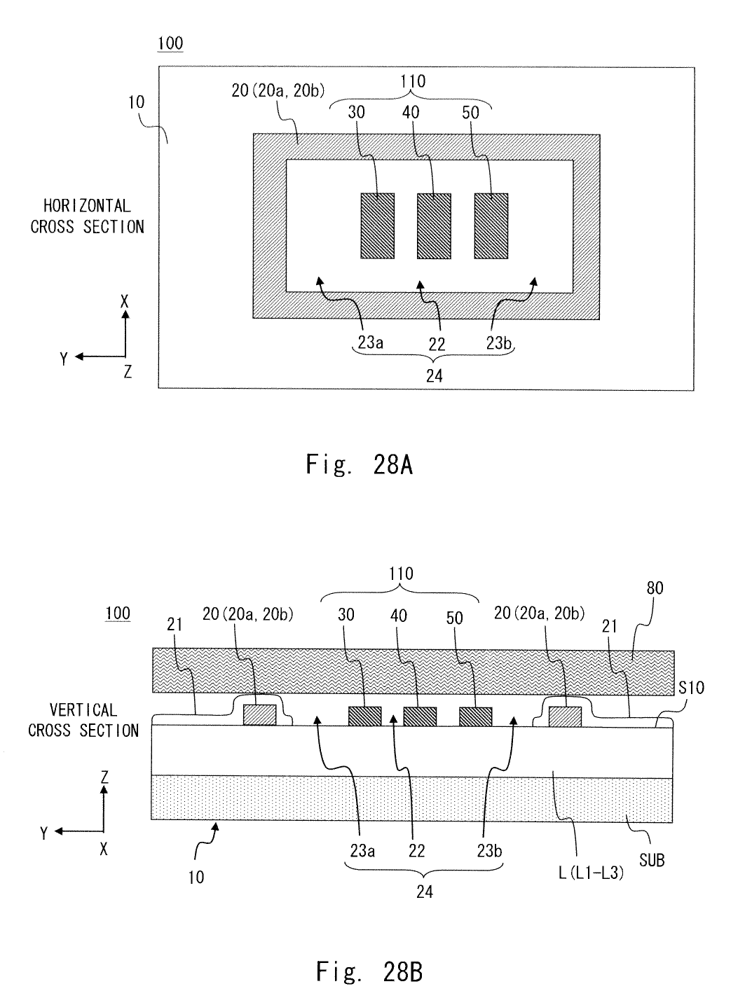

Next, a semiconductor device 100 according to this embodiment of the present invention is explained with reference to FIGS. 28A and 28B. FIGS. 28A and 28B are a horizontal cross section and a vertical cross section of a semiconductor device 100 according to this embodiment.

Since FIG. 1 shows only a part of the semiconductor device 100, it shows only the wall lines 20a and 20b extending in the Y-direction. In contrast to this, FIGS. 28A and 28B show the entire wall line that forms a hollow portion to be filled with a gas.

As shown in FIGS. 28A and 28B, the semiconductor device 100 includes a stacked body 10, an uppermost layer wiring stricture 20 (wall wrings 20a and 20b), a thermal sensor 30, a thermal sensor 50, and a heater 40. Note that since the wall line is formed as a continuous line, the entire wall line is referred to as “20a” or “20b” in the following explanation.

The stacked body 10 includes a semiconductor substrate SUB and a wiring structure layer L. The semiconductor substrate SUB is a silicon substrate. Similarly to FIG. 2, the wiring structure layer L includes wiring structure layers L1 to L3, and each wiring structure layer includes an interlayer insulating film and a wiring layer. Further, the uppermost layer wiring stricture 20 is metal lines (wiring layer) formed in the uppermost layer, and constitutes the wall line 20a.

In this example, the wall line 20a, the heater 40, and the thermal sensors 30 and 50 are formed in the same uppermost layer. The heater 40 is disposed in the uppermost layer of the stacked body 10, and the thermal sensors 30 and 50 are disposed on both sides of the heater 40 in the Y-direction. Note that each line or all lines of the heater 40 and the thermal sensors 30 and 50 is also referred to as “heater/thermal sensor line 110”.

The wall line 20a (20b) that confines the gas flow is disposed so as to surround the heater/thermal sensor line 110 in a roughly rectangular shape as viewed from the top. The upper surface S10 of the wiring structure layer L and the wall line 20a are covered by a protection layer 21 (cover film). The protection layer 21 is not formed in part of the upper surface S10 that is located inside the wall line 20a. That is, the heater/thermal sensor line 110 is not covered by the protection layer 21 and the surface of the lines is exposed to the gas.

Further, similarly to FIG. 17, a cover plate 80 is disposed above the protruding protection layer 21. The cover plate 80 is a glass substrate, a silicon substrate, or the like. The cover plate 80 is stuck over the entire upper surface of the wall line 20a with the protection layer 21 interposed therebetween.

As the wall line 20a comes into contact with the cover plate 80, the area surrounded by the wall line 20a becomes a closed hollow portion 24. That is, the hollow portion 24 is sealed and formed in a state where: the top of the hollow portion 24 is covered by the cover plate 80; the bottom is covered by the interlayer insulating film of the wiring structure layer L (L3) that is in contact with the uppermost layer; and the side is covered by the wall line 20a. Part of the space of the hollow portion 24 located near the heater/thermal sensor line 110 is referred to as “gas passage 22”, and part of the space located on both sides of the gas passage 22 in the Y-direction (gas flow direction) is referred to as “cavity 23 (23a and 23b). This hollow portion 24 is filled with a gas such as the air, nitrogen, or argon.

In the semiconductor device 100 having the configuration as shown in FIGS. 28A and 28B, the gas contained in the hollow portion 24 is heated by the heater 40 and the temperature distribution of the gas is measured by the thermal sensors 30 and 50 as shown in FIGS. 7 and 8. By doing so, an acceleration can be detected based on the temperature difference between the thermal sensors 30 and 50.

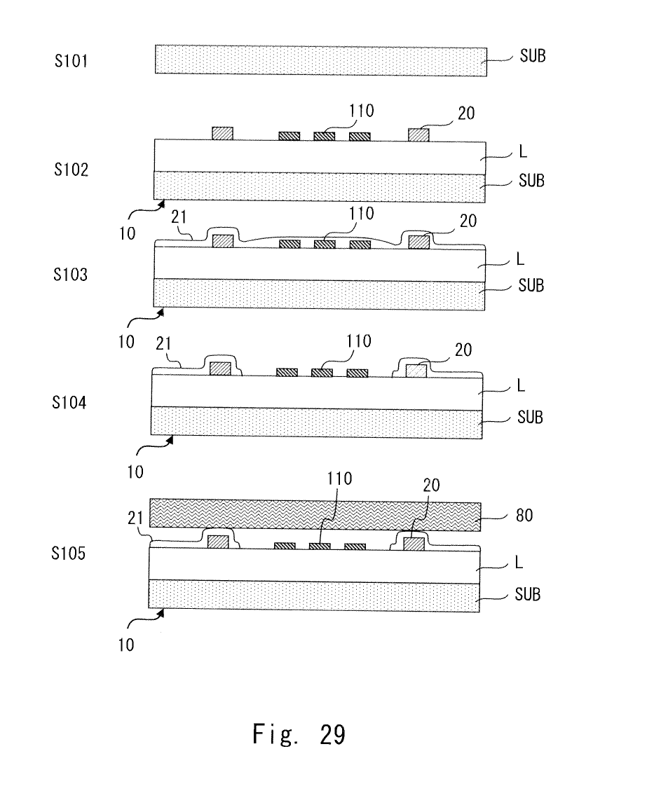

Next, a method of manufacturing the semiconductor device 100 shown in FIGS. 28A and 28B is explained with reference to FIG. 29. Firstly, in a step S101, a semiconductor substrate SUB is prepared and MISFETs (Metal Insulator Semiconductor Field Effect Transistors) that constitute a heat detection circuit and the like (not shown) are formed on the semiconductor substrate SUB.

Next, in a step S102, a wiring structure layer L and an uppermost layer wiring stricture 20 are formed on the semiconductor substrate SUB formed in the step S101. That is, the wiring structure layer L including a wiring layer(s) and an interlayer insulating film(s) is stacked and formed on the semiconductor substrate SUB, and a wall line 20a and a heater/thermal sensor line 110 are formed on the wiring structure layer L as the uppermost layer wiring. For the interlayer insulating film, a substance obtained by mixing carbon into a silicon oxide, or a silicon oxide may be used.

Next, in a step S103, a protection layer 21 is deposited over the entire upper surface of the stacked body 10 formed in the step S102. That is, the protection layer 21 is formed so as to cover the entire upper surface of the wiring structure layer L, the wall line 20a, and the heater/thermal sensor line 110. In this example, the material of the protection layer 21 is polyimide.

Next, in a step S104, part of the protection layer 21 located near the heater/thermal sensor line 110 is removed by performing exposure to light on the upper surface of the stacked body 10 formed in the step S103. That is, part of the protection layer 21 is removed by performing exposure to light on the upper surface of the wiring structure layer L and the heater/thermal sensor line 110 located inside the wall line 20a, so that the interlayer insulating film of the wiring structure layer L and the heater/thermal sensor line 110 are exposed.

Next, in a step S105, a cover plate 80 is stuck on and thereby bonded to the top of the stacked body 10 formed in the step S104. That is, part of the protection layer 21 that protrudes from the remaining part of the protection layer 21 due to the presence of the wall line 20a is brought into contact with and thereby bonded to the cover plate 80. Through the above-described processes, the semiconductor device 100 shown in FIGS. 28A and 28B is formed.

As described above, in the semiconductor device according to this embodiment of the present invention, a hollow portion that is to be filled with a gas is formed by the wall line on the stacked body uppermost layer, and a heater and a plurality of thermal sensors are disposed inside the hollow portion. The gas present above the stacked body is heated by the heater and its temperature is detected by the thermal sensors. By doing so, an acceleration exerted on the semiconductor device can be detected.

As described previously, in the acceleration sensor of the reference example as shown in FIGS. 27A and 27B, it is necessary to cut away the inside of the silicon substrate to form the chamber and to dispose the heater and the thermal sensors inside the chamber in a suspended state. As a result, it is very difficult to manufacture the acceleration sensor. In the present invention, since the acceleration sensor uses the semiconductor device configuration as shown in FIGS. 28A and 28B, the acceleration sensor can be manufactured by using an ordinary semiconductor process as shown in FIG. 29. As a result, it is possible to improve the manufacturing efficiency and to achieve higher packing density.

### Fifteenth Embodiment

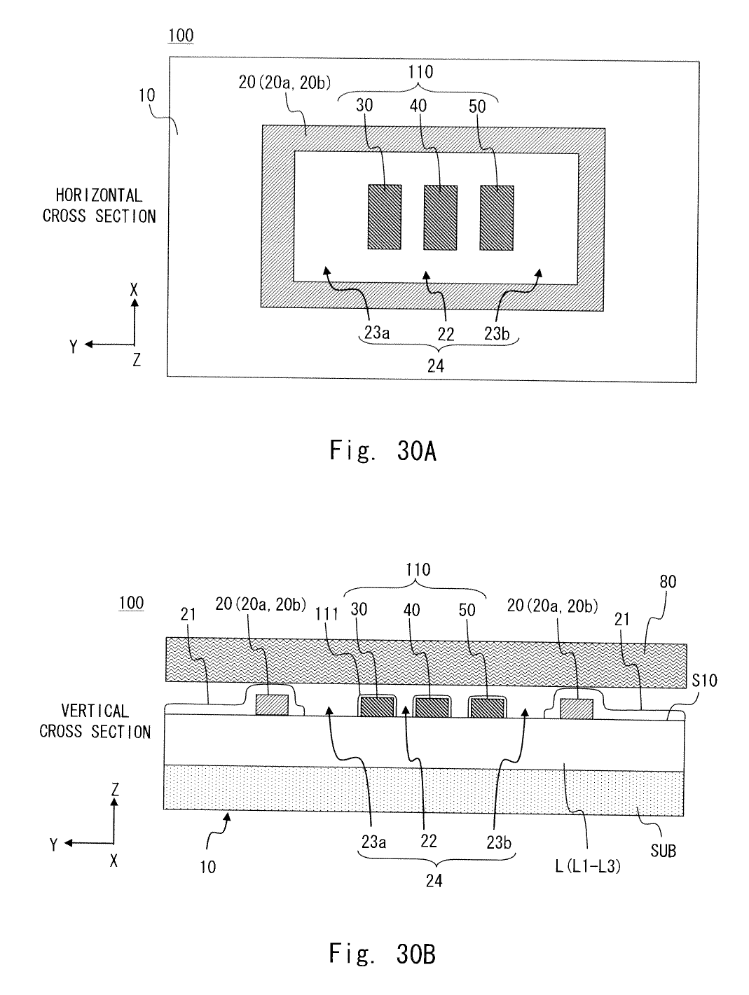

A semiconductor device 100 according to this embodiment of the present invention is explained with reference to FIGS. 30A and 30B. FIGS. 30A and 30B are a horizontal cross section and a vertical cross section of a semiconductor device 100 according to this embodiment.

In the semiconductor device 100 shown in FIGS. 30A and 30B, in comparison to the semiconductor device 100 shown in FIGS. 28A and 28B, a cover film 111 is formed over the heater/thermal sensor line 110. The other configuration is similar to that shown in FIGS. 28A and 28B.

That is, the exposed portion of the heater/thermal sensor line 110 is covered by a cover film 111 for the heater/thermal sensor. The cover film 111 is formed so as to cover the entire upper surface and side surface of the heater/thermal sensor line 110 that are otherwise exposed to the gas. Examples of the material of the cover film 111 include organic materials such as polyimide, oxide films such as SiO2, and nitride films such as SiN, TiN and TaN.

By forming a cover film over the heater/thermal sensor line 110 as described above, the heater/thermal sensor line 110 is not directly exposed to the gas. As a result, it is possible to prevent the metal material of the heater/thermal sensor line 110 from being corroded or broken due to the contact with the gas.

Further, the cover film 111 is preferably formed with a thickness thinner than that of the protection layer (protection film) for the other components such as the wall line 20a. By forming the cover film 111 as a thin film, the heat conductivity improves, thus making it possible to improve the heat generating efficiency of the heater and/or the detection sensitivity of the thermal sensor.

### Sixteenth Embodiment

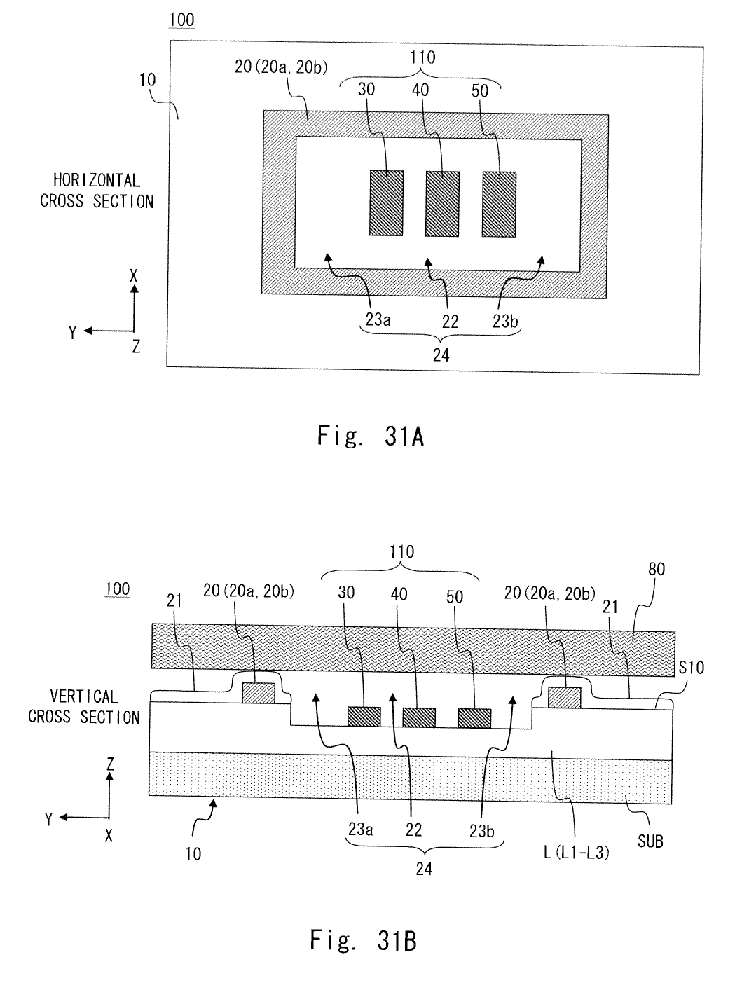

A semiconductor device 100 according to this embodiment of the present invention is explained with reference to FIGS. 31A and 31B. FIGS. 31A and 31B are a horizontal cross section and a vertical cross section of a semiconductor device 100 according to this embodiment. When the semiconductor device 100 shown in FIGS. 31A and 31B is compared with the semiconductor device 100 shown in FIGS. 28A and 28B, the layer level of the wiring layer in which the heater/thermal sensor line 110 is formed is different, but other configurations are similar. In the semiconductor device 100 shown in FIGS. 28A and 28B, the heater/thermal sensor line 110 is formed in the same uppermost layer as the wall line 20a. In contrast to this, in the semiconductor device 100 according to this embodiment shown in FIGS. 31A and 31B, the heater/thermal sensor line 110 is formed in a wiring layer that is located below the wall line 20a.

For example, the wiring structure layer L includes wiring structure layers L1 to L3, and the heater/thermal sensor line 110 is formed in the wiring layer of the wiring structure layer L3 (intermediate layer), which is located immediately below the uppermost layer. Inside the wall line 20a, the surface of the stacked body is dug down to the upper surface of the wiring structure layer L2.

The hollow portion 24 is sealed and formed in a state where: the top of the hollow portion 24 is covered by the cover plate 80; the bottom is covered by the interlayer insulating film of the intermediate layer of the wiring structure layer L (L2); and the side is covered by the wall line 20a and the interlayer insulating film of the wiring structure layer L (L3) that is in contact with the uppermost layer. That is, the hollow portion 24 shown in FIGS. 31A and 31B is formed with a larger depth by an amount equivalent to the thickness of the wiring structure layer L3 in comparison to the hollow portion 24 shown in FIGS. 28A and 28B.

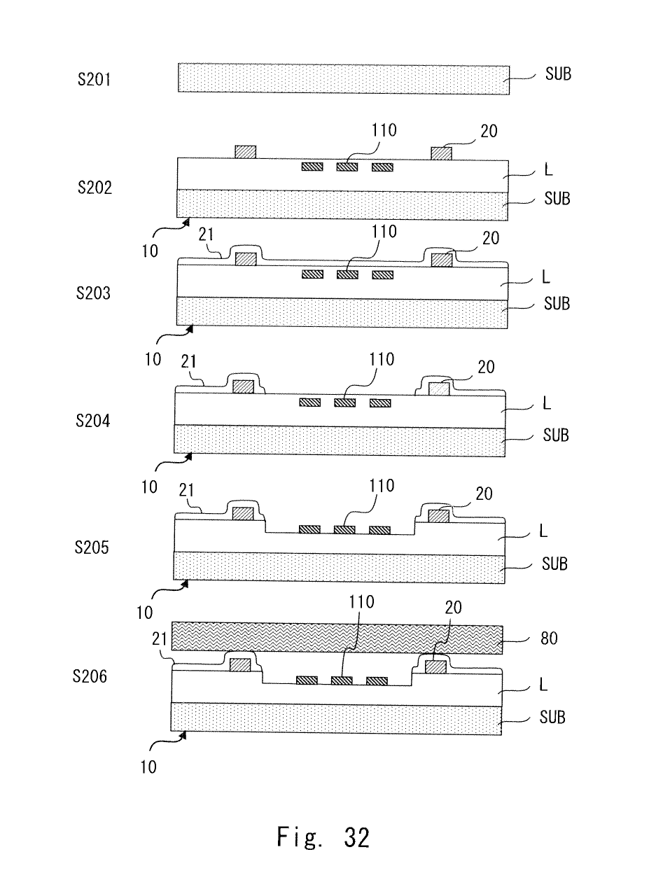

Next, a method of manufacturing the semiconductor device 100 shown in FIGS. 31A and 31B is explained with reference to FIG. 32. Note that the processes shown in FIG. 32 is different from those shown in FIG. 29 in the formation place of the heater/thermal sensor line 110 and in the etching process for exposing the heater/thermal sensor line 110, but the other processes are similar.

Firstly, in a step S201, a semiconductor substrate SUB is prepared and MISFETs that constitute a heat detection circuit and the like (not shown) are formed on the semiconductor substrate SUB.

Next, in a step S202, a wiring structure layer L and an uppermost layer wiring stricture 20 are formed on the semiconductor substrate SUB formed in the step S201. That is, the wiring structure layer L including a wiring layer(s) and an interlayer insulating film(s) is stacked and formed on the semiconductor substrate SUB, and a heater/thermal sensor line 110 is formed on the wiring layer of the wiring structure layer L3 as the intermediate layer wiring. An interlayer insulating film is formed on the heater/thermal sensor line 110, and a wall line 20a is formed on that interlayer insulating film as the uppermost layer wiring.

Next, in a step S203, a protection layer 21 is deposited over the entire upper surface of the stacked body 10 formed in the step S202. That is, the protection layer 21 is formed so as to cover the entire upper surface of the wiring structure layer L and the wall line 20a.

Next, in a step S204, part of the protection layer 21 located above the heater/thermal sensor line 110 and its vicinity is removed by performing exposure to light on the upper surface of the stacked body 10 formed in the step S203. That is, part of the protection layer 21 is removed by performing exposure to light on the upper surface of the wiring structure layer L located inside the wall line 20a, so that the interlayer insulating film of the wiring structure layer L is exposed.

Next, in a step S205, dry-etching is performed on the upper surface of the stacked body 10 formed in the step S204 by using the protection layer 21 as a mask so that part of the interlayer insulating film of the wiring structure layer L is removed. That is, for the inside area of the wall line 20a, the interlayer insulating film of the wiring structure layer L3 is etched and the heater/thermal sensor line 110, which is the wiring layer of the wiring structure layer L3, and the interlayer insulating film of the wiring structure layer L2 is thereby exposed.

Next, in a step S206, a cover plate 80 is stuck on and thereby bonded to the top of the stacked body 10 formed in the step S205. Through the above-described processes, the semiconductor device 100 shown in FIGS. 31A and 31B is formed.

As described above, in the semiconductor device according to this embodiment of the present invention, the hollow portion that is to be filled with a gas is formed by using the level difference formed by the wall line on the stacked body uppermost layer and the interlayer insulating film of the lower layer. By disposing a heater and a plurality of thermal sensors inside this hollow portion, heating the air present above the stacked body by the heater, and detecting the temperature by the thermal sensors, it is possible to detect a moving speed of the semiconductor device as in the case of the embodiment shown in FIGS. 28A and 28B. Further, an acceleration sensor can be manufactured by using an ordinary semiconductor process as in the case of the processes shown in FIG. 29.

Further, since the heater/thermal sensor line 110 is formed in the dug-down wiring structure layer L, the hollow portion 24 can be enlarged. In this embodiment, even when the thickness and the horizontal size of the wall line 20a are equal to those of the embodiment shown in FIGS. 28A and 28B, the volume of the hollow portion 24 can be made larger than that of the embodiment shown in FIGS. 28A and 28B. When the hollow portion is narrow, the gas cannot flow easily. Therefore, by enlarging the hollow portion, the gas can flow more easily, thus making it possible to improve the sensitivity of the acceleration sensor.

### Seventeenth Embodiment

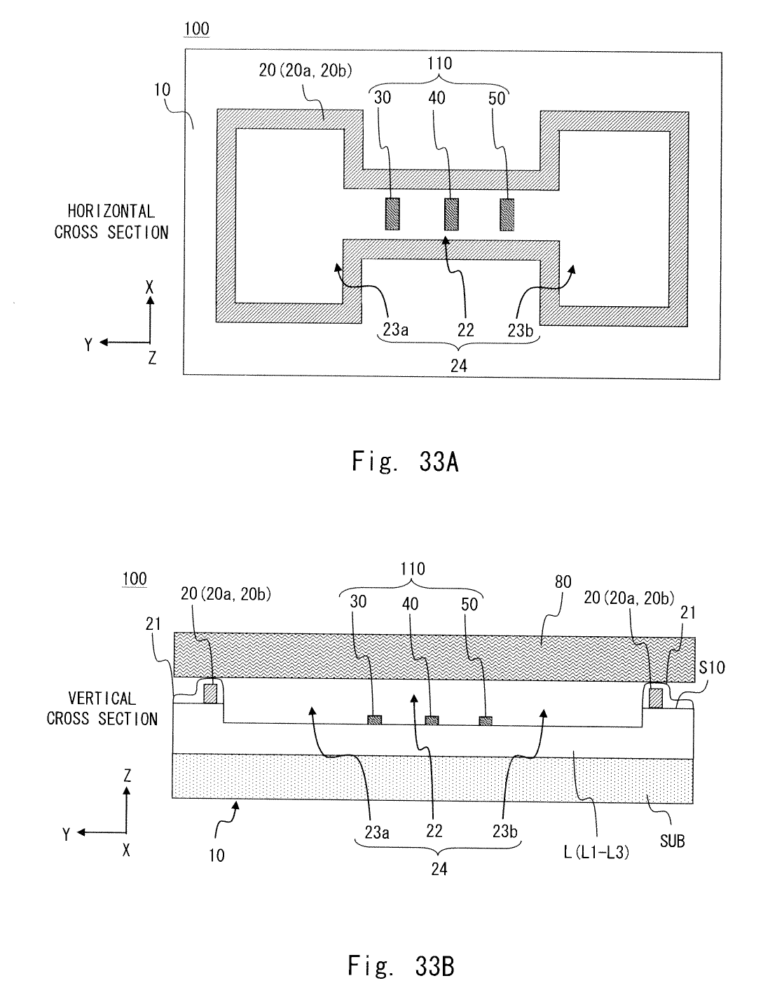

A semiconductor device 100 according to this embodiment of the present invention is explained with reference to FIGS. 33A and 33B. FIGS. 33A and 33B are a horizontal cross section and a vertical cross section of a semiconductor device 100 according to this embodiment.

In the semiconductor device 100 shown in FIGS. 33A and 33B, in comparison to the semiconductor device 100 shown in FIGS. 31A and 31B, the lay-out pattern of the wall line 20a and the shape of the hollow portion 24, which is defined and formed by the wall line 20a, are different. The other configuration is similar to that shown in FIGS. 31A and 31B. In the semiconductor device 100 shown in FIGS. 33A and 33B, similarly to the semiconductor device 100 shown in FIGS. 31A and 31B, the heater/thermal sensor line 110 is formed in a wiring layer that is located below the uppermost layer. In this manner, it is possible to provide a large space for the gas flow above the heater/thermal sensor line 110.

The shape of the hollow portion 24 in this embodiment, which is formed by the lay-out pattern of the wall line 20a, is explained hereinafter. In the semiconductor device 100 shown in FIGS. 31A and 31B, the horizontal cross section of the hollow portion 24 is roughly a rectangle with the long sides in the Y-direction, and therefore the width of the horizontal cross section is constant from the cavity 23a to the gas passage 22 and to the cavity 23b.

In contrast to this, in the semiconductor device 100 shown in FIGS. 33A and 33B, the width of the horizontal cross section of the hollow portion 24 in the X-direction (direction perpendicular to the gas flow) is significantly different between the area near the thermal sensors 30 and 50 and the other areas. That is, the width is narrower in the gas passage 22 where the thermal sensors 30 and 50 are located, and cavities 23a and 23b having a wider width are formed on both sides of the gas passage 22.

In FIGS. 33A and 33B, the horizontal cross section of each of the cavities 23a and 23b is roughly a rectangle with the long sides in the X-direction, and the length of the long side is longer than the width of the gas passage 22. Note that the only requirement for this embodiment is that the width of the cavities 23a and 23b is wider than the width of the gas passage 22. Therefore, the shape of the cavities is not limited to rectangles. That is, examples of the shape of the cavities include squares and other polygons. Further, the only requirement for this embodiment may be that the width of the gas passage 22 is narrower in the vicinity of the thermal sensors 30 and 50. For example, the width may be wider near the heater 40 than the width near the thermal sensors 30 and 50.

When the semiconductor device 100 moves, the gas contained in the hollow portion 24 cannot follow the movement of the semiconductor device 100. As a result, a gas flow occurs in the opposite direction to the movement of the semiconductor device 100. When the gas in the cavity 23a moves to the cavity 23b, the gas needs to pass through the gas passage 22 near the thermal sensors 30 and 50. When the gas in the cavity 23a having a larger space tries to pass through the gas passage 22 having a narrower space (bottleneck), the gas having a large volume suddenly enters the bottleneck, thereby causing an increase in the gas pressure.

As a result, when the gas passes through the gas passage 22, the flow speed of the gas becomes faster than that in the cavities 23a and 23b. As the gas flow becomes faster in the gas passage 22, the transfer speed of the heat also becomes faster due to the faster gas flow. Further, the quantity of the transferred heat also increases. Therefore, in comparison to the case where there is no bottleneck portion, the temperature change of the sensor becomes faster and larger, thus making it possible to improve the sensitivity of the acceleration sensor.

As described above, in the acceleration sensor like the reference example shown in FIGS. 27A and 27B or the one shown in FIGS. 31A and 31B, the shape of the hollow portion that hermetically contains the gas is unchanged between the area of the thermal sensors and the other areas. Therefore, the gas flow speed is also unchanged. Accordingly, the gas flow speed cannot be controlled. Therefore, to improve the sensitivity of the acceleration sensor, it is necessary to increase the size of the hollow portion and/or the size of the heater/thermal sensor line.

In this embodiment, in the acceleration sensor that detects a gas flow above the stacked body, part of the area through which the gas flows is narrowed so that the gas flow in that part becomes faster than that in the other parts. By disposing the thermal sensors in this part where the flow speed is higher, it is possible to improve the detection sensitivity to the gas temperature.

### Eighteenth Embodiment

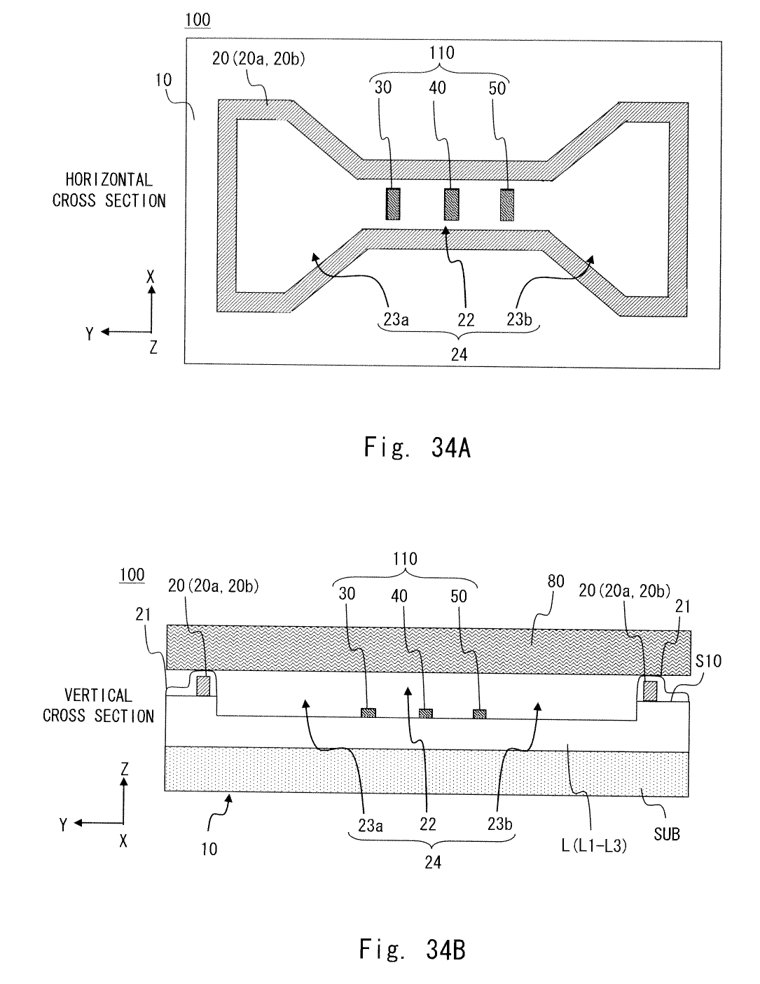

A semiconductor device 100 according to this embodiment of the present invention is explained with reference to FIGS. 34A and 34B. FIGS. 34A and 34B are a horizontal cross section and a vertical cross section of a semiconductor device 100 according to this embodiment.

In the semiconductor device 100 shown in FIGS. 34A and 34B, in comparison to the semiconductor device 100 shown in FIGS. 33A and 33B, the lay-out pattern of the wall line 20a and the shape of the cavities of the hollow portion 24, which is defined and formed by the wall line 20a, are different. The other configuration is similar to that shown in FIGS. 33A and 33B.

In the semiconductor device 100 shown in FIGS. 33A and 33B, each of the cavities 23a and 23b is roughly a rectangle with the long sides in the X-direction. The sides (wall lines) of the cavities 23a and 23b adjoin the sides (wall lines) of the gas passage 22 at the right angle.

In contrast to this, in the semiconductor device 100 shown in FIGS. 34A and 34B, the sides (wall lines) of the cavities 23a and 23b adjoin the sides (wall lines) of the gas passage 22 at an angle gentler than the right angle. That is, the width of the hollow portion 24, which is formed by the wall line 20a, is the narrowest near the part of the gas passage 22 in which the thermal sensors 30 and 50 are disposed and becomes gradually wider as the distance from the thermal sensors 30 and 50 increases. In other words, the width of the hollow portion 24 is the widest in the part farthest from the thermal sensors 30 and 50 and becomes gradually narrower as the distance from the thermal sensors 30 and 50 decreases. The only requirement for this embodiment is that the sides of the cavities 23a and 23b that adjoin the gas passage 22 are inclined with respect to the Y-direction (gas flow direction). That is, the shape of the cavities 23a and 23b may be any shape provided that this requirement is satisfied.

As described above, in this embodiment, the shape of the cavities gradually changes as the distance from the thermal sensor decreases. In this way, the air resistance becomes smaller in comparison to the case where the corner of the cavity is square to the gas passage, thus making the gas flow smoother. As a result, it is possible to improve the sensitivity of the acceleration sensor. For example, when the material hermetically contained in the hollow portion 24 is susceptible to the air resistance caused by the wall line, the air resistance can be reduced by inclining the sides of the cavities with respect to the gas passage, thus making it possible to significantly increase the flow speed.

### Nineteenth Embodiment

In FIGS. 33A and 33B, FIGS. 34A and 34B, examples where the horizontal cross section of the hollow portion 24 is changed near the thermal sensors are explained. In this embodiment, an example where the vertical cross section of the hollow portion 24 is changed near the thermal sensors is explained.

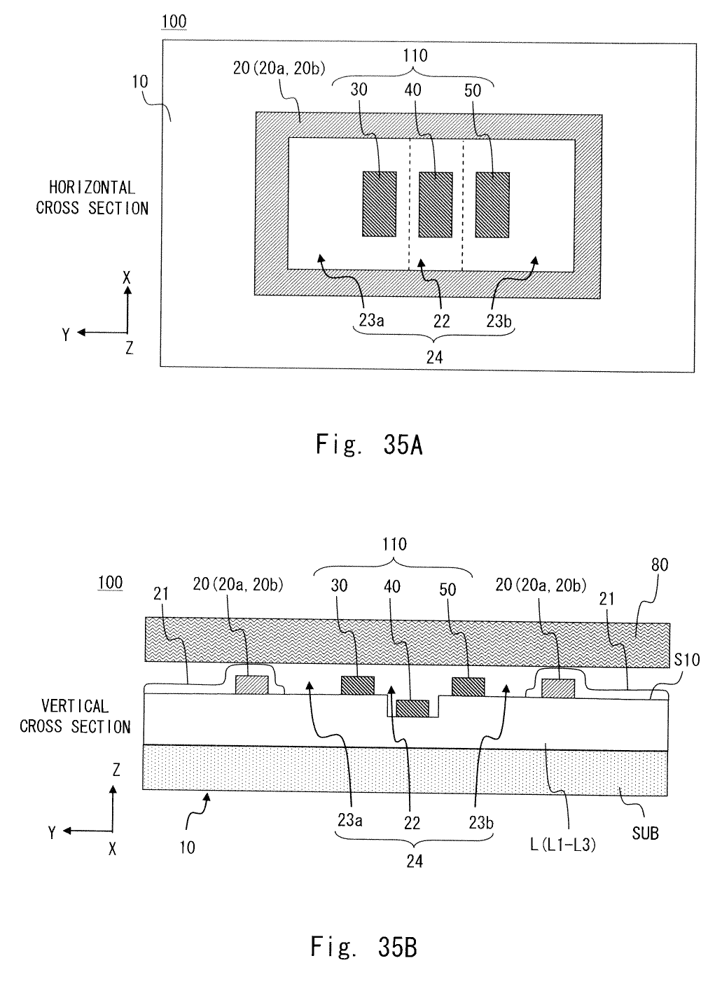

FIGS. 35A and 35B are a horizontal cross section and a vertical cross section of a semiconductor device 100 according to this embodiment.

In the semiconductor device 100 shown in FIGS. 35A and 35B, in comparison to the semiconductor devices 100 shown in FIGS. 28A and 28B, FIGS. 31A and 31B, the position (layer-level) of the wiring layer in which the heater or the thermal sensors is formed is different. The other configuration is similar to that shown in FIGS. 28A and 28B, FIGS. 31A and 31B.

In the semiconductor devices 100 shown in FIGS. 28A and 28B, FIGS. 31A and 31B, the heater 40 and the thermal sensors 30 and 50 are formed in the same wiring layer. In contrast to this, in the semiconductor device 100 shown in FIGS. 35A and 35B, the heater 40 and the thermal sensors 30 and 50 are formed in different wiring layers.

As shown in FIGS. 35A and 35B, the thermal sensors 30 and 50 are formed in the same uppermost layer as the wall line 20a, while the heater 40 is formed in the wiring structure layer L, which is located below the wall line 20a. For example, the wiring structure layer L includes wiring structure layers L1 to L3, and the heater 40 is formed in the wiring layer of the wiring structure layer L3 (intermediate layer), which is located immediately below the uppermost layer. In the area near the heater 40 sandwiched between the thermal sensors 30 and 50, the surface of the stacked body is dug down to the upper surface of the interlayer insulating film of the wiring structure layer L2. That is, in the area near the heater 40, the depth of the hollow portion 24 in the Z-direction is deeper, whereas in the area near the thermal sensors 30 and 50, the depth of the hollow portion 24 in the Z-direction is shallower.

As described above, in this embodiment, the thermal sensors 30 and 50 are formed in the uppermost layer and the heater 40 is formed in the lower wiring layer that is dug down from the uppermost layer. In this way, the space of the hollow portion is larger near the heater 40 and narrower near the thermal sensors 30 and 50. Therefore, similarly to the configurations in FIGS. 33A and 33B, FIGS. 34A and 34B, it is possible to increase the gas flow speed near the thermal sensors and thereby to improve the sensitivity of the acceleration sensor.

### Twentieth Embodiment

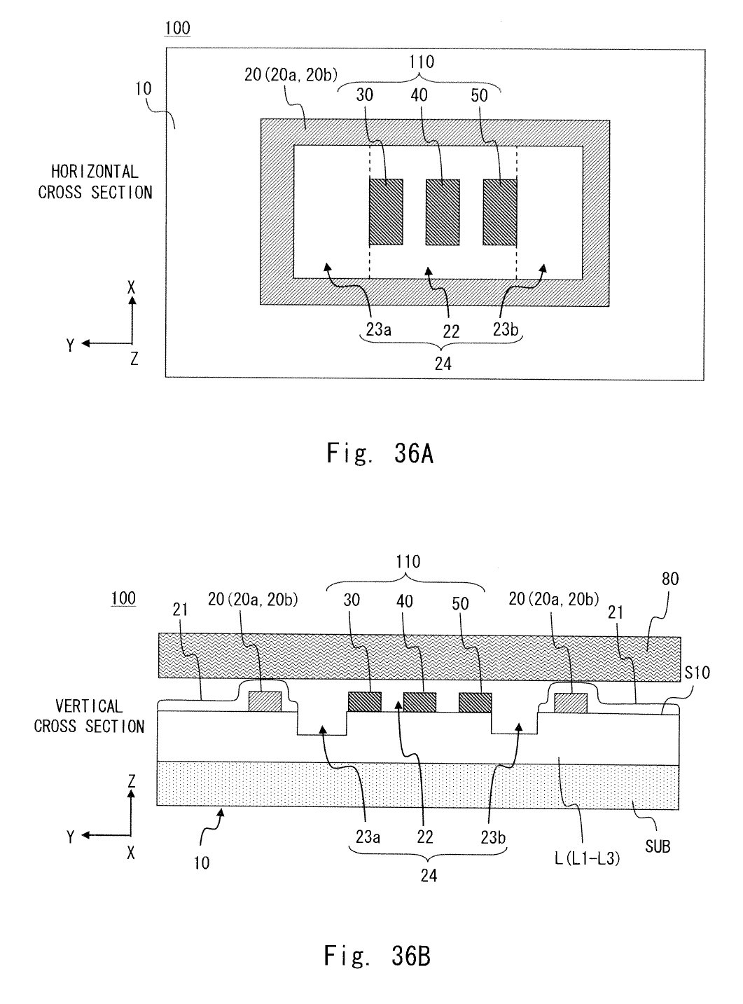

In this embodiment, another example where the vertical cross section of the hollow portion 24 is changed near the thermal sensors is explained. FIGS. 36A and 36B are a horizontal cross section and a vertical cross section of a semiconductor device 100 according to this embodiment.

In the semiconductor device 100 shown in FIGS. 36A and 36B, in comparison to the semiconductor device 100 shown in FIGS. 28A and 28B, the layer that the cavities adjoin is different. Further, in the semiconductor device 100 shown in FIGS. 36A and 36B, in comparison to the semiconductor device 100 shown in FIGS. 31A and 31B, the position of the layer in which the heater/thermal sensor line is formed is different. The other configuration is similar to that shown in FIGS. 28A and 28B, FIGS. 31A and 31B.

In the semiconductor devices 100 shown in FIGS. 28A and 28B, FIGS. 31A and 31B, the wiring layer in which the heater/thermal sensor line 110 is disposed is the same layer as the layer that the cavities 23a and 23b adjoin. In contrast to this, in the semiconductor device 100 shown in FIGS. 36A and 36B, the wiring layer in which the heater/thermal sensor line 110 is disposed is different from the layer that the cavities 23a and 23b adjoin.

As shown in FIGS. 36A and 36B, the heater/thermal sensor line 110 is formed in the same uppermost layer as the wall line 20a. The cavities 23a and 23b adjoin the wiring structure layer L, which is located below the wall line 20a. For example, the wiring structure layer L includes wiring structure layers L1 to L3. Further, in the cavities 23a and 23b sandwiched between the wall line 20a and the thermal sensors 30 and 50, the surface of the stacked body is dug down to the upper surface of the interlayer insulating film of the wiring structure layer L2. That is, in the cavities 23a and 23b and their vicinity, the depth of the hollow portion 24 in the Z-direction is deeper, whereas in the area near the thermal sensors 30 and 50, the depth of the hollow portion 24 in the Z-direction is shallower.

As described above, in this embodiment, the heater/thermal sensor line 110 is formed in the uppermost layer and the wiring structure layer adjoining the cavities 23a and 23b is dug down to the lower layer. As a result, the space of the hollow portion is larger in or near the cavities 23a and 23b and narrower near the thermal sensors 30 and 50. Therefore, similarly to FIGS. 35A and 35B, it is possible to increase the gas flow speed near the thermal sensors and thereby to improve the sensitivity of the acceleration sensor.

### Twenty-First Embodiment

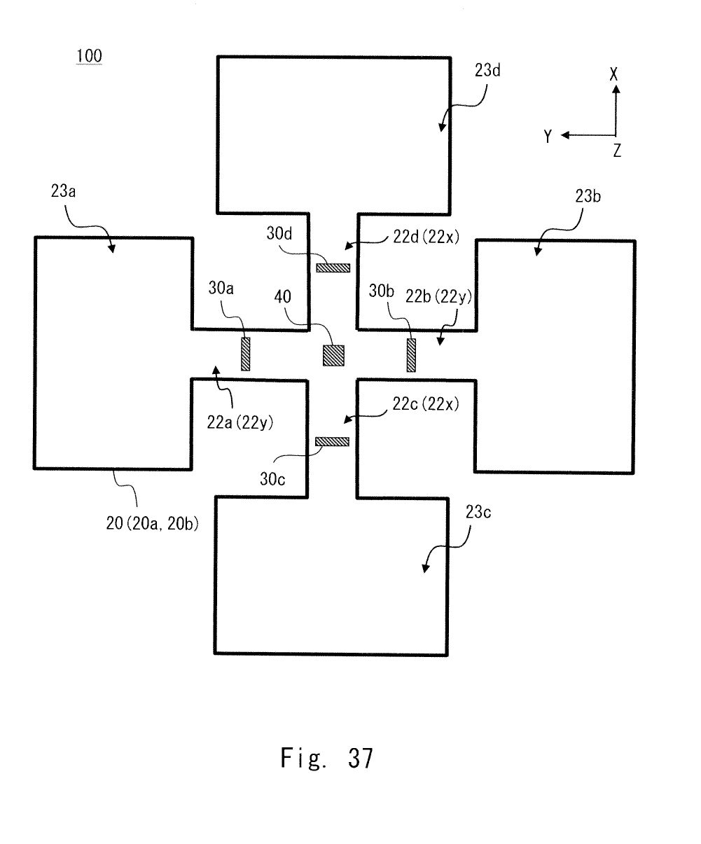

In this embodiment, another example where the vertical cross section of the hollow portion 24 is changed near the thermal sensors is explained. FIG. 37 is a horizontal cross section of a semiconductor device 100 according to this embodiment. Note that the vertical cross section of the semiconductor device 100 is similar to that shown in FIG. 33B or the like.

In the semiconductor device 100 shown in FIGS. 33A and 33B, a gas passage extending in the X-direction is formed, and cavities are formed on both sides of the gas passage. In contrast to this, in the semiconductor device 100 shown in FIG. 37, in addition to the configuration shown in FIGS. 33A and 33B, another gas passage extending in the Y-direction is formed and cavities are formed on both sides of that gas passage.

As shown in FIG. 37, the heater 40 is disposed at the center and four thermal sensors 30 (50) are arranged near the heater 40 along the X-direction and Y-direction. In the Y-direction, the thermal sensor 30a (50), the heater 40, and the thermal sensor 30b (50) are arranged in a row in this order. Further, in the X-direction, the thermal sensor 30c (50), the heater 40, and the thermal sensor 30d (50) are arranged in a row in this order.

Gas passages 22a and 22b extending in the Y-direction are formed in the place where the thermal sensors 30a and 30b are disposed. The gas passages 22a and 22b constitute a gas passage 22y, and cavities 23a and 23b are formed on both sides of the gas passage 22y.

Further, gas passages 22c and 22d extending in the X-direction are formed in the place where the thermal sensors 30c and 30d are disposed. The gas passages 22c and 22d constitute a gas passage 22x, and cavities 23c and 23d are formed on both sides of the gas passage 22x.

In other words, the gas passages 22y and 22x intersect each other at right angles and the heater 40 is disposed at the intersection of the gas passages. Four thermal sensors 30 are disposed in respective gas passages at places that are the same distance away from the heater 40. Note that similar to FIGS. 33A and 33B, FIGS. 34A and 34B, the cavities may have other various shapes.

As described above, in this embodiment, the thermal sensors are disposed so as to sandwich the heater not only in the X-direction but also in the Y-direction. Therefore, similarly to FIG. 26, it is possible to detect accelerations along two different axes, i.e., in the X-direction and Y-direction by using four thermal sensors.

Further, in this embodiment, the width of the hollow portion is narrower in the gas passage portions extending in the X-direction and Y-direction in which four thermal sensors are disposed, and is wider in the four cavities located outside the gas passage portions. In this way, similarly to FIGS. 33A and 33B and the like, it is possible to increase the gas flow speed in the gas passage portions and thereby to improve the sensitivity of the acceleration sensor.

### Twenty-Second Embodiment

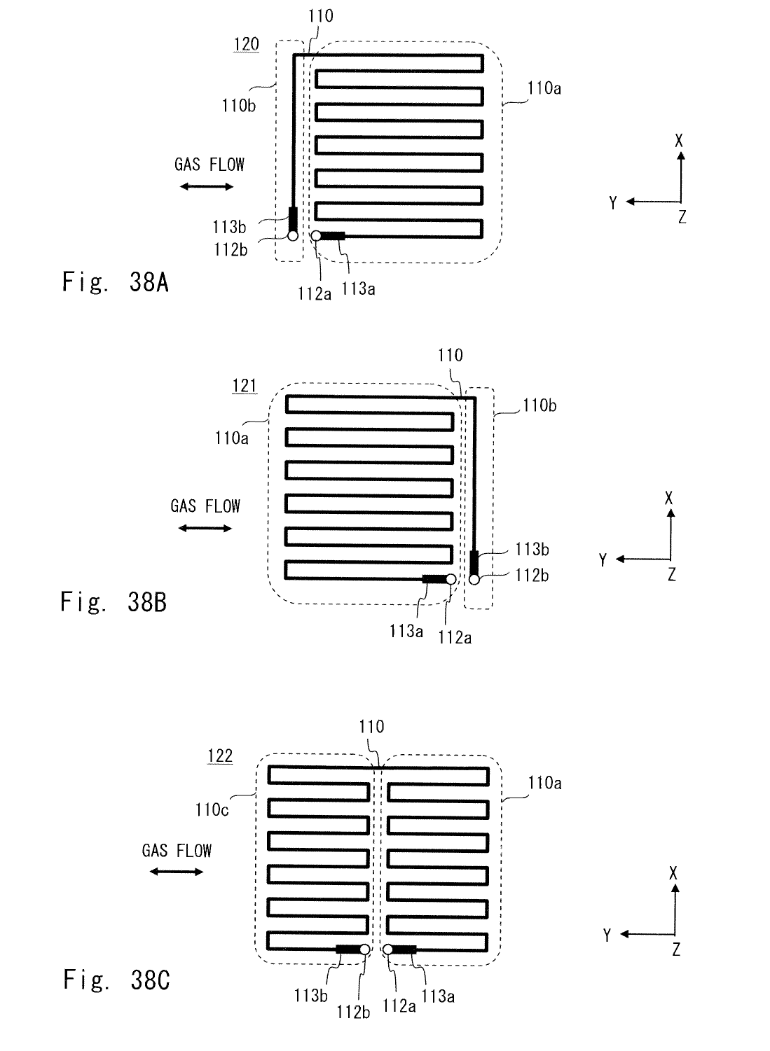

A wiring pattern of the heater/thermal sensor line 110 according to this embodiment of the present invention is explained with reference to FIGS. 38A, 38B and 38C. FIGS. 38A, 38B and 38C show a wiring pattern of the heater 40 or the thermal sensor 30 or 50 as viewed from the top.

As described above, in the semiconductor device 100, the heater 40 and the thermal sensors 30 and 50 are formed from metal lines, and they function as a heater and thermal sensors by using the parasitic resistances of the lines. Therefore, to make the heater 40 and the thermal sensors 30 and 50 function effectively, it is necessary to increase the resistance value of the metal line.

Therefore, to increase the resistance value of the line, the heater/thermal sensor line 110 is laid out as a slender line as shown in FIGS. 38A, 38B and 38C in this embodiment. FIGS. 38A, 38B and 38C show three examples of a meander-shape wiring pattern.

As shown in FIGS. 38A, 38B and 38C, the heater/thermal sensor line 110 is laid out in a meander-shape so that the slender line can be laid out in a small area with efficiency. The meander-shape line means a line in a zigzag wiring pattern, in which the line is laid out in such a manner that it is alternately folded back in one direction and in the opposite direction.

FIGS. 38A and 38B show left-right asymmetric wiring patterns in the Y-axis positive direction and the Y-axis negative direction (gas flow direction), and FIG. 38C shows a left-right symmetric wiring pattern in the Y-axis positive direction and the Y-axis negative direction.

In the wiring pattern 120 in FIG. 38A, the heater/thermal sensor line 110 includes a meander-shaped meander line portion 110a and a straight-line return line portion 110b. In the wiring pattern 120, the meander line portion 110a is disposed on the Y-axis direction positive side and the return line portion 110b is disposed in the Y-axis direction negative side.

One end of the meander line portion 110a is connected to a trench line (via) 112a through a wide line 113a and the other end is connected to the return line portion 110b. The meander line portion 110a is formed by alternately folding back the line extending along the gas flow direction (Y-direction).

One end of the return line portion 110b is connected to the meander line portion 110a and the other end is connected to a trench line 112b through a wide line 113b. The return line portion 110b extends in a straight line toward the direction (X-direction) perpendicular to the gas flow direction from the other end of the meander line portion 110a to the trench line 112b located near the trench line 112a.

For example, as an example of actual formation of the wiring pattern 120, assume that: the wiring material is copper; the line width is 0.2 μm; the line interval is 0.2 μm; the film thickness is 0.3 μm; the line length is 1 mm; and the resistance is 700Ω. In this case, the wiring pattern 120 is formed with its overall X-direction length being 50 μm and the Y-direction length being 15 μm.

Similarly to the wiring pattern 120, the wiring pattern 121 in FIG. 38B includes a meander line portion 110a and a return line portion 110b. In the wiring pattern 121, the positional relation between the meander line portion 110a and the return line portion 110b is reversed with respect to the wiring pattern 120. That is, the meander line portion 110a is disposed on the Y-axis direction negative side and the return line portion 110b is disposed in the Y-axis direction positive side.

In the wiring pattern 122 in FIG. 38C, the heater/thermal sensor line 110 includes two meander line portions 110a and 110c. These two meander line portions 110a and 110c are arranged in a row in the Y-direction.

One of the meander line portions, i.e., the meander line portion 110a is connected to a trench line 112a through a wide line 113a and the other end is connected to the meander line portion 110c. Similarly, the other meander line portion, i.e., the meander line portion 110c is connected to a trench line 112b through a wide line 113b and the other end is connected to the meander line portion 110a.

By laying out the heater/thermal sensor line 110 constituting the thermal sensors 30 and 50 in a meander-shape as shown above, it is possible to laying out the line with efficiency. Further, by laying out the line in such a manner that the extending direction of the line (long side direction) is parallel with the gas flow direction, the disturbance of the gas flow due to the line can be reduced. As a result, the disturbance of the gas flow is prevented, thus making it possible to improve the sensitivity of the acceleration sensor.

Further, the heater/thermal sensor line is connected to other circuits by using a metal line located in a layer below the heater/thermal sensor line, and the heater/thermal sensor line and the metal line located in the lower layer are connected through a trench line. By using the lower-layer line for the line other than the heater/thermal sensor line and thereby preventing the line from being exposed to the gas, it is possible to suppress the effect on the gas flow and thereby improve the sensitivity of the acceleration sensor.

Further, the heater/thermal sensor line has a wider width in the connection part with the trench line than the width of the other parts. In this way, it is possible to secure the resistance to EM (Electro Migration) in the trench line portion.

### Twenty-Third Embodiment

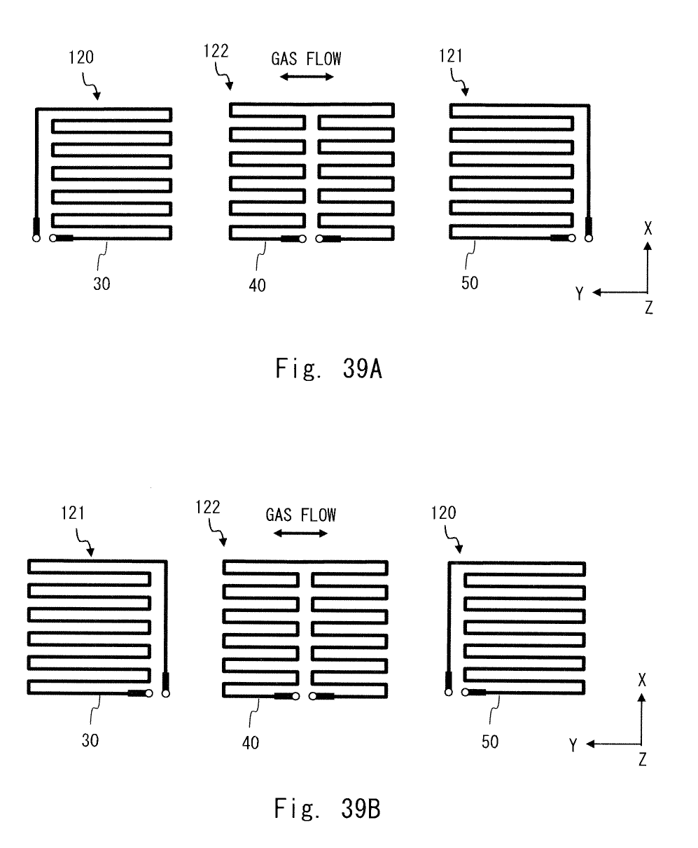

A combination of wiring patterns of the heater/thermal sensor lines 110 according to this embodiment of the present invention is explained with reference to FIGS. 39A and 39B. FIGS. 39A and 39B show a wiring pattern of the heater 40 and the thermal sensors 30 and 50 as viewed from the top, and shows examples of a combination of wiring patterns that can be used when the wiring patterns 120 to 122 shown in FIGS. 38A, 38B and 38C are applied to the semiconductor device 100.

FIG. 39A shows an example in which: the heater 40 is a line composed of a wiring pattern 122; the thermal sensor 30 is a line composed of a wiring pattern 120; and the thermal sensor 50 is a line composed of a wiring pattern 121. FIG. 39B shows an example in which: the heater 40 is a line composed of a wiring pattern 122; the thermal sensor 30 is a line composed of a wiring pattern 121; and the thermal sensor 50 is a line composed of a wiring pattern 120.

Since the heater 40 needs to transfer the heat substantially equally to the thermal sensors 30 and 50, it is preferable to adopt the wiring pattern 122 that is left-right symmetrical in the gas flow direction.

Since the thermal sensors 30 and 50 need to detect the heat generated by the heater 40 with substantially the same sensitivity, it is preferable to use a wiring pattern that is symmetrical as viewed from the heater 40. That is, in FIG. 39A, each of the thermal sensors 30 and 50 has its meander line portion 110a on the side closer to the heater 40 and has its return line portion 110b on the side farther from the heater 40. Further, the thermal sensors 30 and 50 are symmetrical as viewed from the heater 40.

In FIG. 39B, each of the thermal sensors 30 and 50 has its return line portion 110b on the side closer to the heater 40 and has its meander line portion 110a on the side farther from the heater 40. Further, the thermal sensors 30 and 50 are symmetrical as viewed from the heater 40. Note that similar advantageous effects can be also achieved when the left-right symmetric wiring pattern 122 is adopted for each of the heater 40 and thermal sensors 30 and 50.

In particular, as shown in FIG. 39A, by disposing the meander line portions 10 of the thermal sensors 30 and 50 near the heater 40, the heat of the heater 40 can be detected in places closer to the heater 40. As a result, the sensitivity of the thermal sensor can be improved even further.

### Twenty-Fourth Embodiment

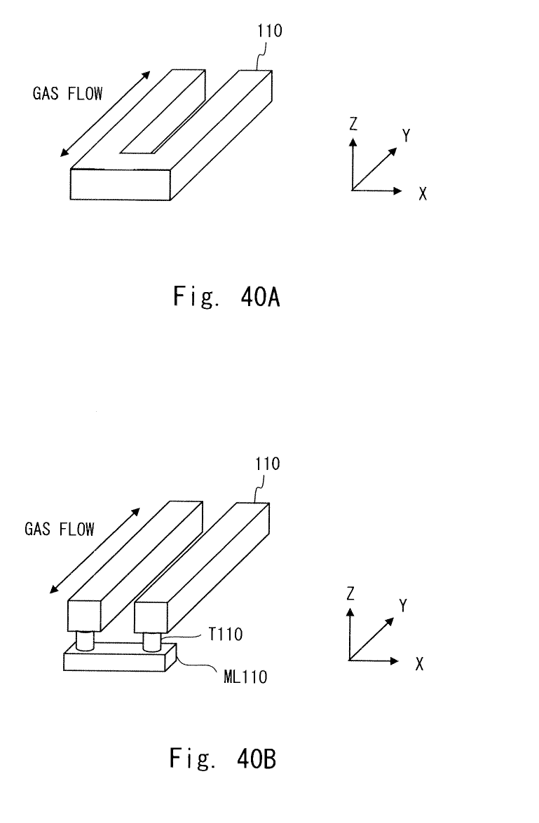

Another example of a wiring pattern of the heater/thermal sensor line 110 according to this embodiment of the present invention is explained with reference to FIGS. 40A and 40B. FIGS. 40A and 40B are a perspective view of a wiring pattern of the heater/thermal sensor line 110, and show a folding portion of the meander-shaped wiring pattern shown in FIGS. 38A, 38B and 38C.

FIG. 40A shows an example in which a folding portion of the heater/thermal sensor line 110 is formed by a single wiring layer. In this case, the folding portion is disposed perpendicular to the gas flow, thus possibly obstructing the gas flow.

FIG. 40B shows an example in which a line in a lower layer is used for the folding portion. In this case, the folding portion is connected to a lower-layer line ML110 through trench lines T110. The lower-layer line ML110 is connected between the trench lines T110 so that the heater/thermal sensor line 110 is folded back by using the lower-layer line ML110. In this way, no wall line is formed in the area that could obstruct the gas flow, thus making it possible to increase the gas flow speed.

However, the trench line portion has a poor resistance to EM, thus posing the possibility of broken wires. Therefore, it is preferable to form the folding portion by a single wiring layer as shown in FIG. 40A. That is, since the heater/thermal sensor line 110 is laid out in a slender line as shown in FIGS. 38A, 38B and 38C, it is desirable to eliminate the use of trench lines (vias) as much as possible in order to secure the EM resistance. Note that when a trench line(s) is used as shown in FIG. 40B, it is preferable to lower the maximum current that can flow through the heater a value lower than that of the configuration in FIG. 40A in order to prevent the occurrence of broken lines.

### Twenty-Fifth Embodiment

In this embodiment, a wiring pattern made of dummy metal (dummy pattern), when the dummy metal is disposed in the semiconductor device 100, is explained.

In Cu wiring process, it is necessary to dispose dummy metal throughout the entire surface of the chip in order to form minuscule lines. In general, when no line is laid out in a certain area, dummy metal is laid out in a predetermined pattern in that area.

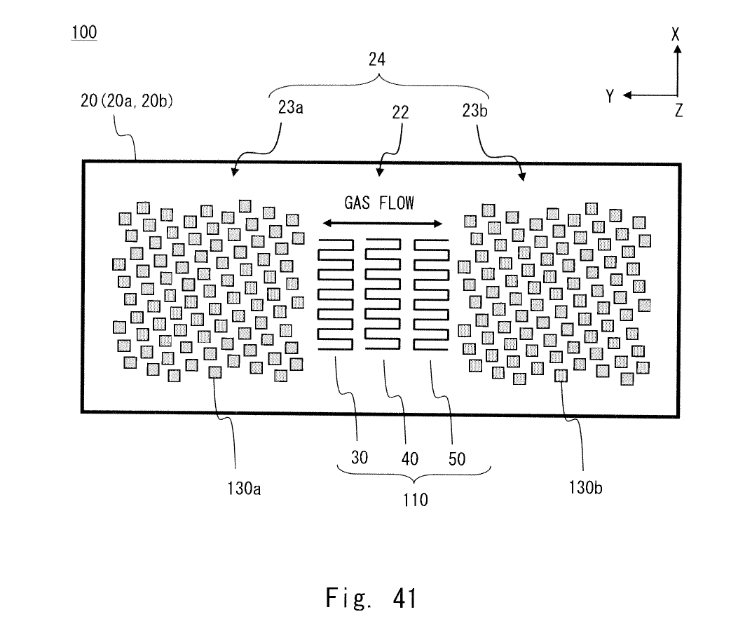

FIG. 41 shows a reference example in which dummy metal is disposed in the semiconductor device 100 shown in FIGS. 28A and 28B or FIGS. 31A and 31B in a simple manner. In this reference example, since no line is formed in the cavities 23a and 23b, a plurality of dummy metal pieces are disposed in the cavities 23a and 23b. As shown in FIG. 41, usually, a particle-like dummy pattern (each particle is roughly a square) is used. That is, particle-like dummy metal pieces 130a and 130b are disposed throughout the cavities 23a and 23b.

However, when a particle-like dummy pattern is used as shown in FIG. 41, the gas flow is obstructed and thereby disturbed by the dummy metal pieces. As a result, the sensitivity of the acceleration sensor deteriorates.

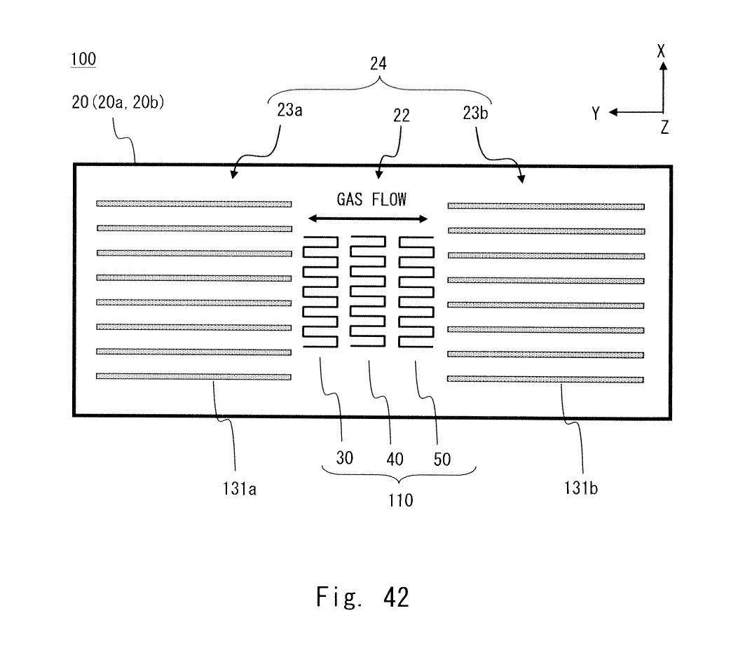

Therefore, this embodiment uses a dummy pattern shown in FIG. 42. FIG. 42 shows a horizontal cross section of the semiconductor device 100 similar to that shown in FIGS. 28A and 28B or FIGS. 31A and 31B.

As shown in FIG. 42, in the semiconductor device 100 according to this embodiment, the dummy metal is formed as such a dummy pattern that each piece has a long rectangular shape. In the cavities 23a and 23b of the semiconductor device 100 in which no line is formed, rectangular dummy metal pieces 131a and 131b are disposed in such a manner that they extend in the Y-direction along which the gas flows. Each of the dummy metal pieces 131a and 131b has a rectangular shape with the long sides extending in the Y-direction. A plurality of dummy metal pieces 131a and 131b are arranged at predetermined intervals in the cavities 23a and 23b. Note that in this specification, an individual dummy line may be referred to as “dummy metal” and a plurality of dummy lines may be also referred to as “dummy metal” in this specification.

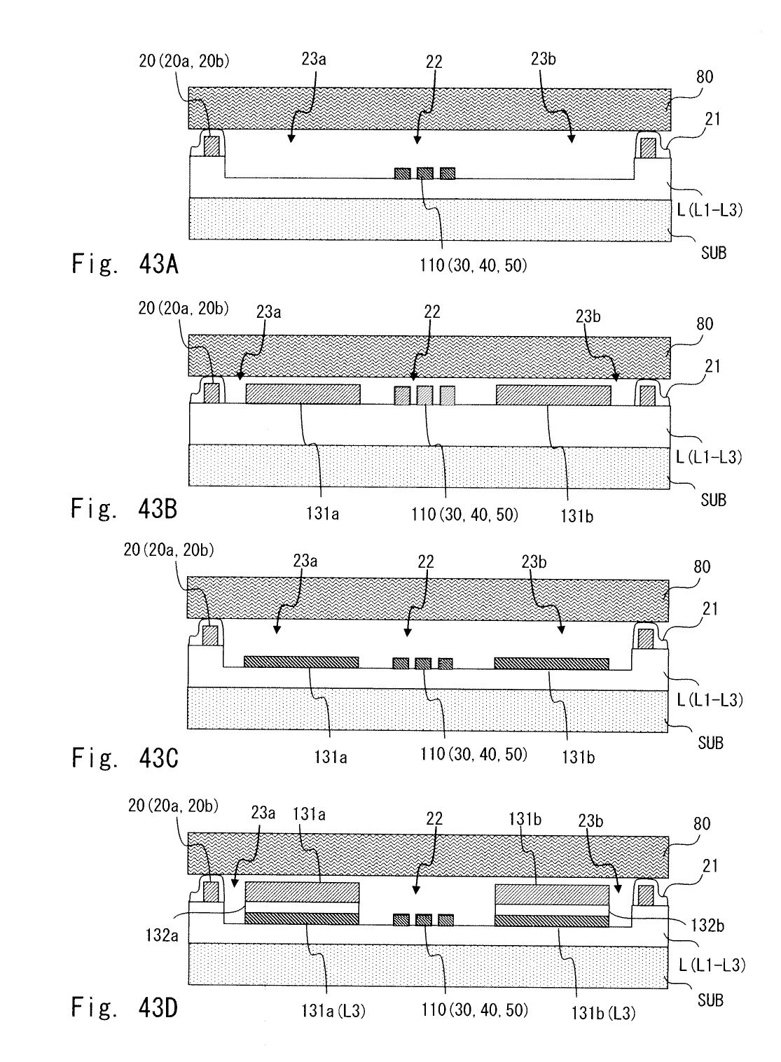

FIGS. 43A to 43D are vertical cross sections of the semiconductor device 100 shown in FIG. 42, and show examples of the positional relation between the dummy metal pieces 131 and the heater/thermal sensor line 110 in the depth direction (Z-direction).

FIG. 43A shows an example in which the heater/thermal sensor line 110 is formed in the wiring layer of a layer that is located below the uppermost layer and no dummy metal is formed. That is, it has a similar configuration to that of the semiconductor device 100 shown in FIGS. 31A and 31B. For example, when the heater/thermal sensor line 110 is formed by an A1 line, no dummy metal is necessary. Therefore, the configuration shown in FIG. 43A may be used.

FIG. 43B shows an example in which the heater/thermal sensor line 110 is formed in the uppermost layer wiring and a dummy metal 131 is also disposed in the uppermost layer wiring. That is, it is an example that is obtained by forming dummy metals 131a and 131b in the uppermost layer in the cavities 23a and 23b in the configuration of the semiconductor device 100 shown in FIGS. 28A and 28B. Note that in this case, dummy metals may be also disposed in the wiring layer included in the wiring structure layer L, but the illustration thereof is omitted in the figure.

FIG. 43C shows an example in which the heater/thermal sensor line 110 is formed in the wiring layer of a layer that is located below the uppermost layer and a dummy metal 131 is formed only in the wiring layer of the same lower layer as the heater/thermal sensor line 110. That is, it is an example that is obtained by forming dummy metals 131a and 131b in the same wiring layer as the heater/thermal sensor line 110 in the cavities 23a and 23b in the configuration of the semiconductor device 100 shown in FIGS. 31A and 31B. This configuration may be used for the processes in which no dummy metal is necessary in the uppermost wiring layer.

FIG. 43D shows an example in which the heater/thermal sensor line 110 is formed in the wiring layer of a layer that is located below the uppermost layer and a dummy metal 131 is disposed in each of the uppermost layer wiring layer and the lower layer wiring layer. That is, it is an example that is obtained by forming dummy metals 131a and 131b in the same lower layer wiring layer as the heater/thermal sensor line 110 (wiring layer of the wiring structure layer L3) and further forming dummy metals 131a and 131b in the uppermost layer wiring in the cavities 23a and 23b in the configuration of the semiconductor device 100 shown in FIGS. 31A and 31B. Further, the interlayer insulating layers 132a and 132b of the wiring structure layer L3 are formed between the dummy metals 131a and 131b of the uppermost layer and the dummy metals 131a and 131b of the lower layer. The dummy metals formed in the respective wiring layers have the same shape, and disposed in such a manner that they are placed on top of each other in the vertical direction (Z-direction) with the interlayer insulating layer interposed therebetween. Note that in this case, no dummy metal needs to be disposed directly above the heater/thermal sensor line 110.

As described above, in this embodiment, slender rectangular dummy metal pieces are used and they are disposed in such a manner that their long side direction is parallel to the gas flow direction. As a result, the disturbance of the gas flow caused by the dummy pattern is minimized. Therefore, it is possible to increase the gas low speed and thereby to improve the sensitivity of the acceleration sensor.

### Twenty-Sixth Embodiment

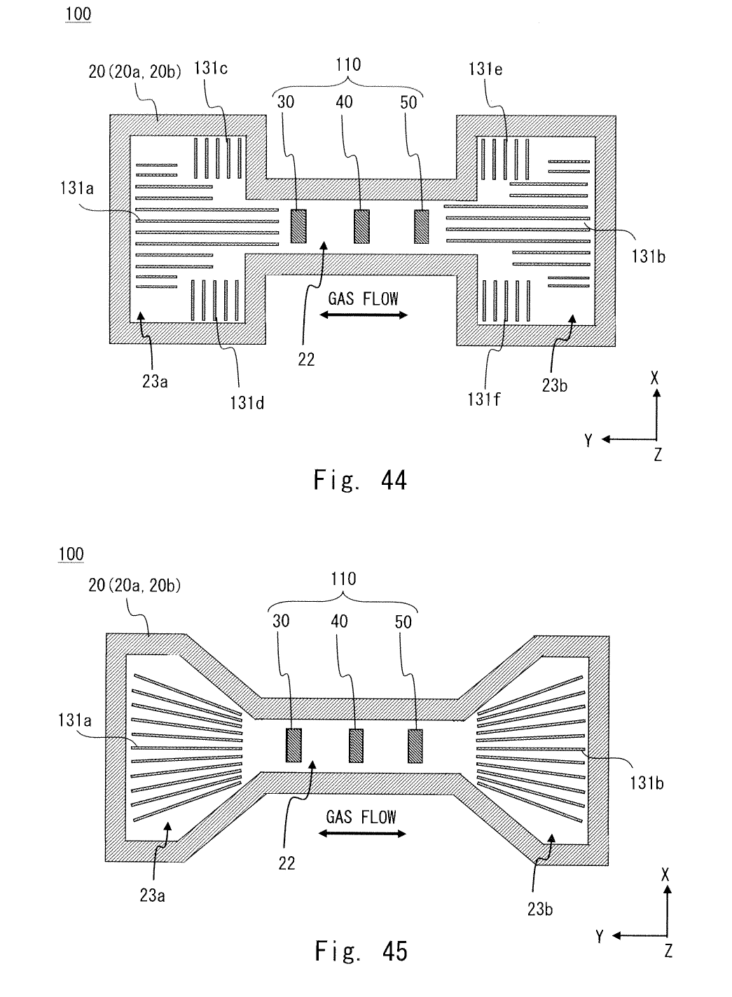

In this embodiment, another example where dummy metal is disposed in the semiconductor device 100 is explained. FIG. 44 is a horizontal cross section of a semiconductor device 100 according to this embodiment of the present invention, and shows an example in which similar dummy metal to that shown in FIG. 42 is applied to the semiconductor device 100 shown in FIGS. 33A and 33B.

As shown in FIG. 44, slender rectangular dummy metal pieces are disposed in empty spaces, in which no heater/thermal sensor line 110 is formed, of the hollow portion 24 containing the cavities 23a and 23b and the gas passage 22. In FIG. 44, dummy metal pieces are disposed in the X-direction and Y-direction.

In the cavity 23a, a plurality of dummy metal pieces 131a are disposed in parallel with the Y-direction along which the gas flows. The dummy metal pieces 131a extend from the end of the cavity 23a in the Y-direction (from the long side of the rectangle) to the vicinity of the thermal sensor 30 of the gas passage 22. Since the width of the hollow portion 24 is narrower in the gas passage 22 and is wider in the cavity 23a, the number of the dummy metal pieces 131a increases as the distance from the gas passage 22 increases. By arranging the dummy metal pieces 131a in this manner, the gas present in the cavity 23a can flow more easily from the Y-direction end of the cavity 23a to the gas passage 22 side.

Further, a plurality of dummy metal pieces 131c and 131d are disposed in parallel with the X-direction in the corner portions of the cavity 23a on the thermal sensor 30 side. The dummy metal pieces 131c and 131d extend from the end of the cavity 23a in the X-direction (from the short sides of the rectangle) toward the center of the cavity 23a to the vicinity of the dummy metal pieces 131a. By arranging the dummy metal pieces 131c and 131d in this manner, the gas present in the cavity 23a can flow more easily from the X-direction ends of the cavity 23a to the gas passage 22 side.

Note that additional dummy metal pieces may be disposed in other empty spaces such as other corner portions of the cavity 23a.

Similarly to the cavity 23a, dummy metal pieces 131b are disposed in the Y-direction and dummy metal pieces 131e and 131f are disposed in the X-direction in the cavity 23b. With these dummy metal pieces, the gas present in the cavity 23b can flow more easily from the Y-direction ends and X-direction end to the gas passage 22 side.

### Twenty-Seventh Embodiment

In this embodiment, another example where dummy metal is disposed in the semiconductor device 100 is explained. FIG. 45 is a horizontal cross section of a semiconductor device 100 according to this embodiment of the present invention, and shows an example in which similar dummy metal to that shown in FIG. 42 is applied to the semiconductor device 100 shown in FIGS. 34A and 34B.

As shown in FIG. 45, slender rectangular dummy metal pieces are disposed in empty spaces of the cavities 23a and 23b in which no heater/thermal sensor line 110 is formed. In FIG. 45, dummy metal pieces are disposed in oblique directions with respect to the X-axis and Y-axis.

In FIG. 45, the width of the cavities 23a and 23b is the narrowest in the area where the thermal sensors 30 and 50 are disposed and becomes gradually wider as the distance from the thermal sensors 30 and 50 increases. To conform to the shape of the cavities 23a and 23b, the intervals of the dummy metal pieces 131a and 131b are narrower near the thermal sensors 30 and 50 and become wider as the distance from the thermal sensors 30 and 50 increases. That is, the pitch of the dummy metal pieces changes according to the internal width of the cavity.

By disposing the dummy metal pieces 131a and 131b in oblique directions toward the thermal sensors 30 and 50 in this manner, the gas present in the cavities 23a and 23b can flow more easily from the Y-direction ends of the cavities 23a and 23b to the gas passage 22 side.

### Twenty-Eighth Embodiment

In this embodiment, a configuration of a resistance measurement circuit included in the heat detection circuit of the semiconductor device 100 is explained. The resistance measurement circuit is a circuit for measuring the resistance value of a thermal sensor. For example, in the heat detection circuit shown in FIG. 6, the current source CS1 and the amplifier AMP that are used to measure the resistance value of the resistor R2 constitute the resistance measurement circuit.

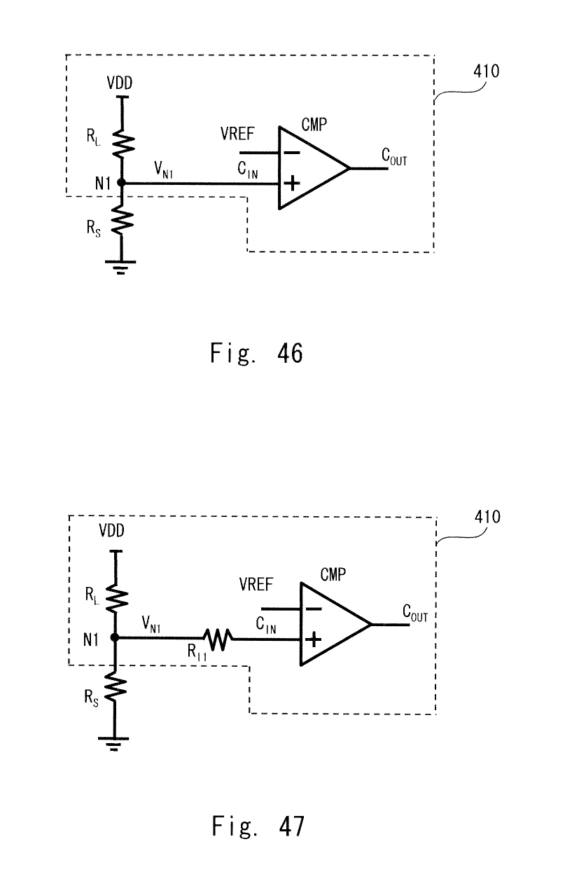

FIG. 46 shows a configuration of a resistance measurement circuit according to this embodiment of the present invention. As shown in FIG. 46, this resistance measurement circuit 410 includes a load resistor RL and a comparator CMP that are used to measure the resistance value of a sensor resistor RS. Firstly, the correspondence relation between FIG. 46 and FIG. 6 is explained. The load resistor RL, the sensor resistor RS, and the comparator CMP in FIG. 46 correspond to the current source CS1, the resistor R2, and the amplifier AMP, respectively, in FIG. 6.

The load resistor RL and the sensor resistor RS are connected in series between a power-supply potential VDD and a ground potential GND. Further, the node N1 between the load resistor RL and the sensor resistor RS is input to the positive input terminal (CIN) of the comparator CMP. The sensor resistor RS represents the line resistance of the thermal sensor 30 or 50. The load resistor RL is a resistor that is used to apply a bias voltage to the sensor resistor RS. The comparator CMP compares a voltage VN1 measured at the node N1 with a reference voltage VREF, amplifies their difference value, and outputs the amplified difference value as a measured voltage COUT.

In FIG. 46, a resistor having a large temperature coefficient is used for the sensor resistor RS and a resistor having a small temperature coefficient is used for the load resistor RL. The sensor resistor RS having a large temperature coefficient is disposed as the thermal sensors 30 or 50 in an area where the resistor is exposed to the gas. The load resistor RL having a small temperature coefficient can be disposed in any place where the resistor is not exposed to the gas. Among the resistive bodies commonly used on silicon chips, the metal lines such as Cu and Al have a relatively large temperature coefficient. Therefore, a metal line is used as the sensor resistor RS having a large temperature coefficient. Polysilicon whose temperature coefficient is one tenth of that of the metal line, is used as the load resistor RL having a small temperature coefficient.

In FIG. 46, since the sensor resistor RS and the load resistor RL are connected in series, the heat is transferred from the sensor resistor RS, which is exposed to the gas, to the load resistor RL.

The voltage VN1 at the node N1 in FIG. 46 caused by the temperature change is calculated hereinafter. Firstly, assume that the resistance values of the sensor resistor RS and the sensor resistor RS are given by the following Expressions 1 and 2 respectively.

R_{S}(ΔT)=R_{S0}×(1+K_{S}×ΔT) [Expression 1]

R_{L}(ΔT)=R_{L0}×(1+K_{L}×ΔT) [Expression 2]

In Expressions 1 and 2, RS0 and RL0 represent the resistance values of the sensor resistor RS and the load resistor RL respectively at a reference temperature, and KS and KL represent temperature coefficients of the sensor resistor RS and the load resistor RL respectively. AT represents the temperature difference from the reference temperature.

The voltage VN1 at the node N1 in FIG. 46 generated when the temperature changes from the reference temperature by ΔT is expressed by the following Expression 3 by using Expressions 1 and 2.

$$\begin{matrix}{V}_{N 1} ( Δ T ) = \frac{{R}_{S} ( Δ T )}{{R}_{S} ( Δ T ) + {R}_{L} ( Δ T )} \times {V}_{DD} \\ = \frac{{R}_{S 0} \times ( 1 + {K}_{S} \times Δ T )}{\begin{matrix}{R}_{S 0} \times ( 1 + {K}_{S} \times Δ T ) + \\ {RL}_{0} \times ( 1 + {K}_{L} \times Δ T )\end{matrix}} \times {V}_{DD} \\ \approx ( \begin{matrix}\frac{{R}_{S 0}}{{R}_{S 0} + {R}_{L 0}} + \\ \frac{{R}_{S 0} \times {R}_{L 0} \times ( {K}_{S} - {K}_{L} ) \times Δ T}{{( {R}_{S 0} + {R}_{L 0} )}^{2}}\end{matrix} ) \times {V}_{DD}\end{matrix} \qquad [ Expression 3 ]$$

Based on Expression 3, if KS=KL, the voltage VN1 becomes constant regardless of the temperature. That is, when KS=KL, the output of this resistance measurement circuit becomes constant. Therefore, the temperature cannot be detected. In this embodiment, the relation KS>>KL is satisfied. Therefore, it is possible to output the voltage VN1 according to the heat by using the sensor resistor RS and thereby to prevent the sensitivity deterioration due to the load resistor RL.

As described above, in this embodiment, a resistive element having a large temperature coefficient and a resistive element having a small temperature coefficient are connected in series, and the gas temperature is detected by using the resistive element having a large temperature coefficient. Although the heat is transferred from the resistive element having a large temperature coefficient to the resistive element having a small temperature coefficient, the change in the resistance value of the resistive element having a small temperature coefficient is small. Therefore, it is possible to minimize the effect on the gas temperature detection and thereby to reliably detect the temperature.

### Twenty-Ninth Embodiment

In this embodiment, another configuration example of the resistance measurement circuit of the semiconductor device 100 is explained. FIG. 47 shows a configuration of a resistance measurement circuit according to this embodiment of the present invention. In a resistance measurement circuit 410 shown in FIG. 47, an additional resistor RI1 is added in comparison to the resistance measurement circuit shown in FIG. 46, but other configurations are similar to those in FIG. 46.

In FIG. 47, the resistor RI1 is connected between the node N1 (voltage output terminal) between the sensor resistor RS and the load resistor RL and the positive input terminal (CIN) of the comparator CMP. The resistor RI1 is a resistor having a lower heat conductivity than that of the sensor resistor RS. For example, polysilicon, TiN, or TaN may be used as the resistive body having a low heat conductivity.

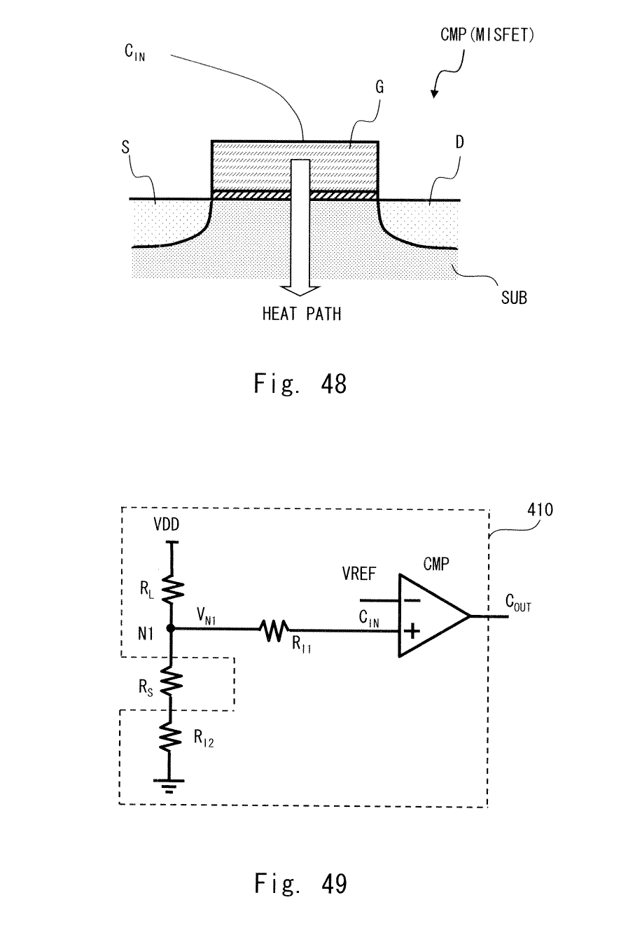

To assist the understanding of the operation principle of this embodiment, FIG. 48 shows a cross section of a semiconductor chip in which the comparator CMP is composed of a MISFET. In the MISFET constituting the comparator CMP as shown in FIG. 48, a source region S and a drain region D are formed in the upper surface of a semiconductor substrate SUB and a gate terminal (gate structure) G is formed in the area sandwiched between the source region S and the drain region D on the semiconductor substrate SUB. In this example, the gate terminal G serves as the positive input terminal CIN of the comparator CMP.

The gate terminal G is not in direct contact with the silicon substrate. However, since the thickness of the insulating film interposed between the gate terminal G and the silicon substrate is equal to or less than one hundredth of the thickness of the interlayer insulating film for the lines, it tends to transfer the heat therethrough. Further, since silicon has a high heat conductivity, the silicon substrate tends to dissipate the heat therefrom. Therefore, when the sensor resistor RS is directly connected to the positive input terminal CIN of the comparator CMP as shown in FIG. 46, the heat in the sensor resistor RS easily escapes to the semiconductor substrate SUB through the positive input terminal CIN of the comparator CMP as indicated by the arrow shown in FIG. 48. As a result, it is impossible to accurately detect the temperature by the thermal sensors 30 and 50.

Therefore, in this embodiment, the resistor RI1 having a low heat conductivity is interposed between the node N1 and the input terminal of the comparator CMP (MISFET) as shown in FIG. 47. In this way, it is possible to prevent the heat in the sensor resistor RS from escaping to the comparator CMP side and thereby to improve the sensitivity of the thermal sensor.

### Thirtieth Embodiment

In this embodiment, another configuration example of the resistance measurement circuit of the semiconductor device 100 is explained. FIG. 49 shows a configuration of a resistance measurement circuit according to this embodiment of the present invention. In the resistance measurement circuit 410 shown in FIG. 49, an additional resistor RI2 is added in comparison to the resistance measurement circuit shown in FIG. 47, but other configurations are similar to those in FIG. 47.

In FIG. 49, the resistor RI1 having a low heat conductivity is connected between the node N1 (voltage output terminal) between the sensor resistor RS and the load resistor RL and the positive input terminal (CIN) of the comparator CMP.

In this embodiment, an additional resistor RI2 is connected between the sensor resistor RS and the ground potential GND. Similarly to the resistor RI1, the resistor RI2 is a resistor having a lower heat conductivity than that of the sensor resistor RS. For example, polysilicon, TiN, or TaN may be used as the resistive body having a low heat conductivity.

The line connected to the ground potential GND is typically connected to the silicon substrate through well contacts. Therefore, as shown in FIG. 47, when the sensor resistor RS is directly connected to the ground potential GND, the heat in the sensor resistor RS escapes to the ground potential GND. As a result, it is impossible to accurately detect the temperature by the thermal sensors 30 and 50.

Therefore, in this embodiment, the resistor RI2 having a low heat conductivity is interposed between the sensor resistor RS and the ground potential GND. In this way, the heat conductivity of the path from the sensor resistor RS to the ground potential GND becomes lower. Therefore, it is possible to prevent the heat in the sensor resistor RS from escaping to the ground potential GND side and thereby to improve the sensitivity of the thermal sensor.

### Thirty-First Embodiment

In this embodiment, a wiring example from the heater/thermal sensor line to the resistance measurement circuit (comparator) in the semiconductor device 100 is explained.

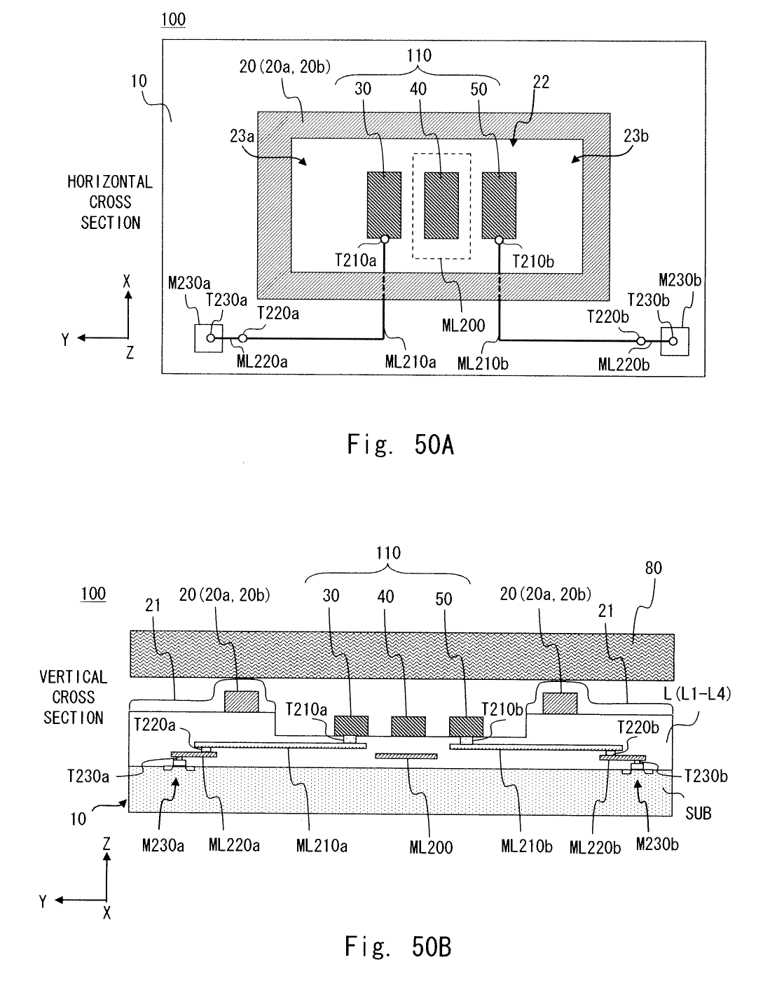

FIGS. 50A and 50B are a horizontal cross section and a vertical cross section of a semiconductor device 100 according to this embodiment of the present invention. In comparison to the semiconductor device 100 shown in FIGS. 31A and 31B, lines extending from the heater/thermal sensor line to the comparator CMP are added in FIGS. 50A and 50B, but other configurations are similar to those in FIGS. 31A and 31B.

Similarly to FIGS. 31A and 31B, FIGS. 50A and 50B show an example in which the heater/thermal sensor line 110 is formed in a layer that is located below the uppermost layer. Note that the heater/thermal sensor line 110 may be formed on the uppermost layer as shown in FIGS. 28A and 28B.

In FIGS. 50A and 50B, similarly to FIG. 2, the wiring structure layer L includes a plurality of wiring structure layers and each wiring structure layer includes a wiring layer and an interlayer insulating film. The following explanation is made on the assumption that the wiring structure layer L includes wiring structure layers L1 to L4.

In the semiconductor device 100, an uppermost layer wiring structure 20 is formed in the uppermost layer and the heater/thermal sensor line 110 is formed in the wiring layer of the wiring structure layer L4, which is located below the uppermost layer wiring structure 20. Lines ML210 (ML210a and ML210b) are formed in the wiring layer of the wiring structure layer L3, which is located below the heater/thermal sensor line 110. A line ML200 and lines ML220 (ML220a and ML220b) are formed in the wiring layer of the wiring structure layer L2, which is located below the lines 210. Transistors M230 (M230a and M230b) constituting the comparator CMP, which severs as the resistance measurement circuit, are formed in the wiring structure layer L1, which is located below the line ML200 and the lines ML220, and the semiconductor substrate SUB.

Note that similarly to FIG. 25, the line ML200 located below the heater 40 is the line that is used to cut off the heat conduction from the heater 40 to the silicon substrate.

The thermal sensors 30 and 50 have a wiring structure as shown in FIGS. 38A, 38B and 38C, and the ends of the lines of the thermal sensors 30 and 50 are connected to one ends of the lines ML210a and ML210b located in the lower layer through trench lines (vias) T210a and T210b. The other ends of the lines ML210a and ML210b are connected to one ends of the lines ML220a and ML220b, which are located below the lines ML210a and ML210b, through trench lines T220a and T220b. The other ends of the lines ML220a and ML220b are connected to the gate terminals Gs of the transistors M230a and ML230b through trench lines (contacts) T230a and T230b.

To avoid the thermal effect caused by the heater 40, the resistance measurement circuits (M230a and M230b) are disposed in places distant from the heater 40. Therefore, the lines ML210a and ML210b are formed in such a manner that they extend toward the directions away from the heater 40 as viewed from the side and then bent to the directions opposite from the heater 40 as viewed from the top. In this manner, the lines ML210a and ML210b connects the thermal sensors 30 and 50 to the resistance measurement circuits.

As described above, the thermal sensors are connected to the resistance measurement circuits through lines formed in layers that are located below the thermal sensors. As a result, since these lines are not exposed in the hollow portion, these lines can be laid out freely without affecting the sensitivity of the acceleration sensor.

### Thirty-Second Embodiment

In this embodiment, another wiring example from the heater/thermal sensor line to the resistance measurement circuit (comparator) in the semiconductor device 100 is explained.

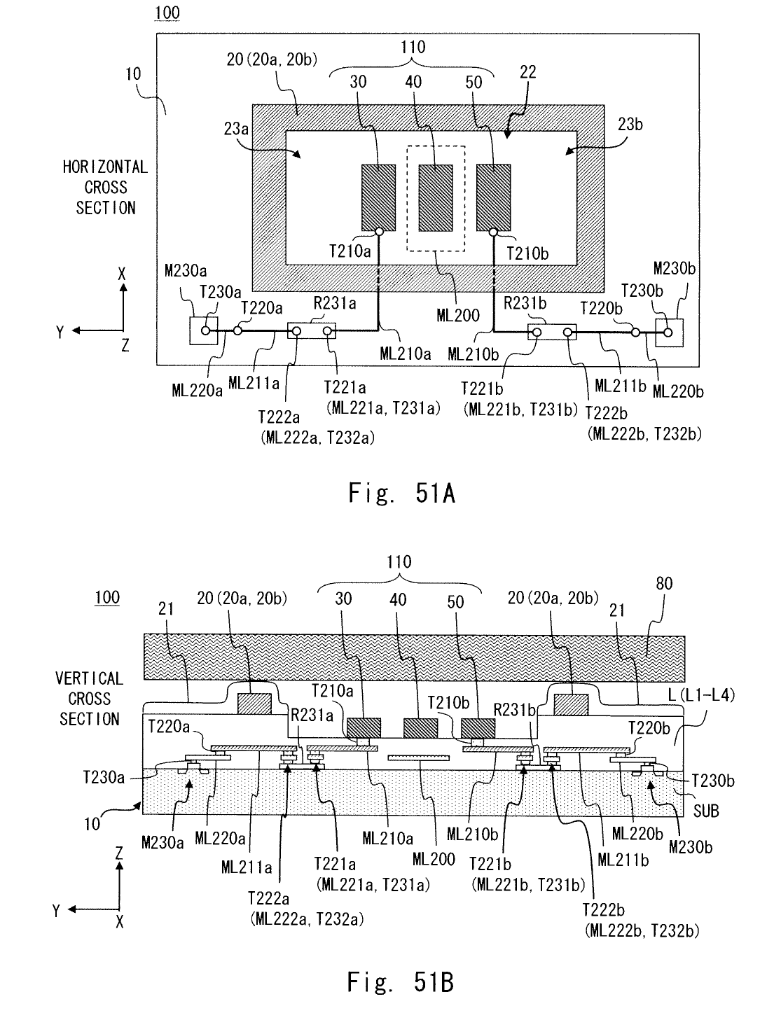

FIGS. 51A and 51B are a horizontal cross section and a vertical cross section of a semiconductor device 100 according to this embodiment of the present invention. FIGS. 51A and 51B show an example in which additional resistors R231 are added in comparison to the configuration shown in FIGS. 50A and 50B. Each of the resistors R231 corresponds to the resistor RI1 in FIG. 47, and is a resistor having a low heat conductivity connected between the thermal sensor and the comparator CMP. For the resistor R231, polysilicon, which has a low heat conductivity, is used. Therefore, a connection is made downward from an upper wiring layer to a lower polysilicon layer through a trench line (contact) and then an connection is made upward from the lower polysilicon layer to the upper wiring layer.

In the semiconductor device 100, an uppermost layer wiring structure 20 is formed in the uppermost layer and the heater/thermal sensor line 110 is formed in the wiring layer of the wiring structure layer L4, which is located below the uppermost layer wiring structure 20. Lines ML210 (ML210a and ML210b) and lines ML211 (ML211a and ML211b) are formed in the wiring layer of the wiring structure layer L3, which is located below the heater/thermal sensor line 110. A line ML200, lines ML220 (ML220a and ML220b), lines ML221 (ML221a and ML221b), and lines ML222 (ML222a and ML222b) are formed in the wiring layer of the wiring structure layer L2, which is located below the lines 210. Transistors M230 (M230a and M230b) constituting the comparator CMP, which severs as the resistance measurement circuit, are formed in the wiring structure layer L1, which is located below the line ML200 and the lines ML220, and the semiconductor substrate SUB.

The ends of the lines of the thermal sensors 30 and 50 are connected to one ends of the lines ML210a and ML210b located in the lower layer through trench lines T210a and T210b. The other end of the line ML210a is connected to one end of the resistor R231a in the lowermost layer through a trench line T221a, a line ML221a in a lower layer, and a trench line T231a. The other end of the resistor R231a is connected to one end of the line ML211a in the upper layer through a trench line T232a, a line ML222a in an upper layer, and a trench line T222a. Similarly, the other end of the line ML210b is connected to one end of the resistor R231b in the lowermost layer through a trench line T221b, a line ML221b in a lower layer, and a trench line T231b. The other end of the resistor R231b is connected to one end of the line ML211b in the upper layer through a trench line T232b, a line ML222b in an upper layer, and a trench line T222b. The other ends of the lines ML211a and ML211b are connected to one ends of the lines ML220a and ML220b in the lower layer through trench lines T220a and T220b. The other ends of the lines ML220a and ML220b are connected to the gate terminals Gs of the transistors M230a and ML230b through trench lines T230a and T230b.

By connecting a resistor having a low heat conductivity made of polysilicon between the thermal sensors 30 and 50 and the resistance measurement circuits, it is possible to prevent the heat from escaping from the thermal sensors 30 and 50 and thereby to improve the sensitivity of the thermal sensor.

### Thirty-Third Embodiment

In this embodiment, a configuration of the heat detection circuit of the semiconductor device 100 is explained. In the semiconductor device 100, the temperature can be detected by the thermal sensor by using, for example, a heat detection circuit like the one shown in FIG. 6.

However, an offset occurs in the output voltage of the thermal sensor due to the variations of components of the semiconductor device, surrounding environments, and/or the like. In particular, since the offset occurring in the output voltage significantly changes over time due to changes in the surrounding environments such as the temperature, it is very difficult to detect an acceleration with stability.

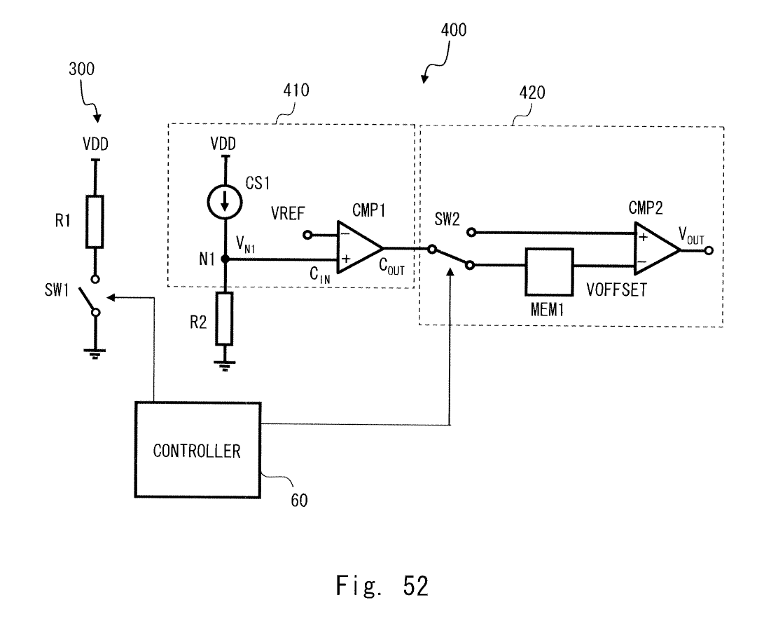

Accordingly, in this embodiment of the present invention, a circuit configuration shown in FIG. 52 is used in order to make it possible to correct the offset of the thermal sensor in a dynamic manner.

FIG. 52 shows a circuit configuration example of a heater drive circuit and a heat detection circuit according to this embodiment of the present invention. A heater drive circuit 300 corresponds to the heater drive circuit in FIG. 5, and a heat detection circuit 400 corresponds to the heat detection circuit in FIG. 6.

The heater drive circuit 300 includes a resistor R1 and a switch circuit SW1 connected in series between a power-supply potential VDD and a ground potential GND. The On/Off of the switch circuit SW1 is controlled by a controller 60. The resistor R1 correspond to the heater 40 and the switch circuit SW1 corresponds to the transistor M1 in FIG. 5. When the switch circuit SW1 is in an On-state, a current flows through the resistor R1 and the heater 40 thereby generates heat. On the other hand, when the switch circuit SW1 is in an Off-state, the heater 40 does not generate any heat.

The heat detection circuit 400 includes a resistor R2 that corresponds to the thermal sensor 30 or 50, a resistance measurement circuit 410 that measures the resistance value of the resistor R2, and an offset correction circuit 420 that performs an offset correction for the output of the resistance measurement circuit 410.

The resistance measurement circuit 410 includes a current source CS1, a resistor R2, and a comparator CMP1. The offset correction circuit 420 includes a switch circuit SW2, a storage element MEM1, and a comparator CMP2.

The current source CS1 and the resistor R2 connected in series between a power-supply potential VDD and a ground potential GND, and the node N1 between the current source CS1 and the resistor R2 is input to the positive input terminal (CIN) of the comparator CMP1. The comparator CMP1 compares a voltage VN1 measured at the node N1 with a reference voltage VREF, amplifies their difference value, and outputs the amplified difference value as a measured voltage COUT.

The switch circuit SW2 connects the output terminal of the comparator CMP1 to the positive input terminal of the comparator CMP2 or to the storage element MEM1. The On/Off of the switch circuit SW2 is controlled by a controller 60. When the switch circuit SW2 is in an On-state, the output terminal of the comparator CMP1 is connected to the positive input terminal of the comparator CMP2. On the other hand, when the switch circuit SW2 is in an Off-state, the output terminal of the comparator CMP1 is connected to the storage element MEM1.

When the storage element MEM1 is connected to the comparator CMP1, the storage element MEM1 stores the output voltage (measured voltage) COUT of the comparator CMP1 as an offset voltage VOFFSET. When the comparator CMP2 is connected to the comparator CMP1, the comparator CMP2 compares the output voltage COUT of the comparator CMP1 with the offset voltage VOFFSET stored in the storage element MEM1 and outputs their difference value as an output voltage VOUT.

The On/Off of the switch circuit SW1 of the heater drive circuit 300 and the On/Off of the switch circuit SW2 of the heat detection circuit 400 are switched in a synchronized manner by the controller 60. That is, the On/Off timing of the heater 40 is synchronized with the heat detection output by the thermal sensor or with the offset storage timing.

By turning off the switch circuits SW1 and SW2, the output voltage COUT by the resistor (sensor resistor) R2 at the time when the heater is in an Off-state is stored into the storage element MEM1 as an offset value VOFFSET. By turning on the switch circuits SW1 and SW2, a voltage obtained by subtracting the offset value VOFFSET from the output voltage COUT by the resistor R2 at the time when the heater is in an On-state is output as an output voltage VOUT.

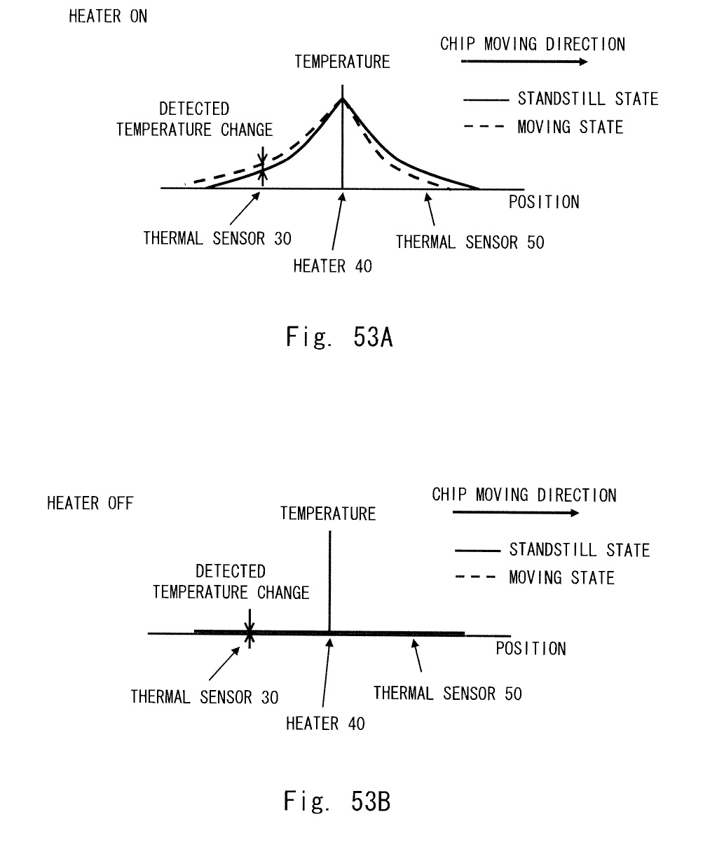

FIGS. 53A and 53B show distributions of temperatures near the thermal sensors 30 and 50 when the heater 40 is an On-state and when it is in an Off-state.

As shown in FIG. 53A, when the heater 40 is an On-state, the temperature distributions are different between when the semiconductor device 100 is at a standstill and when it is moving. That is, when the semiconductor device 100 is at a standstill, the temperature distribution is left-right symmetrical between the thermal sensor 30 side and the thermal sensor 50 side with respect to the heater 40. In contrast to this, when the semiconductor device 100 moves, a gas flow occurs. Therefore, the temperature distribution becomes left-right asymmetrical between the thermal sensor 30 side and the thermal sensor 50 side with respect to the heater 40. As a result, it is possible to detect an acceleration based on the difference between the temperature near the thermal sensor 30 and that near the thermal sensor 50.

In contrast to this, as shown in FIG. 53B, when the heater 40 is an Off-state, the temperature distribution is unchanged regardless of whether the semiconductor device 100 is at a standstill or is moving. That is, since the heater 40 generates no heat and the gas temperature is constant, the temperature distribution is unchanged regardless of whether the semiconductor device 100 is at a standstill or is moving. Therefore, since no difference occurs between the temperature near the thermal sensor 30 and that near the thermal sensor 50, no acceleration is detected. Accordingly, when the heater is in an Off-state, the temperature distribution between the thermal sensors becomes the offset value on which the acceleration has no effect. That is, the offset value is the output of the thermal sensors in a state where no effect exerted by the heat generated by the heater 40.

In this embodiment, when the heater 40 is turned off, this offset value is stored in the storage element MEM1 shown in FIG. 52. Further, when the heater 40 is turned on, the offset value is subtracted by the comparator CMP2 and the offset correction is thereby performed. In this way, an acceleration can be detected with accuracy and stability.

Further, by intermittently operating the heater and thereby alternately repeating the step for storing the offset of the thermal sensors and the step for performing the offset correction for the detected value of the thermal sensors, it is possible to correct for characteristic fluctuations in a real-time manner.

### Thirty-Fourth Embodiment

In this embodiment, actual measurement results of the semiconductor device 100 using the heat detection circuit shown in FIG. 52 are explained.

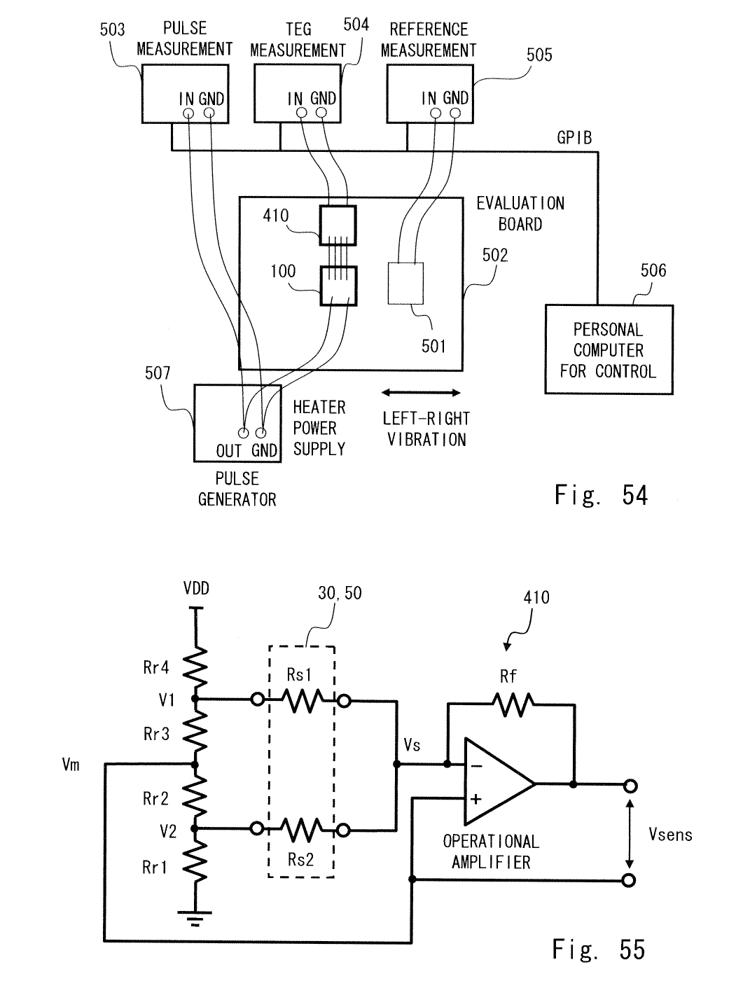

FIG. 54 shows a configuration of a measurement system for measuring an acceleration detection operation performed by the semiconductor device 100, i.e., by the acceleration sensor. In this example, the detection operation is checked by comparing the output of the semiconductor device 100 according to an aspect of the present invention with the output of another acceleration sensor. To that end, the output of an acceleration sensor 501, which is used as a reference acceleration, is also measured at the same time for the comparison. The acceleration sensor 501 is a typical acceleration sensor that outputs a signal according to the acceleration to be detected.

As shown in FIG. 54, the semiconductor device 100 according to an aspect of the present invention and the acceleration sensor 501 are mounted on the same evaluation board 502 and this evaluation board 502 is horizontally vibrated.

On the evaluation board 502, a resistance measurement circuit 410 that measures the resistance values of the thermal sensors is connected to the semiconductor device 100. The resistance measurement circuit 410 may be formed inside the semiconductor device 100 as described above, or may be provided outside the semiconductor device 100 as shown in FIG. 54.

FIG. 55 shows a circuit configuration of the resistance measurement circuit 410 shown in FIG. 54. The sensor resistors RS1 and RS2 correspond to the thermal sensors 30 and 50 of the semiconductor device 100. Both terminals of the sensor resistor RS1 and both terminals of the sensor resistor RS2, i.e., the four terminals in total are connected to the resistance measurement circuit 410.

The resistance measurement circuit 410 includes resistors Rr1 to Rr4, an operational amplifier 411, a feedback resistor Rf. The resistors Rr1 to Rr4 are connected in series between a power-supply potential VDD and a ground potential GND in the order of the resistors Rr4, Rr3, Rr2 and Rr1.

The node between the resistors Rr4 and Rr3 is connected to one end of the resistor RS1 and the voltage V1 at this node is thereby supplied to the sensor resistor RS1. The node between the resistors Rr2 and Rr1 is connected to one end of the resistor RS2 and the voltage V2 at this node is thereby supplied to the sensor resistor RS2.

The node (voltage Vm) between the resistors Rr3 and Rr2 is connected to the positive input terminal of the operational amplifier 411 and this node voltage Vm is thereby supplied to the operational amplifier 411. The other end of the resistor RS1 and the other end of the resistor RS2 are connected together and this node is also connected to the negative input terminal of the operational amplifier 411. Therefore, this node voltage Vs is supplied to the operational amplifier 411. Further, the output terminal of the operational amplifier 411 is connected to its negative input terminal through the feedback resistor Rf in a feedback configuration.

In the resistance measurement circuit 410, the operational amplifier 411 amplifies a voltage VS generated by the change in resistance values of the resistors RS1 and RS2 and outputs the amplified voltage as a detection voltage (measured voltage) Vsense. In this example, measurement was carried out in a state where the resistance measurement circuit 410 was operated under the condition that: supplied VDD=5V; and resistance Rr1=Rr4=1 kΩ, Rr2=Rr3=100Ω, and Rf=10 kΩ.

Further, as shown in FIG. 54, a pulse generator 507 is connected to the heater 40 of the semiconductor device 100. For the pulse generator 507, 33250A (Agilent) was used. The heater 40 is intermittently and repeatedly turned on and off by a pulse signal output from the pulse generator 507. The frequency of the On/Off of the heater 40 was 4 Hz. Further, the pulse signal generated by the pulse generator 507 is measured by a digital multi-meter for pulse measurement 503.

Further, the output voltage of the resistance measurement circuit 410, which is connected to the semiconductor device 100, is measured by a digital multi-meter for TEG (Test Element Group) measurement 504. At the same time, the output voltage of the acceleration sensor 501 is measured by a digital multi-meter for reference measurement 505. For each of the digital multi-meters 503 to 505, 34410A (Agilent) was used. The measurement results of the digital multi-meters 503 to 505 are output to a personal computer for control 506 through a GPIB (General Purpose Interface Bus).

The personal computer for control 506 obtains a detected acceleration based on the On/Off pulses for the heater measured by the digital multi-meter 503 and the voltage of the resistance measurement circuit 410 measured by the digital multi-meter 504. A mean value of the measured output voltages of the resistance measurement circuit 410 during a period in which the heater is in an Off-state is calculated and the calculated mean value is stored as an offset value. During a period in which the heater is in an On-state, the stored offset value is subtracted from a measured output voltage of the resistance measurement circuit 410 and an offset correction is thereby preformed. Then, this offset-corrected voltage is used as a detected acceleration.

That is, in this measurement example, the personal computer for control 506 performs an offset correction. That is, the offset correction circuit 420 shown in FIG. 52 corresponds to the personal computer for control 506.

Note that the output signal of the acceleration sensor 501 is measured by the digital multi-meter 505, and the personal computer for control 506 performs arithmetic processing on this measurement result and thereby obtains a detected acceleration.

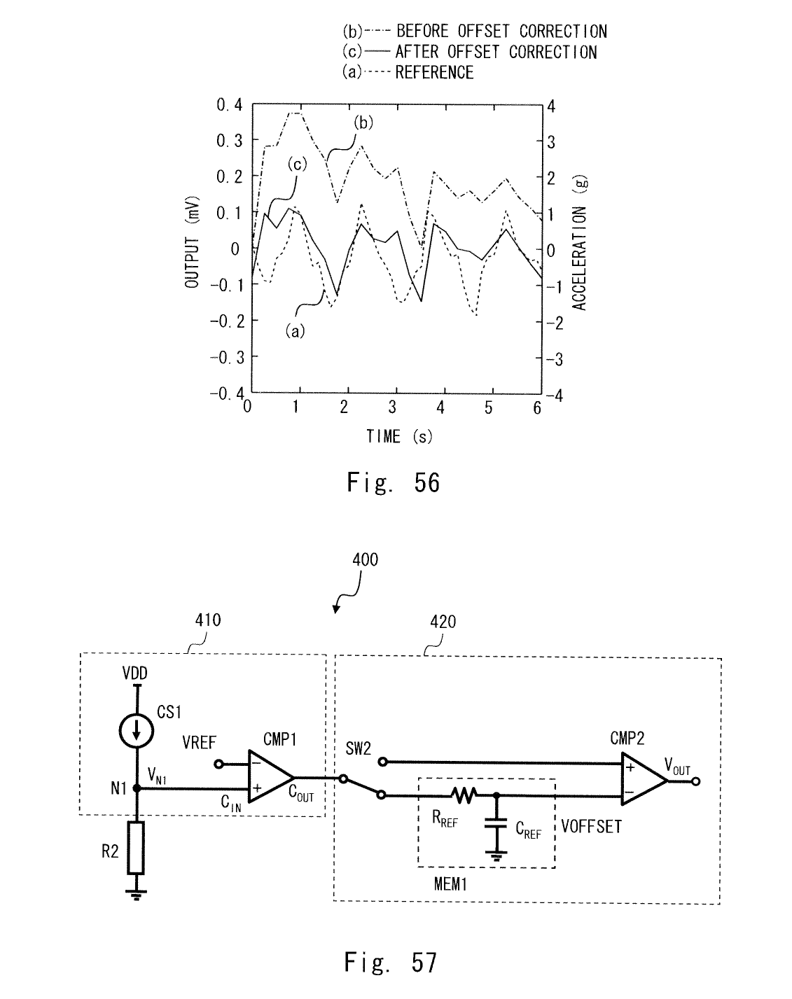

FIG. 56 shows measurement results of the measurement system shown in FIG. 54. FIG. 56, in which the horizontal axis represents time, shows responses of the semiconductor device 100 and the acceleration sensor 501 to the acceleration that varies with time. Against the horizontal axis, the vertical axis on the left side of the figure is a scale for the output voltage output by the resistance measurement circuit 410 and the vertical axis on the right side of the figure is a scale for the acceleration detected by the acceleration sensor 501.

A dotted polygonal line (a) represents the reference acceleration detected by the acceleration sensor 501, and indicates the acceleration exerted on the evaluation board 502. A chain polygonal line (b) represents the output voltage output by the resistance measurement circuit 410 according to an aspect of the present invention for which the offset correction is not performed. It corresponds to VSENS in FIG. 55 (COUT in FIG. 52). The solid polygonal line (c) represents the output voltage according to an aspect of the present invention obtained by performing the offset correction for the output voltage represented by the polygonal line (b). It corresponds to VOUT in FIG. 52.

When the polygonal line (b) according to an aspect of the present invention is compared with the polygonal line (a) representing the reference, the difference from the acceleration detected by the acceleration sensor 501 is large before the offset correction is performed as indicated by the polygonal line (b) because drifts of the output voltage occur due to changes of the offset value over time. In contrast to this, as indicated by the polygonal line (c) according to an aspect of the present invention, it can be seen that the output waveform closer to the acceleration detected by the acceleration sensor 501 can be obtained after the offset correction is performed because the drifts are cancelled by the offset correction. Therefore, by performing a real-time correction with the offset correction circuit as shown in FIG. 52, it became possible to perform an acceleration detection operation that produces similar results to those obtained by an ordinary acceleration sensor as shown in FIG. 56.

### Thirty-Fifth Embodiment

In this embodiment, an example in which the offset correction circuit of the semiconductor device 100 is formed by an analog circuit is explained.

FIG. 57 shows a circuit configuration example of a heat detection circuit in a semiconductor device 100 according to this embodiment of the present invention. FIG. 57 shows a specific circuit configuration of the storage element MEM1 shown in FIG. 52, and other configurations are similar to those in FIG. 52.

In FIG. 57, a capacitance Cref and an input resistor Rref are used as the storage element MEM1. One end of the input resistor Rref is connected to the output terminal of the comparator CMP1 through the switch circuit SW2 and the other end of the input resistor Rref is connected to the one end of the capacitance Cref and the negative input terminal of the comparator CMP2. The other end of the capacitance Cref is connected to a ground potential GND.

The capacitance Cref and the input resistor Rref form a low-pass filter. Therefore, the high frequency component of the offset value of the output voltage COUT is removed and only the low frequency component is thereby extracted and stored in the capacitance Cref.

As described above, in this embodiment, it is possible to perform a real-time offset correction by the configuration similar to that in FIG. 52. Further, by forming the storage element MEM1 by the capacitance Cref and the input resistor Rref, the circuit can be formed with ease. In addition, it also serves as a low-pass filter and thereby prevents the effect caused by high frequency noises contained in the output voltage COUT.

### Thirty-Sixth Embodiment

In this embodiment, an example in which the offset correction circuit of the semiconductor device 100 is formed by a digital circuit is explained.

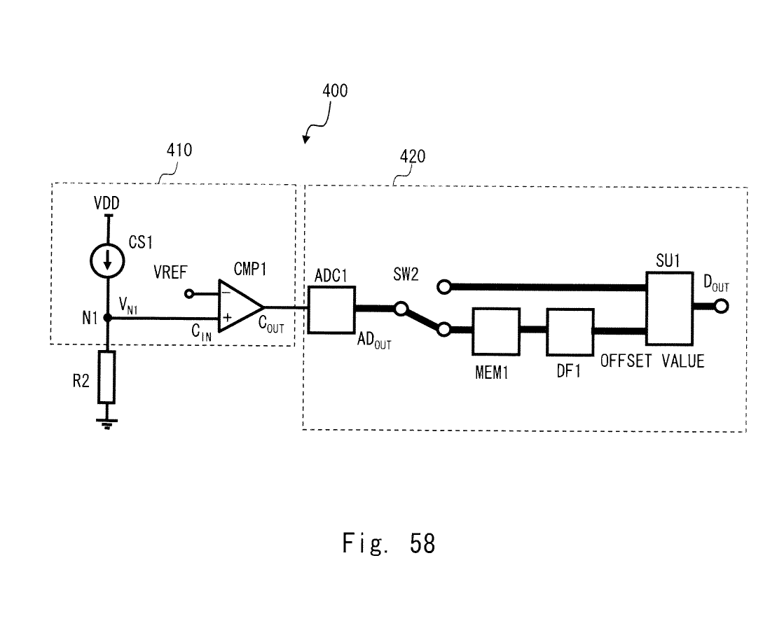

FIG. 58 shows a circuit configuration example of a heat detection circuit in a semiconductor device 100 according to this embodiment of the present invention. In FIG. 58, the offset correction circuit 420 shown in FIG. 52 is formed by a digital circuit and other configurations are similar to those in FIG. 52.

In FIG. 58, the offset correction circuit 420 includes an AD converter ADC1, a storage element MEM1, a digital filter DF1, and a subtracter SU1.

The AD converter ADC1 converts the output signal of the comparator CMP1 into a digital signal and outputs the obtained digital signal to the subtracter SU1 or to the storage element MEM1.

When the heater is in an Off-state, this digital signal is stored in the storage element MEM1. The digital filter DF1 removes the high frequency component of the digital signal stored in the storage element MEM1 and thereby outputs only the low frequency component of the digital signal to the subtracter SU1 as an offset value. When the heater is in an On-state, the subtracter SU1 subtracts the offset value stored in the storage element MEM1 from the digital signal output from the AD converter ADC1 and outputs the subtraction result as an output DOUT in the form of a digital signal.

As described above, in this embodiment, it is possible to perform a real-time offset correction by the configuration similar to that in FIG. 52. Further, by forming the offset correction circuit by a digital circuit, the offset correction circuit can be implemented by using digital signal processing. Therefore, the offset correction circuit can be constructed by using a microcomputer or the like. In the microcomputer or the like, arithmetic processing is performed by using software. Therefore, it is implemented without forming any analog circuit.

### Thirty-Seventh Embodiment

In this embodiment, a configuration example of a comparator used for the resistance measurement circuit of the semiconductor device 100 is explained. As shown in FIGS. 46, 47, 49, 52, 55 and so on, the resistance measurement circuit 410 of the semiconductor device 100 includes the comparator CMP (or CMP1). For this comparator CMP, an ordinary operational amplifier, for example, can be used.

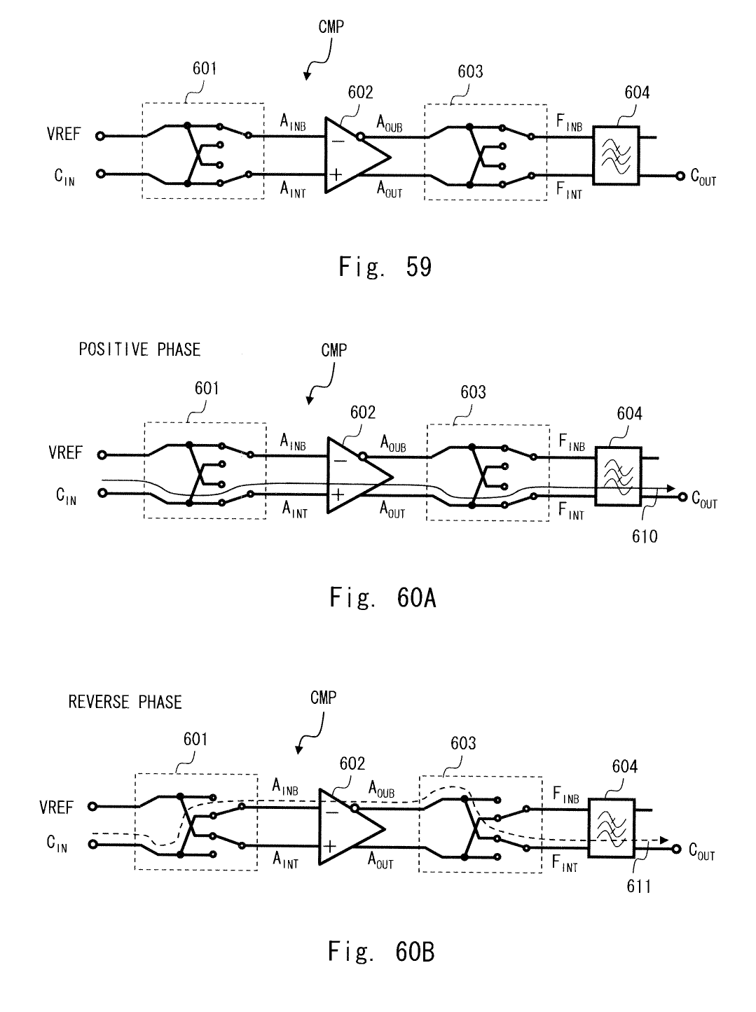

In this embodiment, a chopper-type amplifier is used as the comparator CMP instead of using the operational amplifier. FIG. 59 shows a configuration of a comparator CMP according to this embodiment of the present invention. As shown in FIG. 59, the comparator CMP is formed by a chopper-type amplifier, and includes two select switches 601 and 603, a differential amplifier 602, and a low-pass filter 604. They are connected in series in the order of the select switch 601, the differential amplifier 602, the select switch 603, and the low-pass filter 604. Each of the select switches 601 and 603 is a switch circuit having two inputs and two outputs. The select switches 601 and 603 are switched simultaneously with each other in response to the same clock signal (switching signal).

The select switch 601 connects each of the reference voltage VREF and CIN (input of the comparator CMP) to either the negative input AINB or the positive input AINT of the differential amplifier. The differential amplifier 602 performs differential amplification for the signal that is input from the select switch 601 to its negative input AINB and positive input AINT, and outputs the amplified signal from the negative output AOUB and positive output AOUT. The select switch 603 connects each of the negative output AOUB and positive output AOUT of the differential amplifier 602 to either the negative input FINB or the positive input FINT of the low-pass filter 604. The low-pass filter 604 removes the high frequency component from the signal that is input from the select switch 603 to its negative input FINB and positive input FINT, and outputs the low frequency component signal to the COUT (output of the comparator CMP).

FIGS. 60A and 60B show an operation of the comparator CMP formed by the chopper-type amplifier shown in FIG. 59. The chopper-type amplifier has two states consisting of a positive phase and a reverse phase that are determined according to the states of the select switches 601 and 603. The chopper-type amplifier alternately repeats the positive phase and reverse phase in response to the clock signal supplied to the select switches 601 and 603.

FIG. 60A shows a signal flow in the positive phase. In the positive phase, the select switch 601 connects VREF to AINB and connects CIN to AINT. Further, the select switch 603 connects AOUB to FINB and connects AOUT to FINT. Therefore, in the positive phase, the signal input from CIN propagates through the path “CIN-AINT-AOUT-FINT-COUT” as indicated by the solid-line arrow 610.

Meanwhile, FIG. 60B shows a signal flow in the reverse phase. In the reverse phase, the select switch 601 connects VREF to AINT and connects CIN to AINB. Further, the select switch 603 connects AOUB to FINT and connects AOUT to FINB. Therefore, in the reverse phase, the signal input from CIN propagates through the path “CIN-AINB-AOUB-FINT-COUT” as indicated by the dotted-line arrow 611. That is, the positive phase and the negative phase are different in whether the signal input from CIN passes through the positive input AINT or through the negative input AINB of the differential amplifier 602.

Here, assume that the differential amplifier 602 has an offset voltage ΔV due to the component variations or the like, and has a gain GAMP. Then, when no signal is input at all, that is, when CIN=VREF, a voltage ΔV×GAMP is output from the output of the differential amplifier 602 during a period in which the chopper-type amplifier is in a positive phase. Further, a voltage −ΔV×GAMP is output from the output of the differential amplifier 602 as the offset during a period in which the chopper-type amplifier is in a reverse phase.

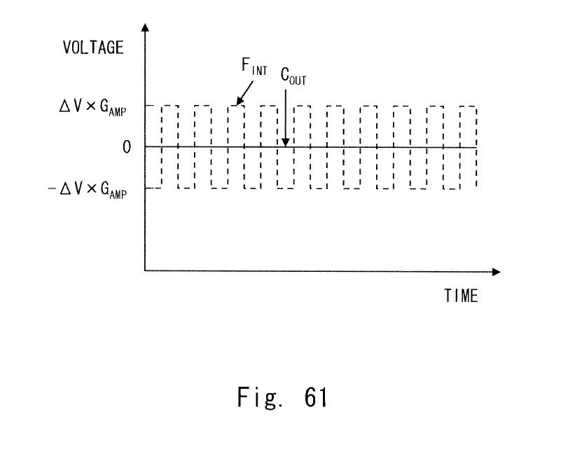

FIG. 61 schematically shows signal waveforms at FINT and COUT in FIGS. 59 and 60. In response to the repetition of the positive and negative phases of the chopper-type amplifier, the signal at FINT alternately changes between ΔV×GAMP and −ΔV×GAMP. When this signal at FINT passes through the low-pass filter 604, the repetitive signal is averaged to the mean value between ΔV×GAMP and −ΔV×GAMP. That is, 0 V is output to the COUT.

As described above, by forming the comparator CMP by a chopper-type amplifier, the offset of the differential amplifier has no effect on the output of the comparator CMP. As a result, it is possible to accurately amplifies a minute signal lower than the offset voltage of the differential amplifier. Therefore, it is possible to accurately detect the temperature of the thermal sensor by using this comparator CMP for the resistance measurement circuit of the semiconductor device 100.

While the invention has been described in terms of several embodiments, those skilled in the art will recognize that the invention can be practiced with various modifications within the spirit and scope of the appended claims and the invention is not limited to the examples described above.

Further, the scope of the claims is not limited by the embodiments described above.

Furthermore, it is noted that, Applicant's intent is to encompass equivalents of all claim elements, even if amended later during prosecution.

What is claimed is:

1. A semiconductor device comprising:
a stacked body with a recessed gas passage formed therein;
a heat-generating section disposed in the stacked body, the heat-generating section being exposed on a bottom surface of the gas passage; and
a plurality of heat-sensing sections disposed in the stacked body in such a manner that the plurality of heat-sensing sections are exposed on the bottom surface of the gas passage and sandwich the heat-generating section therebetween in an extending direction of the gas passage.

2. The semiconductor device according to claim 1, wherein
the stacked body comprises:
a semiconductor substrate;
a wiring structure layer provided on the semiconductor substrate, the wiring structure layer comprising an insulating layer and a wiring layer; and
an uppermost layer wiring structure provided on the wiring structure layer, the gas passage being disposed in the uppermost layer wiring structure, and
the heat-generating section is thermally isolated from the semiconductor substrate by the insulating layer included in the wiring structure layer.

3. The semiconductor device according to claim 1, wherein a wall line formed by a projecting shape of a wiring structure is provided in a periphery of the recessed gas passage.

4. The semiconductor device according to claim 1, wherein
the heat-generating section and the heat-sensing section comprises a conducive line patterned on the bottom surface of the gas passage, and
when the gas passage is viewed from top, a plurality of patterning areas formed by patterning of the conductive line are provided in the gas passage.

5. The semiconductor device according to claim 1, wherein the heat-generating section and the heat-sensing section are formed from aluminum, copper, tungsten, gold, platinum, vanadium, titanium, iron, nickel, an alloy thereof, an oxide thereof, or a nitride thereof.

6. The semiconductor device according to claim 1, wherein
the heat-generating section and the heat-sensing section comprises a conducive line patterned on the bottom surface of the gas passage, and
when the gas passage is viewed from top, at least one heat-generating section and at least two heat-sensing sections formed by patterning of the conductive line are provided in the gas passage.

7. The semiconductor device according to claim 1, wherein
the heat-generating section and the heat-sensing section comprises a conducive line patterned on the bottom surface of the gas passage, and
when the gas passage is viewed from top, at least one heat-generating section and at least two heat-sensing sections formed by patterning of the conductive line are provided in the gas passage and the heat-sensing sections are disposed in symmetric places with respect to the heat-generating section.

8. The semiconductor device according to claim 1, wherein
the heat-generating section and the heat-sensing section comprises a conducive line patterned on the bottom surface of the gas passage, and
when the gas passage is viewed from top, at least one heat-generating section and at least four heat-sensing sections formed by patterning of the conductive line are provided in the gas passage and the heat-sensing sections are disposed in four-time rotationally symmetric places with respect to the heat-generating section.

9. The semiconductor device according to claim 1, wherein either or both of the heat-sensing section and the heat-generating section has an uneven surface.

10. The semiconductor device according to claim 1, wherein a contacting area between the heat-sensing section or the heat-generating section and an insulating layer is smaller than a surface area of part of the heat-sensing section or the heat-generating section that is not in contact with the insulating layer.

11. The semiconductor device according to claim 1, wherein a distance between a drive section that drives the heat-generating section and the heat-generating section is larger than a distance between the heat-generating section and the heat-sensing section.

12. The semiconductor device according to claim 1, wherein a distance between a detection circuit connected to the heat-sensing section and the heat-sensing section is larger than a distance between the heat-generating section and the heat-sensing section.

13. The semiconductor device according to claim 1, further comprising a wiring area fixed to a ground or a fixed potential in an intermediate wiring layer between a wiring layer constituting the heat-generating section and a semiconductor substrate.

14. The semiconductor device according to claim 13, wherein the wiring area is fixed to the ground or the fixed potential by a circuit block comprising a drive section that drives the heat-generating section.

15. The semiconductor device according to claim 1, wherein the heat-generating section is driven in such a manner that a quantity of heat generated by the heat-generating section periodically changes.

16. The semiconductor device according to claim 1, wherein
the heat-generating section is formed by a conductive line, and
a current flows through the conductive line in different directions in a time-division manner.

17. The semiconductor device according to claim 1, further comprising a drive section that drives the heat-generating section,
wherein the drive section controls a current supply state to the heat-generating section based on a switching signal.

18. The semiconductor device according to claim 1, wherein the plurality of heat-sensing sections are individually connected to a plurality of PN junctions.

19. The semiconductor device according to claim 18, wherein a distance between the plurality of heat-sensing sections is smaller than a distance of the plurality of PN junctions.

20. The semiconductor device according to claim 1, wherein the plurality of the heat-sensing sections are individually connected to a plurality of detection circuits that detect temperature changes of the heat-sensing sections.

21. The semiconductor device according to claim 20, further comprising a comparison circuit that compares output voltages of detection circuits corresponding to temperatures of two heat-sensing sections among the plurality of the heat-sensing sections.

22. The semiconductor device according to claim 21, wherein the comparison circuit defines an output voltage of the detection circuit at a time when the semiconductor device is not accelerated as a reference voltage and detects an acceleration based on whether an output voltage of the detection circuit at a time when the semiconductor device is accelerated is higher or lower than the reference voltage.

23. The semiconductor device according to claim 20, wherein
the heat-generating section is driven in such a manner that a quantity of heat generated by the heat-generating section periodically changes, and
an acceleration is detected by detecting a phase difference with respect to a periodic change of generated heat of an output voltage of the detection circuit corresponding to a temperature in the heat-sensing section.

24. The semiconductor device according to claim 20, wherein
the heat-generating section is driven in such a manner that a quantity of heat generated by the heat-generating section periodically changes, and
a phase difference of a low frequency component of a signal obtained by mixing a periodically-changing output voltage of the detection circuit corresponding to a temperature in the heat-sensing section with a signal having a same frequency as a frequency of generated heat is detected.

25. The semiconductor device according to claim 1, further comprising a cover member provided on the stacked body, the cover member covering the gas passage from above.

26. The semiconductor device according to claim 2, wherein the uppermost layer wiring structure is made of same material as material of at least one of the insulating layer and the wiring layer included in the wiring structure layer.

27. The semiconductor device according to claim 25, wherein the cover member, which is provided on the stacked body and covers the gas passage from above, is an extended portion of a projecting portion formed by a wiring structure.

28. A method of manufacturing a semiconductor device, comprising:
forming a heat-generating section in a stacked body;
forming a plurality of heat-sensing sections in the stacked body in such a manner that the plurality of heat-sensing sections sandwich the heat-generating section therebetween; and
providing a recessed gas passage that extends along a direction in which the heat-generating section and the plurality of heat-sensing sections are disposed, the heat-generating section and the plurality of heat-sensing sections being exposed on a bottom surface of the gas passage.

29. The method of manufacturing a semiconductor device according to claim 28, wherein
the heat-generating section and the heat-sensing section comprises a conducive line patterned on the bottom surface of the gas passage, and
when the gas passage is viewed from top, a plurality of patterning areas formed by the patterning of the conductive line are provided in the gas passage.
